(19) United States
(12) Patent Application Publication
(10) Pub. No.: US 2025/0185340 A1
(43) Pub. Date: Jun. 5, 2025

(54) SEMICONDUCTOR DEVICE

(71) Applicant: Semiconductor Energy Laboratory Co., Ltd., Atsugi-shi, Kanagawa-ken (JP)

(72) Inventors: Ryota HODO, Atsugi (JP); Masaru NAKANO, Isehara (JP); Naoki OKUNO, Yamato (JP); Hiromi SAWAI, Atsugi (JP)

(21) Appl. No.: 18/845,920

(22) PCT Filed: Mar. 1, 2023
(86) PCT No.: PCT/IB2023/051879

§ 371 Date: Sep. 11, 2024

(30) Foreign Application Priority Data
Mar. 18, 2022 (JP) 2022-044219

(51) Int. Cl. H10D 64/66; H10B 12/00; H10D 1/68; H10D 30/60; H10D 62/17; H10D 62/86; H10D 64/23

(52) U.S. Cl. CPC H10D 64/665; H10B 12/01; H10D 1/68; H10D 30/611; H10D 62/235; H10D 62/86; H10D 64/257; H10D 64/667

(57) ABSTRACT

A semiconductor device that includes a first conductor (233a1), a second conductor (231), a first transistor (201) over a first insulator, and a second insulator (282) over the first insulator is provided. The first transistor includes a third conductor (242a) and a fourth conductor (242b) that are each electrically connected to a first metal oxide (230), a third insulator (253, 254) over the first metal oxide, and a fifth conductor (260) over the third insulator. The fourth conductor includes a second layer over a first layer. The top surface of the fifth conductor includes a region in contact with the second insulator. The first conductor includes a portion positioned inside an opening of the first insulator, a region in contact with a side surface of the third conductor, and a portion positioned inside an opening of the second insulator. The second conductor includes a region in contact with the second layer and a portion positioned inside an opening of the second insulator. The top surface of the first conductor and the top surface of the second conductor are level with each other.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method of manufacturing any of them.

In this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. A display device (e.g., a liquid crystal display apparatus and a light-emitting display apparatus), a projection device, a lighting device, an electro-optical device, a power storage device, a memory device, a semiconductor circuit, an imaging device, an electronic device, and the like can be regarded as including a semiconductor device.

### BACKGROUND ART

In recent years, semiconductor devices such as LSI (Large Scale Integration), CPUs (Central Processing Units), and memories (memory devices) have been developed. These semiconductor devices have been used in various electronic devices such as computers and portable information terminals. In addition, memories under development employ various memory systems for intended uses such as temporary storage at the time of executing arithmetic processing and long-term storage of data. Examples of memories with typical memory systems include a DRAM (Dynamic Random Access Memory), an SRAM (Static Random Access Memory), and a flash memory.

With an increasing amount of data to process, a semiconductor device having a larger storage capacity has been required. Patent Document 1 and Non-Patent Document 1 disclose memory cells in which transistors are stacked.

### REFERENCE

### Patent Document

[Patent Document 1]
[Patent Document 1] PCT International Publication No. 2021/053473

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. An object of one embodiment of the present invention is to provide a semiconductor device with high operating speed. An object of one embodiment of the present invention is to provide a semiconductor device with favorable electrical characteristics. An object of one embodiment of the present invention is to provide a semiconductor device with a small variation in electrical characteristics of transistors. An object of one embodiment of the present invention is to provide a highly reliable semiconductor device. An object of one embodiment of the present invention is to provide a semiconductor device with a high on-state current. An object of one embodiment of the present invention is to provide a semiconductor device with low power consumption. An object of one embodiment of the present invention is to provide a novel semiconductor device.

An object of one embodiment of the present invention is to provide a method for manufacturing a semiconductor device with a small number of steps.

An object of one embodiment of the present invention is to provide a memory device with high memory capacity. An object of one embodiment of the present invention is to provide a memory device that occupies a small area. An object of one embodiment of the present invention is to provide a highly reliable memory device. An object of one embodiment of the present invention is to provide a memory device with low power consumption. An object of one embodiment of the present invention is to provide a novel memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device that includes a first conductor, a second conductor, a first insulator, a first transistor over the first insulator, and a second insulator over the first transistor. The first transistor includes a first metal oxide, a third conductor electrically connected to the first metal oxide, a fourth conductor electrically connected to the first metal oxide, a third insulator over the first metal oxide, and a fifth conductor over the third insulator. The fourth conductor includes a first layer and a second layer over the first layer. The top surface of the fifth conductor includes a region in contact with the second insulator. The first conductor includes a portion positioned inside an opening of the first insulator, a region in contact with a side surface of the third conductor, and a portion positioned inside an opening of the second insulator. The second conductor includes a region in contact with the second layer and a portion positioned inside an opening of the second insulator. The top surface of the first conductor and the top surface of the second conductor are level or substantially level with each other.

One embodiment of the present invention is a semiconductor device that includes a first conductor, a second conductor, a first insulator, a first transistor, a second transistor, and a third transistor over the first insulator, and a second insulator over the first transistor, the second transistor, and the third transistor. The first transistor includes a first metal oxide, a third conductor electrically connected to the first metal oxide, a fourth conductor electrically connected to the first metal oxide, a third insulator over the first metal oxide, and a fifth conductor over the third insulator. The fourth conductor includes a first layer and a second layer over the first layer. The second transistor includes a second metal oxide, a sixth conductor electrically connected to the second metal oxide, a seventh conductor electrically connected to the second metal oxide, a fourth insulator over the second metal oxide, and an eighth conductor over the fourth insulator. the third transistor includes the second metal oxide, the seventh conductor electrically connected to the second metal oxide, a ninth conductor electrically connected to the second metal oxide, a fifth insulator over the second metal oxide, and a tenth conductor over the fifth insulator. The top surface of the fifth conductor and the top surface of the tenth conductor include a region in contact with the second insulator. The first conductor includes a portion positioned inside an opening of the first insulator, a region in contact with a side surface of the third conductor, and a portion positioned inside an opening of the second insulator. The second conductor includes a region in contact with the second layer and a portion positioned inside an opening of the second insulator. The second conductor and the eighth conductor are electrically connected to each other. The top surface of the first conductor and the top surface of the second conductor are level or substantially level with each other.

One embodiment of the present invention is a semiconductor device that includes a first conductor, a second conductor, a first insulator, a first transistor, a second transistor, and a third transistor over the first insulator, a second insulator over the first transistor, the second transistor, and the third transistor, and a capacitor. The first transistor includes a first metal oxide, a third conductor electrically connected to the first metal oxide, a fourth conductor electrically connected to the first metal oxide, a third insulator over the first metal oxide, and a fifth conductor over the third insulator. The fourth conductor includes a first layer and a second layer over the first layer. The second transistor includes a second metal oxide, a sixth conductor electrically connected to the second metal oxide, a seventh conductor electrically connected to the second metal oxide, a fourth insulator over the second metal oxide, and an eighth conductor over the fourth insulator. The third transistor includes the second metal oxide, the seventh conductor electrically connected to the second metal oxide, a ninth conductor electrically connected to the second metal oxide, a fifth insulator over the second metal oxide, and a tenth conductor over the fifth insulator. The capacitor includes an eleventh conductor, a sixth insulator over the eleventh conductor, and a twelfth conductor over the sixth insulator. The top surface of the fifth conductor and the top surface of the tenth conductor include a region in contact with the second insulator. The first conductor includes a portion positioned inside an opening of the first insulator, a region in contact with a side surface of the third conductor, and a portion positioned inside an opening of the second insulator. The second conductor includes a region in contact with the second layer and a portion positioned inside an opening of the second insulator. The second conductor and the eighth conductor are electrically connected to each other through the eleventh conductor. The top surface of the first conductor and the top surface of the second conductor are level or substantially level with each other.

In the semiconductor device described in any of the above, the sixth insulator includes a first zirconium oxide, an aluminum oxide over the first zirconium oxide, and a second zirconium oxide over the aluminum oxide.

In the semiconductor device described in any of the above, the first layer includes tantalum nitride and the second layer includes tungsten.

In the semiconductor device described in any of the above, the thickness of the fourth conductor is greater than or equal to 10 nm and less than or equal to 50 nm and the thickness of the first layer is greater than or equal to 2 nm and less than or equal to 10 nm.

In the semiconductor device described in any of the above, the width of the region of the first conductor that is in contact with the side surface of the third conductor is smaller than the width of a region of the first conductor that is in contact with a side surface of the second insulator in a cross-sectional view in the channel length direction.

In the semiconductor device described in any of the above, the first metal oxide and the second metal oxide include one or more selected from indium, zinc, gallium, aluminum, and tin.

### Effect of the Invention

According to one embodiment of the present invention, a semiconductor device that can be miniaturized or highly integrated can be provided. According to one embodiment of the present invention, a semiconductor device with high operating speed can be provided. According to one embodiment of the present invention, a semiconductor device with favorable electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided.

According to one embodiment of the present invention, a method for manufacturing a semiconductor device with a small number of steps can be provided.

According to one embodiment of the present invention, a memory device with high memory capacity can be provided. According to one embodiment of the present invention, a memory device that occupies a small area can be provided. According to one embodiment of the present invention, a highly reliable memory device can be provided. According to one embodiment of the present invention, a memory device with lower power consumption. According to one embodiment of the present invention, a novel memory device can be provided. Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a cross-sectional view illustrating a structure example of a semiconductor device.

FIG. 2A is a cross-sectional view illustrating a structure example of a semiconductor device. FIG. 2B is a cross-sectional view illustrating a structure example of a transistor.

FIG. 3 is a cross-sectional view illustrating a structure example of a semiconductor device.

FIG. 4 is a cross-sectional view illustrating a structure example of a semiconductor device.

FIG. 5 is a cross-sectional view illustrating a structure example of a semiconductor device.

FIG. 6 is a cross-sectional view illustrating a structure example of a semiconductor device.

FIG. 7A and FIG. 7B are plan views each illustrating a structure example of a semiconductor device.

FIG. 8A to FIG. 8E are cross-sectional views illustrating an example of a method for manufacturing a semiconductor device.

FIG. 9A to FIG. 9C are cross-sectional views illustrating an example of a method for manufacturing a semiconductor device.

FIG. 10A to FIG. 10C are cross-sectional views illustrating an example of a method for manufacturing a semiconductor device.

FIG. 11A and FIG. 11B are cross-sectional views illustrating an example of a method for manufacturing a semiconductor device.

FIG. 12 is a cross-sectional view illustrating an example of a method for manufacturing a semiconductor device.

FIG. 13A and FIG. 13B are cross-sectional views illustrating an example of a method for manufacturing a semiconductor device.

FIG. 14A and FIG. 14B are cross-sectional views illustrating an example of a method for manufacturing a semiconductor device.

FIG. 15 is a cross-sectional view illustrating an example of a method for manufacturing a semiconductor device.

FIG. 16A and FIG. 16B are diagrams illustrating an example of a memory device.

FIG. 17A and FIG. 17B are circuit diagrams each illustrating an example of a memory layer.

FIG. 18 is a timing chart showing an operation example of a memory cell.

FIGS. 19A and 19B are circuit diagrams each illustrating an operation example of a memory cell.

FIGS. 20A and 20B are circuit diagrams each illustrating an operation example of a memory cell.

FIG. 21 is a circuit diagram illustrating a structure example of a semiconductor device.

FIG. 22A and FIG. 22B are drawings illustrating an example of a semiconductor device.

FIG. 23A and FIG. 23B are diagrams each illustrating an example of an electronic component.

FIG. 24A to FIG. 24J are diagrams each illustrating an example of an electronic device.

FIG. 25A to FIG. 25E are diagrams each illustrating an example of an electronic device.

FIG. 26A to FIG. 26C are diagrams each illustrating an example of an electronic device.

FIG. 27 is a diagram illustrating an example of a device for space.

FIG. 28 shows results of etching rate measurement in Example 1.

FIG. 29 shows results of sheet resistance measurement in Example 1.

FIG. 30 shows results of carrier concentration measurement in Example 1.

FIG. 31 shows results of contact resistance measurement in Example 2.

FIG. 32 shows results of contact resistance measurement in Example 2.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same reference numerals are commonly used for the same portions or portions having similar functions in different drawings, and a repeated description thereof is omitted. The same hatching pattern is used for portions having similar functions, and the portions are not denoted by specific reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

The term “film” and the term “layer” can be interchanged with each other depending on the case or circumstances. For example, the term “conductive layer” can be replaced with the term “conductive film”. For another example, the term “insulating film” can be replaced with the term “insulating layer”.

In this specification and the like, terms for describing positioning, such as “over,” “under,” “above,” and “below,” are sometimes used for convenience to describe the positional relation between components with reference to drawings. The positional relationship between components is changed as appropriate in accordance with a direction in which each component is described. Thus, the positional relation is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

Note that in this specification and the like, the expression “level or substantially level” indicates a structure having the same level from a reference surface (e.g., a flat surface such as a substrate surface) in a cross-sectional view. For example, in a manufacturing process of a semiconductor device, planarization treatment (typically, chemical mechanical polishing (CMP) treatment) is performed, whereby the surface(s) of a single layer or a plurality of layers are exposed in some cases. In this case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level or substantially level” in this specification and the like. For example, the expression “level or substantially level” includes the case where two layers (here, given as a first layer and a second layer) having different levels with respect to the reference surface are included, and the difference between the top-surface level of the first layer and the top-surface level of the second layer is less than or equal to 20 nm.

Note that in this specification and the like, the expression “end portions are aligned or substantially aligned” means that at least outlines of stacked layers partly overlap with each other in a top view. For example, the case of processing an upper layer and a lower layer with the use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned or substantially aligned”.

### Embodiment 1

In this embodiment, a semiconductor device of one embodiment of the present invention will be described with reference to drawings.

One embodiment of the present invention relates to a semiconductor device in which a memory layer is provided over a substrate. The memory layer includes a first transistor, a second transistor, a third transistor, and a capacitor, which can form a memory cell. The semiconductor device of one embodiment of the present invention includes the memory cell and thus has a function of storing data. Hence, the semiconductor device of one embodiment of the present invention can be referred to as a memory device.

The first transistor includes a first metal oxide, first and second conductors covering parts of the top surface and the side surfaces of the first metal oxide, a first insulator provided between the first conductor and the second conductor, and a third conductor over the first insulator. The second transistor includes a second metal oxide, a fourth conductor covering parts of the top surface and the side surface of the second metal oxide, a fifth conductor covering part of the top surface of the second metal oxide, a second insulator provided between the fourth conductor and the fifth conductor, and a sixth conductor over the second insulator. The third transistor includes the second metal oxide, the fifth conductor, a seventh conductor covering parts of the top surface and the side surface of the second metal oxide, a third insulator provided between the fifth conductor and the seventh conductor, and an eighth conductor over the third insulator. That is, the second transistor and the third transistor share the second metal oxide and the fifth conductor. Note that it can be said that the first metal oxide is electrically connected to each of the first and second conductors. It can also be said that the second metal oxide is electrically connected to each of the fourth and fifth conductors. It can also be said that the second metal oxide is electrically connected to each of the fifth and seventh conductors.

The first metal oxide includes a region functioning as a channel formation region of the first transistor. The first conductor includes a region functioning as one of a source electrode and a drain electrode of the first transistor. The second conductor includes a region functioning as the other of the source electrode and the drain electrode of the first transistor. The third conductor includes a region functioning as a gate electrode of the first transistor. The first insulator includes a region functioning as a gate insulator of the first transistor.

The second metal oxide includes regions functioning as channel formation regions of the second and third transistors. The fourth conductor includes a region functioning as one of a source electrode and a drain electrode of the second transistor. The fifth conductor includes a region functioning as the other of the source electrode and the drain electrode of the second transistor and also functioning as one of a source electrode and a drain electrode of the third transistor. The sixth conductor includes a region functioning as a gate electrode of the second transistor. The seventh conductor includes a region functioning as the other of the source electrode and the drain electrode of the third transistor. The eighth conductor includes a region functioning as a gate electrode of the third transistor. The second insulator includes a region functioning as a gate insulator of the second transistor. The third insulator includes a region functioning as a gate insulator of the third transistor.

When the second transistor and the third transistor are adjacent to each other to share the second metal oxide and the fifth conductor, the two transistors can be formed in an area smaller than the area of two transistors (e.g., in the area of one and a half transistors). This enables the transistors to be arranged at high density, which leads to high integration in the semiconductor device.

The semiconductor device of one embodiment of the present invention includes a transistor including a metal oxide in a channel formation region (an OS transistor). When the OS transistor, which has a low off-state current, is used in a semiconductor device that can be a memory device, stored contents can be retained for a long time. That is, a refresh operation is not required or the frequency of the refresh operation is extremely low; thus, the power consumption of the semiconductor device can be adequately reduced. The OS transistor has high frequency characteristics and thus enables the semiconductor device to perform data reading and writing at high speed.

In the semiconductor device of one embodiment of the present invention, a plurality of memory layers each having the above structure are stacked. That is, the plurality of memory layers each having the above structure are provided in the direction perpendicular to the substrate surface, for example. Thus, without an increase in the area occupied by memory cells, the semiconductor device can have larger memory capacity than a semiconductor device including one memory layer. Accordingly, the occupation area per bit is reduced, so that the semiconductor device can have a small size and large memory capacity.

In the case where the plurality of memory layers are stacked, a write bit line and a read bit line can be provided in the direction perpendicular to the substrate surface, for example. For example, in the case where a semiconductor device including n (n is an integer greater than or equal to 2) memory layers is formed, connection electrodes for connecting conductors included in the n memory layers in the vertical direction are formed, whereby a write bit line and a read bit line extending in the vertical direction can be formed. Here, in the semiconductor device of one embodiment of the present invention, a conductor including a region functioning as a write bit line is provided to include a region in contact with the top surface and the side surface of the first conductor. Furthermore, in the semiconductor device of one embodiment of the present invention, a conductor including a region functioning as the read bit line is provided to include a region in contact with the top surface and the side surface of the seventh conductor. Such a structure eliminates the need for additionally providing a connection electrode between the first conductor and the write bit line and the need for additionally providing a connection electrode between the seventh conductor and the read bit line. In this manner, the semiconductor device of one embodiment of the present invention can be a semiconductor device having a high integration degree of memory cells.

### <Structure Examples of Semiconductor Device>

Structure examples of the semiconductor device of one embodiment of the present invention will be described below.

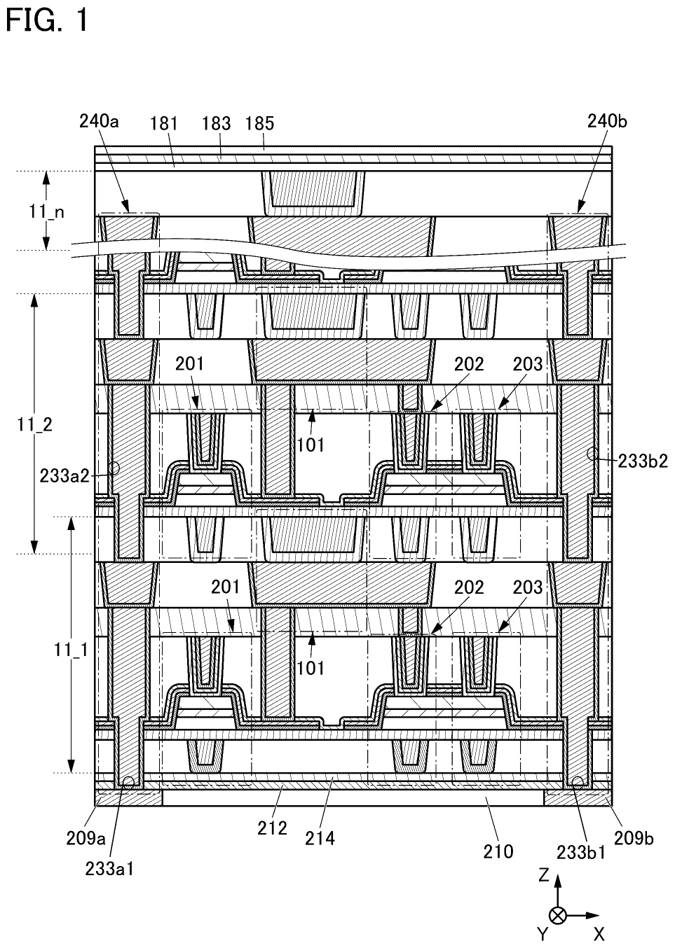

FIG. 1 is a cross-sectional view illustrating a structure example of the semiconductor device of one embodiment of the present invention. The semiconductor device illustrated in FIG. 1 includes an insulator 210 over a substrate (not illustrated), a conductor 209a and a conductor 209b embedded in the insulator 210, an insulator 212 over the insulator 210, an insulator 214 over the insulator 212, n memory layers 11 over the insulator 214, a connection electrode 240a and a connection electrode 240b each of which connects conductors included in the n layers in the Z direction (also referred to as the vertical direction) and is provided to extend in the Z direction to be electrically connected to the conductor 209, an insulator 181 over the memory layer 11_n, an insulator 183 over the insulator 181, and an insulator 185 over the insulator 183. Note that components included in the semiconductor device of this embodiment may each have either a single-layer structure or a stacked-layer structure.

In the following description of matters common to components distinguished from each other using letters of the alphabet, reference numerals without the letters of the alphabet are sometimes used. For example, in the case where matters common to the conductor 209a and the conductor 209b are described, the term “conductor 209” is used in some cases.

The memory layer 11_1 to the memory layer 11_n are each provided with a memory cell array including a plurality of memory cells. The memory cells each include a transistor 201, a transistor 202, a transistor 203, and a capacitor 101. The connection electrode 240a includes a region functioning as a write bit line, and the connection electrode 240b includes a region functioning as a read bit line.

In this specification and the like, a direction parallel to a channel length direction of a transistor illustrated is referred to as an X direction, and a direction parallel to a channel width direction of a transistor illustrated is referred to as a Y direction. The X direction and the Y direction can be perpendicular to each other. Furthermore, a direction perpendicular to both the X direction and the Y direction, i.e., a direction perpendicular to the XY plane, is referred to as a Z direction. The X direction and the Y direction can each be a direction parallel to the substrate surface, and the Z direction can be a direction perpendicular to the substrate surface, for example.

The conductor 209a and the conductor 209b each function as a wiring, an electrode, a terminal, or part of a circuit element such as a switch, a transistor, a capacitor, an inductor, a resistor, or a diode.

FIG. 1 illustrates the memory layer 11_1 that is the lowermost layer among the n memory layers, the memory layer 11_2 over the memory layer 11_1, and the memory layer 11_n that is the uppermost layer among the n memory layers.

The conductor 209a and the conductor 209b are electrically connected to driver circuits for driving the memory cells provided in the memory layers 11. The driver circuits are provided below the conductor 209a and the conductor 209b. Increasing the number of stacked memory layers 11 (the value of n) can increase the memory capacity of the memory device without an increase in the area occupied by the memory cells. Accordingly, the occupation area per bit is reduced, so that the semiconductor device can have a small size and large memory capacity.

The transistor 201, the transistor 202, and the transistor 203 are provided over the insulator 214. Here, the transistor 202 and the transistor 203 share some layers. The capacitor 101 is provided above the transistor 201 to the transistor 203.

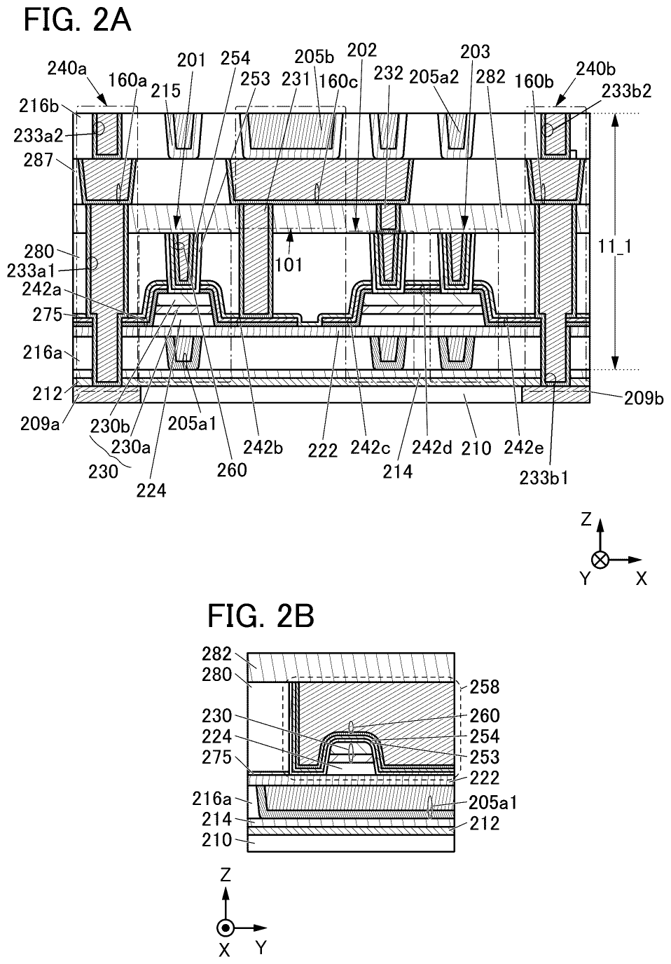

FIG. 2A is a cross-sectional view illustrating structure examples of the conductor 209a, the conductor 209b, the insulator 210, the insulator 212, the insulator 214, and the memory layer 11_1. As illustrated in FIG. 2A, an insulator 282 is provided over the transistor 201 to the transistor 203, and the capacitor 101 is provided on the insulator 282.

The transistor 201, the transistor 202, and the transistor 203 each include a conductor 205a1 over the insulator 214, an insulator 222 over the conductor 205a1, an insulator 224 over the insulator 222, a metal oxide 230 (a metal oxide 230a and a metal oxide 230b) over the insulator 224, a conductor 242 covering part of the side surface of the insulator 224 and parts of the top surface and the side surfaces of the metal oxide 230, an insulator 253 over the metal oxide 230, an insulator 254 over the insulator 253, and a conductor 260 over the insulator 254. Here, the transistor 201 includes a conductor 242a and a conductor 242b as the conductor 242, the transistor 202 includes a conductor 242c and a conductor 242d as the conductor 242, and the transistor 203 includes the conductor 242d and a conductor 242e as the conductor 242. The transistor 202 and the transistor 203 share the metal oxide 230 and the conductor 242d.

An insulator 216a provided with an opening is provided over the insulator 214, and the conductor 205a1 is embedded in the opening. The insulator 222 is provided over the conductor 205a1 and the insulator 216a. An insulator 275 is provided over the conductor 242a to the conductor 242e, and an insulator 280 is provided over the insulator 275. The insulator 253, the insulator 254, and the conductor 260 are embedded in an opening provided in the insulator 280 and the insulator 275. An insulator 282 is provided over the insulator 280 and the conductor 260. The conductor 205a1 can include a region in contact with the side surface of the insulator 216a. The insulator 253 can include a region in contact with at least parts of the side surface of the conductor 242, the side surface of the insulator 275, and the side surface of the insulator 280.

The metal oxide 230 includes a region functioning as a channel formation region of the transistor 201, the transistor 202, or the transistor 203. Note that for the transistor 201, the transistor 202, and the transistor 203, a semiconductor such as single crystal silicon, polycrystalline silicon, or amorphous silicon may be used instead of the metal oxide 230; for example, low-temperature polysilicon (LTPS) may be used.

The conductor 242a includes a region functioning as one of a source electrode and a drain electrode of the transistor 201. The conductor 242b includes a region functioning as the other of the source electrode and the drain electrode of the transistor 201. The conductor 242c includes a region functioning as one of a source electrode and a drain electrode of the transistor 202. The conductor 242d includes a region functioning as the other of the source electrode and the drain electrode of the transistor 202 and a region functioning as one of a source electrode and a drain electrode of the transistor 203. The conductor 242e includes a region functioning as the other of the source electrode and the drain electrode of the transistor 203.

The conductor 260 includes a region functioning as a first gate electrode of the transistor 201, the transistor 202, or the transistor 203. The insulator 253 and the insulator 254 each include a region functioning as a first gate insulator of the transistor 201, the transistor 202, or the transistor 203.

The conductor 205a1 includes a region functioning as a second gate electrode of the transistor 201, the transistor 202, or the transistor 203. The insulator 222 includes a region functioning as a second gate insulator of the transistor 201, a region functioning as a second gate insulator of the transistor 202, and a region functioning as a second gate insulator of the transistor 203. The insulator 224 includes a region functioning as the second gate insulator of the transistor 201, the transistor 202, or the transistor 203.

In this specification and the like, the first gate electrode can be referred to as a front gate electrode or simply as a gate electrode, and the second gate electrode can be referred to as a back gate electrode. Note that the first gate electrode may be referred to as a back gate electrode, and the second gate electrode may be referred to as a front gate electrode or simply as a gate electrode.

Thus, the two transistors (the transistor 202 and the transistor 203) can be formed in an area smaller than the area of two transistors (e.g., in the area of one and a half transistors). The transistor 202 and the transistor 203 are adjacent to each other and share the metal oxide 230 and the conductor 242d as described above. This enables the transistors to be arranged at high density as compared with the case where the transistor 202 and the transistor 203 do not share the metal oxide 230 and the conductor 242d; hence, high integration in the semiconductor device can be achieved.

The conductor 242d is placed in a region between the conductor 260 included in the transistor 202 and the conductor 260 included in the transistor 203. Thus, an n-type region (low-resistance region) can be formed in a region of the metal oxide 230 that overlaps with the conductor 242d. Specifically, the n-type region can be formed in a region of the metal oxide 230b that overlaps with the conductor 242d. Moreover, current can flow between the transistor 202 and the transistor 203 through the conductor 242d. Thus, the resistance component between the transistor 202 and the transistor 203 can be significantly reduced as compared with a structure in which two transistors using silicon in their semiconductor layers where channels are formed (also referred to as Si transistors) are connected in series.

The capacitor 101 includes a conductor 160c over the insulator 282, an insulator 215 over the conductor 160c, and a conductor 205b over the insulator 215.

An insulator 287 is provided over the insulator 282. Openings are provided in the insulator 287, and a conductor 160a, a conductor 160b, and the conductor 160c (they may be collectively referred to as a conductor 160) are embedded in the openings. An insulator 216b is provided over the conductor 160 and the insulator 287. Openings are provided in the insulator 216b, and the insulator 215, a conductor 205a2, and the conductor 205b are embedded in the openings. The conductor 160 can include a region in contact with part of the side surface of the insulator 287. Note that the opening provided in the insulator 216b includes a region where the top surface of the conductor 160c is exposed, the insulator 215 is provided over the exposed conductor 160c, and the conductor 205b is provided over the insulator 215.

Hereinafter, in the case where matters common to the conductor 205a1 and the conductor 205a2 are described, the term “conductor 205a” is used in some cases. In addition, in the case where matters common to the conductor 205a and the conductor 205b are described, the term “conductor 205” is used in some cases.

The conductor 160c includes a region functioning as one electrode (also referred to as a lower electrode) of the capacitor 101. The insulator 215 includes a region functioning as a dielectric of the capacitor 101. The conductor 205b includes a region functioning as the other electrode (also referred to as an upper electrode) of the capacitor 101. The capacitor 101 forms a MIM (Metal-Insulator-Metal) capacitor.

An opening reaching the conductor 242b is provided in the insulator 275, the insulator 280, and the insulator 282, and a conductor 231 is embedded in the opening. An opening reaching the conductor 260 included in the transistor 202 is provided in the insulator 282, and a conductor 232 is provided in the opening. The conductor 242b and the conductor 160c are electrically connected to each other through the conductor 231. The conductor 260 included in the transistor 202 and the conductor 160c are electrically connected to each other through the conductor 232. In this manner, the conductor 242b including the region functioning as the other of the source electrode and the drain electrode of the transistor 201 is electrically connected to the conductor 260 including the region functioning as the gate electrode of the transistor 202 through the conductor 231, the conductor 160c, and the conductor 232. The conductor 160c includes regions in contact with the top surface of the conductor 231 and the top surface of the conductor 232.

An opening reaching the conductor 209a is provided in the insulator 212, the insulator 214, the insulator 216a, the insulator 222, the insulator 275, the insulator 280, and the insulator 282, and a conductor 233a1 is embedded in the opening. An opening reaching the conductor 160a is provided in the insulator 216b, and a conductor 233a2 is embedded in the opening. Thus, it can be said that the conductor 233a1 includes a region in contact with any one or more side surfaces of the insulator 212, the insulator 214, the insulator 216a, the insulator 222, the insulator 275, the insulator 280, and the insulator 282. It can also be said that the conductor 233a2 includes a region in contact with the side surface of the insulator 216b.

In other words, it can be said that the conductor 233a1 includes a portion positioned inside one or more of the opening in the insulator 212, the opening in the insulator 214, the opening in the insulator 216a, the opening in the insulator 222, the opening in the insulator 275, the opening in the insulator 280, and the opening in the insulator 282. It can also be said that the conductor 233a2 includes a portion positioned inside the opening in the insulator 216b.

An opening reaching the conductor 209b is provided in the insulator 212, the insulator 214, the insulator 216a, the insulator 222, the insulator 275, the insulator 280, and the insulator 282, and a conductor 233b1 is embedded in the opening. An opening reaching the conductor 160b is provided in the insulator 216b, and a conductor 233b2 is embedded in the opening. Thus, it can be said that the conductor 233b1 includes a region in contact with any one or more side surfaces of the insulator 212, the insulator 214, the insulator 216a, the insulator 222, the insulator 275, the insulator 280, and the insulator 282. It can also be said that the conductor 233b2 includes a region in contact with the side surface of the insulator 216b.

In other words, it can be said that the conductor 233b1 includes a portion positioned inside one or more of the opening in the insulator 212, the opening in the insulator 214, the opening in the insulator 216a, the opening in the insulator 222, the opening in the insulator 275, the opening in the insulator 280, and the opening in the insulator 282. It can also be said that the conductor 233b2 includes a portion positioned inside the opening in the insulator 216b.

The top surface of the conductor 209a includes a region in contact with the conductor 233al. The top surface of the conductor 233a1 includes a region in contact with the conductor 160a. The top surface of the conductor 160a includes a region in contact with the conductor 233a2. In this manner, the connection electrode 240a includes the conductor 233a1 and the conductor 160a. Note that the connection electrode 240a in the range illustrated in FIG. 2 may be expressed as including the conductor 233a1, the conductor 160a, and the conductor 233a2.

The top surface of the conductor 209b includes a region in contact with the conductor 233b1. The top surface of the conductor 233b1 includes a region in contact with the conductor 160b. The top surface of the conductor 160b includes a region in contact with the conductor 233b2. In this manner, the connection electrode 240b includes the conductor 233b1 and the conductor 160b. Note that the connection electrode 240b in the range illustrated in FIG. 2 may be expressed as including the conductor 233b1, the conductor 160b, and the conductor 233b2. As described above and illustrated in FIG. 2A, the top surface of the conductor 231, the top surface of the conductor 232, the top surface of the conductor 233a1, and the top surface of the conductor 233b1 are level or substantially level with each other.

The conductor 242a, the conductor 242b, the conductor 242c, and the conductor 242e extend beyond the metal oxide 230 functioning as a semiconductor layer and cover parts of the top surface and the side surfaces of the metal oxide 230. Thus, the conductor 242a, the conductor 242b, the conductor 242c, and the conductor 242e also function as wirings. The connection electrode 240a including a region functioning as a write bit line is provided to include a region in contact with parts of the top surface and the side surface of the conductor 242a, for example. The connection electrode 240b including a region functioning as a read bit line is provided to include a region in contact with parts of the top surface and the side surface of the conductor 242e. Note that the conductor 242d can also function as a wiring. Another wiring can also function as a wiring in some cases.

Since the connection electrode 240a includes the region in contact with parts of the top surface and the side surface of the conductor 242a and the connection electrode 240b includes the region in contact with parts of the top surface and the side surface of the conductor 242e, a connection electrode does not need to be provided additionally; thus, the area occupied by the memory cell array can be reduced. In addition, the integration degree of the memory cells can be increased and the memory capacity can be increased. When the connection electrode 240a is in contact with a plurality of surfaces of the conductor 242a, the contact resistance between the connection electrode 240a and the conductor 242a can be reduced; when the connection electrode 240b is in contact with a plurality of surfaces of the conductor 242e, the contact resistance between the connection electrode 240b and the conductor 242e can be reduced.

FIG. 2B is a cross-sectional view illustrating a structure example of the transistor illustrated in FIG. 2A in the channel width direction, i.e., in the Y direction.

In the example illustrated in FIG. 2B, the insulator 212 is provided over the insulator 210, the insulator 214 is provided over the insulator 212, the insulator 216a is provided over the insulator 214, and the conductor 205a1 is provided in the opening provided in the insulator 216a. The insulator 222 is provided over the conductor 205a1 and the insulator 216a, the insulator 224 and the insulator 275 are provided over the insulator 222, and the metal oxide 230 is provided over the insulator 224. The side surface of the insulator 224 and the top surface and the side surface of the metal oxide 230 are covered with the insulator 253, the insulator 254, and the conductor 260. The insulator 253, the insulator 254, and the conductor 260 are provided in an opening 258 formed in the insulator 280 over the insulator 275. The insulator 282 is provided over the insulator 253, the insulator 254, the conductor 260, and the insulator 280.

Here, the conductor 260 including the region functioning as the first gate electrode can be regarded as covering not only the top surface but also the side surfaces of the metal oxide 230.

In this specification and the like, a transistor structure in which a channel formation region is electrically surrounded by at least the electric field of a first gate electrode is referred to as a surrounded channel (S-channel) structure. The S-channel structure disclosed in this specification and the like has a structure that is different from a Fin-type structure and a planar structure. The S-channel structure disclosed in this specification and the like can be regarded as a kind of the Fin-type structure. Note that in this specification and the like, the Fin-type structure refers to a structure in which a gate electrode is placed to cover at least two or more surfaces (specifically, two surfaces, three surfaces, or four surfaces) of a channel. With use of the Fin-type structure and the S-channel structure, a transistor with high resistance to a short-channel effect, i.e., a transistor in which a short-channel effect is unlikely to occur, can be obtained.

When the transistor included in the semiconductor device of this embodiment has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having the S-channel structure, the GAA structure, or the LGAA structure, the channel formation region that is formed at the interface between an oxide and a gate insulator or in the vicinity of the interface can be the entire bulk of the metal oxide. Accordingly, the density of current flowing through the transistor can be improved, which can be expected to improve the on-state current of the transistor or increase the field-effect mobility of the transistor.

Although FIG. 2B illustrates a transistor with the S-channel structure as the transistor, the semiconductor device of one embodiment of the present invention is not limited thereto. For example, a transistor structure that can be used in one embodiment of the present invention may be one or more selected from the planar structure, the Fin-type structure, and the GAA structure.

Note that the cross-sectional shape of the metal oxide 230 is not limited to the structure illustrated in FIG. 2B. For example, the metal oxide 230 may have a curved surface between its side surface and its top surface. In that case, coverage with a film formed over the metal oxide 230 can be improved.

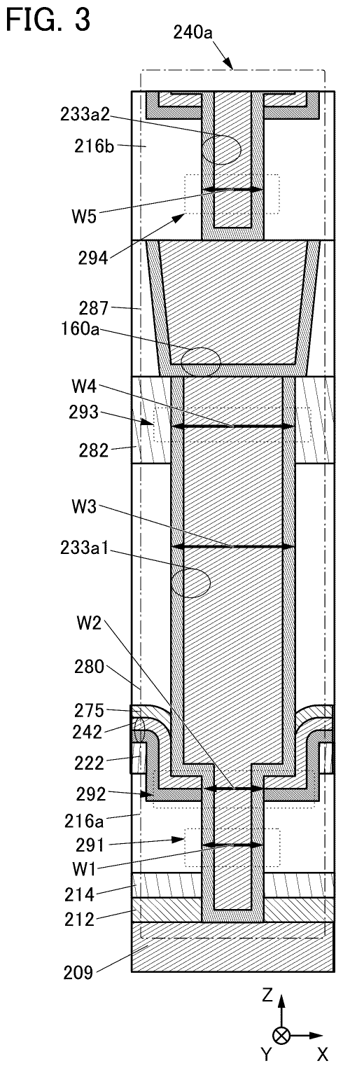

FIG. 3 is an enlarged view of part of the connection electrode 240a and its peripheral region in FIG. 2A. In FIG. 3, in the conductor 233a1 included in the connection electrode 240a, the width of a region in contact with the side surface of the insulator 216a is denoted by a width W1, the width of a region in contact with the side surface of the conductor 242 is denoted by a width W2, the width of a region in contact with the side surface of the insulator 280 is denoted by a width W3, the width of a region in contact with the side surface of the insulator 282 is denoted by a width W4, and the width of a region in contact with the side surface of the insulator 216b is denoted by a width W5. In other words, the width of an opening 291 in the insulator 216a can be denoted by the width W1, the width of an opening 292 in the conductor 242 can be denoted by the width W2, the width of an opening 293 in the insulator 282 can be denoted by the width W4, and the width of an opening 294 in the insulator 216b can be denoted by the width W5.

As illustrated in FIG. 3, at least some of the width W1, the width W3, the width W4, and the width W5 are preferably larger than the width W2 in a cross-sectional view. In this structure, the connection electrode 240a is in contact with at least part of the top surface and part of the side surface of the conductor 242. Thus, the area of the region where the connection electrode 240a and the conductor 242 are in contact with each other can be increased. Note that in this specification and the like, the contact between the connection electrode 240a and the conductor 242 is referred to as a top-side contact in some cases. As illustrated in FIG. 3, the connection electrode 240a may be in contact with part of the bottom surface of the conductor 242. This structure enables the area of the region where the connection electrode 240a and the conductor 242 are in contact with each other to be further increased.

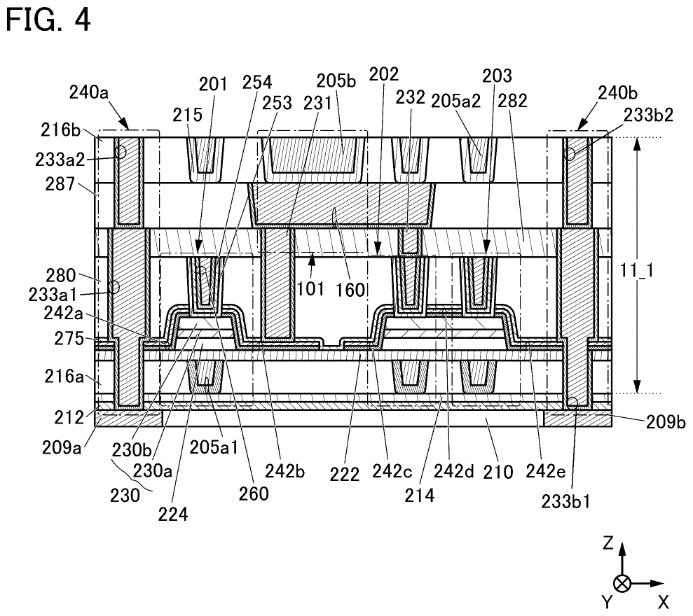

FIG. 4 illustrates a variation example of the structure illustrated in FIG. 2A, in which the connection electrode 240a does not include the conductor 160a and the connection electrode 240b does not include the conductor 160b.

In FIG. 4, an opening reaching the conductor 233a1 is provided in the insulator 287 and the insulator 216b, and the conductor 233a2 is embedded in the opening. An opening reaching the conductor 233b1 is provided in the insulator 287 and the insulator 216b, and the conductor 233b2 is embedded in the opening.

Next, the transistors included in the semiconductor device of this embodiment will be described in detail.

The metal oxide 230 preferably includes the metal oxide 230a over the insulator 224 and the metal oxide 230b over the metal oxide 230a. The metal oxide 230a under the metal oxide 230b can inhibit diffusion of impurities into the metal oxide 230b from the components formed below the metal oxide 230a.

Although an example in which the metal oxide 230 has a two-layer structure of the metal oxide 230a and the metal oxide 230b is described in this embodiment, the present invention is not limited thereto. For example, the metal oxide 230 may have a single-layer structure of the metal oxide 230b or a stacked-layer structure of three or more layers.

The metal oxide 230b includes a channel formation region of each transistor and a source region and a drain region provided to sandwich the channel formation region. At least part of the channel formation region overlaps with the conductor 260. The source region overlaps with one of a pair of conductors 242, and the drain region overlaps with the other of the pair of conductors 242.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration in the metal oxide 230b, the impurity concentration in the metal oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or metal oxide) having a low carrier concentration may be referred to as a highly purified intrinsic or substantially highly purified intrinsic oxide semiconductor (or metal oxide).

In order to obtain stable electrical characteristics of the transistor, reducing the impurity concentration in the metal oxide 230b is effective. In order to reduce the impurity concentration in the metal oxide 230b, the impurity concentration in an adjacent film is also preferably reduced. Examples of impurities include hydrogen, nitrogen, an alkali metal, an alkaline earth metal, iron, nickel, and silicon. Note that an impurity in the metal oxide 230b refers to, for example, an element other than the main components of the metal oxide 230b. For example, an element with a concentration lower than 0.1 atomic % can be regarded as an impurity.

Note that the channel formation region, the source region, and the drain region may each be formed not only in the metal oxide 230b but also in the metal oxide 230a.

In the metal oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter also referred to as an oxide semiconductor) is preferably used as the metal oxide 230.

The metal oxide functioning as a semiconductor preferably has a band gap of 2 eV or higher, further preferably 2.5 eV or higher. With use of a metal oxide having a wide bandgap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

The metal oxide 230 preferably has a stacked-layer structure of a plurality of oxide layers with different chemical compositions. For example, the atomic ratio of the element M to a metal element that is a main component of the metal oxide used as the metal oxide 230a is preferably greater than the atomic ratio of the element M to a metal element that is a main component of the metal oxide used as the metal oxide 230b. Moreover, the atomic ratio of the element M to In in the metal oxide used as the metal oxide 230a is preferably greater than the atomic ratio of the element M to In in the metal oxide used as the metal oxide 230b. With this structure, impurities and oxygen can be inhibited from diffusing into the metal oxide 230b from the components formed below the metal oxide 230a.

Furthermore, the atomic ratio of In to the element M in the metal oxide used as the metal oxide 230b is preferably greater than the atomic ratio of In to the element M in the metal oxide used as the metal oxide 230a. With this structure, the transistor can have a high on-state current and high frequency characteristics.

When the metal oxide 230a and the metal oxide 230b contain a common element as the main component besides oxygen, the density of defect states at an interface between the metal oxide 230a and the metal oxide 230b can be decreased. Thus, the influence of interface scattering on carrier conduction is small, and the transistor can have a high on-state current and high frequency characteristics.

Specifically, as the metal oxide 230a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. As the metal oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. In the case where a single layer of the metal oxide 230b is provided as the metal oxide 230, a metal oxide that can be used as the metal oxide 230a may be used as the metal oxide 230b. The compositions of the metal oxides that can be used as the metal oxide 230a and the metal oxide 230b are not limited to the above. For example, the composition of the metal oxide that can be used as the metal oxide 230a can be applied to the metal oxide 230b. Similarly, the composition of the metal oxide that can be used as the metal oxide 230b can be applied to the metal oxide 230a.

When the metal oxide is deposited by a sputtering method, the above atomic ratio is not limited to the atomic ratio of the deposited metal oxide and may be the atomic ratio of a sputtering target used for depositing the metal oxide.

The metal oxide 230b preferably has crystallinity. It is particularly preferable to use a CAAC-OS (c-axis aligned crystalline oxide semiconductor) as the metal oxide 230b.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

When an oxide having crystallinity, such as CAAC-OS, is used as the metal oxide 230b, oxygen extraction from the metal oxide 230b by the source electrode or the drain electrode can be inhibited. This can reduce oxygen extraction from the metal oxide 230b even when heat treatment is performed; thus, the transistor is stable with respect to high temperatures in a manufacturing process (what is called thermal budget).

A transistor using an oxide semiconductor is likely to have its electrical characteristics changed by impurities and oxygen vacancies in a region of the oxide semiconductor where a channel is formed, which might affect the reliability. In some cases, a defect that is an oxygen vacancy into which hydrogen in the vicinity of the oxygen vacancy has entered (hereinafter sometimes referred to as VoH) is formed, which generates an electron serving as a carrier. Therefore, when the region of the oxide semiconductor where a channel is formed includes oxygen vacancies, the transistor is likely to have normally-on characteristics (characteristics with which, even when no voltage is applied to the gate electrode, the channel exists and current flows through the transistor). Therefore, impurities, oxygen vacancies, and VoH are preferably reduced as much as possible in the region of the oxide semiconductor where a channel is formed. In other words, the region of the oxide semiconductor where a channel is formed is preferably an i-type (intrinsic) or substantially i-type region with a reduced carrier concentration.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and VoH in the channel formation region of the oxide semiconductor are preferably reduced. Supply of an excess amount of oxygen to the source region and the drain region and excessive reduction in the amount of VoH in the source region and the drain region are preferably inhibited. Furthermore, a structure is preferable in which a reduction in the conductivity of the conductor 260, the conductor 242, and the like is inhibited. For example, a structure is preferable in which oxidation of the conductor 260, the conductor 242, and the like is inhibited. Note that hydrogen in the oxide semiconductor can form VoH; thus, the hydrogen concentration needs to be reduced in order to reduce the amount of VoH.

The semiconductor device of this embodiment thus has a structure in which the hydrogen concentration in the channel formation region is reduced, oxidation of the conductor 242 and the conductor 260 is inhibited, and a reduction in the hydrogen concentration in the source region and the drain region is inhibited.

The insulator 253 in contact with the channel formation region of the metal oxide 230b preferably has a function of capturing hydrogen and fixing hydrogen. In that case, the hydrogen concentration in the channel formation region of the metal oxide 230b can be reduced. Accordingly, VoH in the channel formation region can be reduced, so that the channel formation region can be an i-type or substantially i-type region.

Examples of insulators having a function of capturing hydrogen and fixing hydrogen include a metal oxide having an amorphous structure. As the insulator 253, for example, a metal oxide, such as magnesium oxide or an oxide containing one or both of aluminum and hafnium, is preferably used. In such a metal oxide having an amorphous structure, an oxygen atom has a dangling bond and sometimes has a property of capturing hydrogen and fixing hydrogen with the dangling bond. That is, the metal oxide having an amorphous structure has high capability of capturing hydrogen and fixing hydrogen.

A high dielectric constant (high-k) material is preferably used for the insulator 253. An example of the high-k material is an oxide containing one or both of aluminum and hafnium. With the use of the high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, an oxide containing one or both of aluminum and hafnium is preferably used, further preferably, an oxide containing one or both of aluminum and hafnium and having an amorphous structure is used, and still further preferably, hafnium oxide having an amorphous structure is used. In this embodiment, hafnium oxide is used for the insulator 253. In this case, the insulator 253 is an insulator that contains at least oxygen and hafnium. The hafnium oxide has an amorphous structure. In this case, the insulator 253 has an amorphous structure.

Alternatively, an insulator having a thermally stable structure, such as silicon oxide or silicon oxynitride, may be used as the insulator 253. For example, the insulator 253 may have a stacked-layer structure including aluminum oxide and silicon oxide or silicon oxynitride over the aluminum oxide. As another example, the insulator 253 may have a stacked-layer structure including aluminum oxide, silicon oxide or silicon oxynitride over the aluminum oxide, and hafnium oxide over the silicon oxide or the silicon oxynitride.

In order to inhibit oxidation of the conductor 242 and the conductor 260, a barrier insulator against oxygen is preferably provided in the vicinity of each of the conductor 242 and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 preferably has a single-layer structure or a stacked-layer structure of the barrier insulator against oxygen.

The insulator 253 preferably has a barrier property against oxygen. Oxygen is less likely to pass through the insulator 253 than at least the insulator 280. The insulator 253 includes a region in contact with the side surface of the conductor 242. When the insulator 253 has a barrier property against oxygen, oxidation of the side surface of the conductor 242 and formation of an oxide film on the side surface can be inhibited. Accordingly, a decrease in the on-state current or field-effect mobility of the transistor can be inhibited.

The insulator 253 is provided in contact with the top surface and the side surface of the metal oxide 230b, the side surface of the metal oxide 230a, the side surface of the insulator 224, and the top surface of the insulator 222. When the insulator 253 has a barrier property against oxygen, release of oxygen from the channel formation region of the metal oxide 230b caused by heat treatment can be inhibited, for example. This can reduce formation of oxygen vacancies in the metal oxide 230a and the metal oxide 230b.

Even when an excess amount of oxygen is contained in the insulator 280, by contrast, oxygen can be inhibited from being excessively supplied to the metal oxide 230a and the metal oxide 230b. Thus, it is possible to inhibit excessive oxidation of the source region and the drain region and a decrease in the on-state current or field-effect mobility of the transistor.

The oxide containing one or both of aluminum and hafnium has a barrier property against oxygen and thus can be suitably used for the insulator 253.

The insulator 254 preferably has a barrier property against oxygen. The insulator 254 is provided between the conductor 260 and the channel formation region of the metal oxide 230 and between the insulator 280 and the conductor 260. Such a structure can inhibit diffusion of oxygen contained in the channel formation region of the metal oxide 230 into the conductor 260 and formation of oxygen vacancies in the channel formation region of the metal oxide 230. Oxygen contained in the metal oxide 230 and oxygen contained in the insulator 280 can be inhibited from diffusing into the conductor 260 and oxidizing the conductor 260. Oxygen is less likely to pass through the insulator 254 than at least the insulator 280. For example, silicon nitride is preferably used for the insulator 254. In that case, the insulator 254 is an insulator that contains at least nitrogen and silicon.

The insulator 254 preferably has a barrier property against hydrogen. In that case, diffusion of impurities contained in the conductor 260, such as hydrogen, into the metal oxide 230b can be prevented.

The insulator 275 preferably has a barrier property against oxygen. The insulator 275 is provided between the insulator 280 and the conductor 242. With this structure, oxygen contained in the insulator 280 can be inhibited from diffusing into the conductor 242. Thus, the conductor 242 can be inhibited from being oxidized by oxygen contained in the insulator 280, so that an increase in resistivity and a reduction in on-state current can be inhibited. Oxygen is less likely to pass through the insulator 275 than at least the insulator 280. For example, silicon nitride is preferably used for the insulator 275. In that case, the insulator 275 is an insulator that contains at least nitrogen and silicon.

In order to inhibit a reduction in hydrogen concentration in the source region and the drain region in the metal oxide 230, a barrier insulator against hydrogen is preferably provided in the vicinity of each of the source region and the drain region. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

The insulator 275 preferably has a barrier property against hydrogen. When the insulator 275 has a barrier property against hydrogen, capturing and fixing of hydrogen in the source region and the drain region by the insulator 253 can be inhibited. Thus, the source region and the drain region can be n-type regions.

With the above structure, the channel formation region can be an i-type or substantially i-type region, and the source region and the drain region can be n-type regions. Thus, a semiconductor device with favorable electrical characteristics can be provided. The semiconductor device with the above structure can have favorable electrical characteristics even when miniaturized or highly integrated. Miniaturization of the transistor can improve the high frequency characteristics. Specifically, the cutoff frequency can be improved.

The insulator 253 and the insulator 254 each function as part of the gate insulator. The insulator 253 and the insulator 254 are provided together with the conductor 260 in an opening formed in the insulator 280 and the like. The thickness of the insulator 253 and the thickness of the insulator 254 are preferably small for scaling down of the transistor. The thickness of the insulator 253 is preferably greater than or equal to 0.1 nm and less than or equal to 5.0 nm, further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. The thickness of the insulator 254 is preferably greater than or equal to 0.1 nm and less than or equal to 5.0 nm, further preferably greater than or equal to 0.5 nm and less than or equal to 3.0 nm, still further preferably greater than or equal to 1.0 nm and less than or equal to 3.0 nm. Note that at least part of each of the insulator 253 and the insulator 254 includes a region having the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 253 can be formed on the side surface of the opening portion formed in the insulator 280 and the like, the side end portion of the conductor 242, and the like, with a small thickness like the above-described thickness and good coverage.

Note that some of precursors usable in an ALD method contain carbon, for example. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

For example, silicon nitride deposited by a PEALD method can be used for the insulator 254.

Note that when an insulator having a function of inhibiting passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

In addition to the above structure, the semiconductor device of this embodiment preferably has a structure in which hydrogen is inhibited from entering the transistor. For example, one or both of upper and lower insulators having a function of inhibiting diffusion of hydrogen is/are preferably provided to cover the transistor. In the semiconductor device described in this embodiment, the insulator is, for example, the insulator 212.

As the insulator 212, an insulator having a function of inhibiting diffusion of hydrogen is preferably used. In that case, diffusion of hydrogen into the transistor from below the insulator 212 can be inhibited. As the insulator 212, the above-described insulator that can be used for the insulator 275 can be used.

One or more of the insulator 212, the insulator 214, and the insulator 282 preferably function as a barrier insulating film, which inhibits diffusion of impurities such as water and hydrogen into the transistor from the substrate side or from above the transistor. Thus, one or more of the insulator 212, the insulator 214, and the insulator 282 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, an insulating material having a function of inhibiting diffusion of oxygen (e.g., at least one of an oxygen atom, an oxygen molecule, and the like) (an insulating material through which the oxygen is less likely to pass) is preferably contained.

The insulator 212, the insulator 214, and the insulator 282 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a higher hydrogen barrier property, is preferably used for the insulator 212. The insulator 282 and the like may have a single-layer structure or a stacked-layer structure. As an example of the stacked-layer structure, an insulator in which aluminum oxide and silicon nitride are stacked in this order or an insulator in which hafnium oxide and silicon nitride are stacked in this order can be used. For example, the insulator 212, the insulator 214, and the insulator 282 each preferably contain aluminum oxide, magnesium oxide, or the like, which has a function of capturing and fixing hydrogen well. In that case, impurities such as water and hydrogen can be inhibited from diffusing into the transistor side from the substrate side through the insulator 212 and the insulator 214. Alternatively, impurities such as water and hydrogen can be inhibited from diffusing into the transistor side from an interlayer insulating film and the like which are placed outside the insulator 282. Alternatively, oxygen contained in the insulator 224 and the like can be inhibited from diffusing to the substrate side. Alternatively, oxygen contained in the insulator 280 and the like can be inhibited from diffusing to the components above the transistor through the insulator 282 and the like. In this manner, it is preferable that the transistor be surrounded by upper and lower insulators having a function of inhibiting diffusion of oxygen and impurities such as water and hydrogen.

The conductor 205a is placed to overlap with the metal oxide 230 and the conductor 260. Here, the conductor 205a is preferably provided to be embedded in an opening portion formed in the insulator 216a. Part of the conductor 205a is embedded in the insulator 214 in some cases.

The conductor 205a may have a single-layer structure or a stacked-layer structure. For example, FIG. 2A illustrates an example in which the conductor 205a1 has a two-layer stacked structure of a first conductor and a second conductor. The first conductor of the conductor 205a1 is provided in contact with the bottom surface and sidewall of the opening portion provided in the insulator 216a. The second conductor of the conductor 205a1 is provided to be embedded in a depressed portion defined by the first conductor of the conductor 205al. Here, the top surface of the second conductor of the conductor 205a1 is substantially level with the top surface of the first conductor of the conductor 205a1 and the top surface of the insulator 216a.

Here, the first conductor of the conductor 205a1 preferably contains a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to contain a conductive material having a function of inhibiting diffusion of oxygen (e.g., at least one of an oxygen atom, an oxygen molecule, and the like).

When a conductive material having a function of inhibiting diffusion of hydrogen is used for the first conductor of the conductor 205a1, impurities such as hydrogen contained in the second conductor of the conductor 205a1 can be prevented from diffusing into the metal oxide 230 through the insulator 216a, the insulator 224, and the like. When a conductive material having a function of inhibiting diffusion of oxygen is used for the first conductor of the conductor 205al, the conductivity of the second conductor of the conductor 205a1 can be inhibited from being lowered because of oxidation. Examples of the conductive material having a function of inhibiting diffusion of oxygen include titanium, titanium nitride, tantalum, tantalum nitride, ruthenium, and ruthenium oxide. The first conductor of the conductor 205a1 can have a single-layer structure or a stacked-layer structure of the above conductive material. For example, the first conductor of the conductor 205a1 preferably contains titanium nitride.

A conductive material containing tungsten, copper, or aluminum as its main component is preferably used for the second conductor of the conductor 205al. For example, the second conductor of the conductor 205a1 preferably contains tungsten.

The conductor 205a1 can function as the second gate electrode. In that case, by changing a potential applied to the conductor 205a1 not in conjunction with but independently of a potential applied to the conductor 260, the threshold voltage (Vth) of the transistor can be controlled. In particular, by applying a negative potential to the conductor 205a1, Vth of the transistor can be higher, and the off-state current can be reduced. Thus, a drain current at the time when a potential applied to the conductor 260 is 0 V can be lower in the case where a negative potential is applied to the conductor 205a1 than in the case where the negative potential is not applied to the conductor 205a1.

The electrical resistivity of the conductor 205a1 is designed in consideration of the potential applied to the conductor 205al, and the thickness of the conductor 205a1 is set in accordance with the electrical resistivity. The thickness of the insulator 216a is substantially equal to that of the conductor 205a1. Here, the conductor 205a1 and the insulator 216a are preferably as thin as possible in the allowable range of the design of the conductor 205a1. When the thickness of the insulator 216a is reduced, the amount of impurities such as hydrogen contained in the insulator 216a can be reduced, thereby reducing the amount of the impurities diffused into the metal oxide 230 from the insulator 216a.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen as compared to the insulator 224.

The insulator 222 preferably includes an insulator containing an oxide of one or both of aluminum and hafnium, which is an insulating material. For the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. In the case where the insulator 222 is formed using such a material, the insulator 222 functions as a layer that inhibits release of oxygen from the metal oxide 230 to the substrate side and diffusion of impurities such as hydrogen from the periphery of the transistor into the metal oxide 230. Thus, providing the insulator 222 can inhibit diffusion of impurities such as hydrogen into the transistor and inhibit generation of oxygen vacancies in the metal oxide 230. Moreover, the first conductor of the conductor 205a1 can be inhibited from reacting with oxygen contained in the insulator 224 and the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, these insulators may be subjected to nitriding treatment. A stack of silicon oxide, silicon oxynitride, or silicon nitride over the above insulators may be used for the insulator 222.

For example, the insulator 222 may have a single-layer structure or a stacked-layer structure of an insulator(s) containing what is called a high-k material such as aluminum oxide, hafnium oxide, tantalum oxide, zirconium oxide, or hafnium zirconium oxide. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) can be used for the insulator 222 in some cases.

The insulator 224 that is in contact with the oxide 230 preferably contains silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is less likely to be oxidized or a conductive material having a function of inhibiting diffusion of oxygen is preferably used for each of the conductor 242 and the conductor 260. Examples of the conductive material include a conductive material containing nitrogen and a conductive material containing oxygen. This can inhibit a reduction in the conductivity of the conductor 242 and the conductor 260. In the case where a conductive material containing metal and nitrogen is used for the conductor 242 and the conductor 260, the conductor 242 and the conductor 260 are conductors that contain at least metal and nitrogen.

The conductor 242 may have a single-layer structure or a stacked-layer structure. The conductor 260 may have a single-layer structure or a stacked-layer structure.

For example, the conductor 242 illustrated in FIG. 2A has a two-layer structure of a first conductor and a second conductor over the first conductor. In that case, for the first conductor of the conductor 242 in contact with the metal oxide 230b, it is preferable to use a conductive material that is not easily oxidized or a conductive material having a function of inhibiting oxygen diffusion. This can inhibit a reduction in the conductivity of the conductor 242. For the first conductor of the conductor 242, a material that is likely to absorb (extract) hydrogen is preferably used, in which case the hydrogen concentration in the metal oxide 230 can be reduced.

The second conductor of the conductor 242 preferably has higher conductivity than the first conductor of the conductor 242. For example, the thickness of the second conductor of the conductor 242 is preferably larger than that of the first conductor of the conductor 242.

For example, tantalum nitride or titanium nitride can be used for the first conductor of the conductor 242, and tungsten can be used for the second conductor of the conductor 242.

To inhibit a reduction in the conductivity of the conductor 242, an oxide having crystallinity, such as a CAAC-OS, is preferably used as the metal oxide 230b. Specifically, a metal oxide containing indium, zinc, and one or more selected from gallium, aluminum, and tin is preferably used. When a CAAC-OS is used, oxygen extraction from the metal oxide 230b by the conductor 242 can be inhibited. Furthermore, it is possible to inhibit a reduction in the conductivity of the conductor 242.

As the conductor 242, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

The thickness of the conductor 242 is preferably greater than or equal to 10 nm and less than or equal to 200 nm, further preferably greater than or equal to 10 nm and less than or equal to 100 nm, further preferably greater than or equal to 10 nm and less than or equal to 50 nm, still further preferably greater than or equal to 10 nm and less than or equal to 30 nm, yet still further preferably greater than or equal to 15 nm and less than or equal to 25 nm. In the case where the conductor 242 has a two-layer structure of a first conductor and a second conductor over the first conductor, the thickness of the first conductor is preferably greater than or equal to 1 nm and less than or equal to 20 nm, further preferably greater than or equal to 1 nm and less than or equal to 15 nm, still further preferably greater than or equal to 2 nm and less than or equal to 10 nm, yet still further preferably greater than or equal to 3 nm and less than or equal to 7 nm.

In the case where the conductor 242 is also used as a wiring, the conductor 242 is preferably provided as thick as possible to reduce the wiring resistance. For example, the thickness of the conductor 242 is preferably greater than or equal to 1% and less than or equal to 10%, further preferably greater than or equal to 1% and less than or equal to 20%, further preferably greater than or equal to 1% and less than or equal to 30%, further preferably greater than or equal to 1% and less than or equal to 40%, further preferably greater than or equal to 1% and less than or equal to 50%, further preferably greater than or equal to 1% and less than or equal to 60%, further preferably greater than or equal to 1% and less than or equal to 70%, further preferably greater than or equal to 1% and less than or equal to 80%, still further preferably greater than or equal to 1% and less than or equal to 90%, yet still further preferably greater than or equal to 1% and less than or equal to 95% of the difference between the level of the top surface of the insulator 280 and the level of the top surface of the metal oxide 230. Also in that case, when the conductor 242 has the two-layer structure of the first conductor and the second conductor over the first conductor, the thickness of the first conductor is preferably greater than or equal to 1 nm and less than or equal to 20 nm, further preferably greater than or equal to 1 nm and less than or equal to 15 nm, still further preferably greater than or equal to 2 nm and less than or equal to 10 nm, yet still further preferably greater than or equal to 3 nm and less than or equal to 7 nm.

Note that hydrogen contained in, for example, the metal oxide 230b diffuses into the conductor 242 in some cases. In particular, when a nitride containing tantalum is used for the conductor 242, hydrogen contained in, for example, the metal oxide 230b is likely to diffuse into the conductor 242, and the diffused hydrogen is bonded to nitrogen contained in the conductor 242 in some cases. That is, hydrogen contained in, for example, the metal oxide 230b is absorbed by the conductor 242 in some cases.

The top surface of the conductor 260 is placed to be substantially level with the uppermost portion of the insulator 254, the uppermost portion of the insulator 253, and the top surface of the insulator 280.

The conductor 260 functions as the first gate electrode of the transistor. The conductor 260 preferably includes a first conductor and a second conductor over the first conductor. For example, the first conductor of the conductor 260 is preferably placed to cover the bottom surface and the side surface of the second conductor of the conductor 260.

For example, in FIG. 2A, the conductor 260 has a two-layer structure. In this case, a conductive material that is less likely to be oxidized or a conductive material having a function of inhibiting diffusion of oxygen is preferably used for the first conductor of the conductor 260.

For the first conductor of the conductor 260, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

In addition, when the first conductor of the conductor 260 has a function of inhibiting diffusion of oxygen, the conductivity of the second conductor of the conductor 260 can be inhibited from being lowered because of oxidation due to oxygen contained in the insulator 280, for example. As the conductive material having a function of inhibiting diffusion of oxygen, for example, titanium, titanium nitride, tantalum, tantalum nitride, ruthenium, or ruthenium oxide is preferably used.

As the conductor 260, a conductor having high conductivity is preferably used. For example, a conductive material containing tungsten, copper, or aluminum as its main component can be used for the second conductor of the conductor 260. The second conductor of the conductor 260 may have a stacked-layer structure; for example, a stacked-layer structure of the conductive material and titanium or titanium nitride may be employed.

In the transistor, the conductor 260 is formed in a self-aligned manner to fill the opening formed in the insulator 280, for example. The formation of the conductor 260 in this manner allows the conductor 260 to be placed properly in a region between the pair of conductors 242 without alignment.

The insulator 216a, the insulator 280, the insulator 287, the insulator 216b, the insulator 181, and the insulator 185 each preferably have a lower permittivity than the insulator 214. When a material with a low permittivity is used for an interlayer film, parasitic capacitance generated between wirings can be reduced.

For example, the insulator 216a, the insulator 280, the insulator 287, the insulator 216b, the insulator 181, and the insulator 185 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulator 216a, the insulator 280, the insulator 287, the insulator 216b, the insulator 181, and the insulator 185 may be planarized.

The concentration of impurities such as water and hydrogen in the insulator 280 is preferably reduced. For example, the insulator 280 preferably contains an oxide containing silicon such as silicon oxide or silicon oxynitride.

Note that the sidewall of the insulator 280 in the opening portion in the insulator 280 may be substantially perpendicular to the top surface of the insulator 222 or may have a tapered shape. The tapered sidewall can improve the coverage with the insulator 253 provided in the opening portion of the insulator 280, for example; as a result, the number of defects such as voids can be reduced.

Note that in this specification and the like, the tapered shape refers to a shape such that at least part of the side surface of a component is inclined to a substrate surface or a formation surface. For example, the tapered shape preferably includes a region where the angle formed between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or substantially flat with slight unevenness.

For each of the conductor 160c and the conductor 205b included in the capacitor 101, any of the materials that can be used for the conductor 205a, the conductor 242, and the conductor 260 can be used. The conductor 160c and the conductor 205b are preferably formed by a deposition method that offers excellent coverage, such as an ALD method or a CVD method.

The conductor 160 includes a first conductor and a second conductor over the first conductor. For example, titanium nitride deposited by an ALD method can be used for the first conductor of the conductor 160, and tungsten deposited by a CVD method can be used for the second conductor of the conductor 160. Note that in the case where the adhesion of tungsten to the insulator 282 is sufficiently high, a single-layer structure of tungsten deposited by a CVD method may be used for the conductor 160.

For the insulator 215 included in the capacitor 101, a high dielectric constant (high-k) material (a material with a high relative permittivity) is preferably used. The insulator 215 is preferably formed by a deposition method that offers excellent coverage, such as an ALD method or a CVD method.

Examples of insulators of the high dielectric constant (high-k) material include an oxide, an oxynitride, a nitride oxide, and a nitride containing one or more kinds of metal elements selected from aluminum, hafnium, zirconium, gallium, and the like. The above-described oxide, oxynitride, nitride oxide, and nitride may contain silicon. Stacked insulators formed of any of the above-described materials can also be used.

Examples of the insulators of the high dielectric constant (high-k) material include aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium. Using such a high-k material allows the insulator 215 to be thick enough to inhibit leakage current and the capacitor 101 to have a sufficiently high capacitance.

It is preferable to use stacked insulators formed of any of the above-described materials, and it is preferable to use a stacked-layer structure of a high dielectric constant (high-k) material and a material having a higher dielectric strength than the high dielectric constant (high-k) material. As the insulator 215, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. As another example, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 101. In the case where insulators are stacked, the insulators are preferably deposited without exposure to the air (also referred to as successive deposition). For example, the insulators can be deposited successively by a thermal ALD method.

The conductor 233 preferably has a stacked-layer structure of a first conductor and a second conductor. For example, as illustrated in FIG. 2A, a structure can be employed in which the first conductor of the conductor 233 is provided in contact with an inner wall of the opening portion and the second conductor is provided on the inner side. The first conductor of the conductor 233 includes regions in contact with at least part of the top surface of the conductor 209, part of the side surface of the insulator 212, part of the side surface of the insulator 216a, parts of the top surface and the side surface of the conductor 242, and part of the side surface of the insulator 280.

A conductive material having a function of inhibiting passage of impurities such as water and hydrogen is preferably used for the first conductor of the conductor 233. The first conductor of the conductor 233 can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the metal oxide 230 through the conductor 233.

The conductor 233 also functions as a wiring and thus is preferably formed using a conductor having high conductivity. For example, a conductive material containing tungsten, copper, or aluminum as its main component can be used for the second conductor of the conductor 233.

For example, it is preferable to use titanium nitride for the first conductor of the conductor 233 and tungsten for the second conductor of the conductor 233. In that case, the first conductor of the conductor 233 is a conductor that contains titanium and nitrogen, and the second conductor of the conductor 233 is a conductor that contains tungsten.

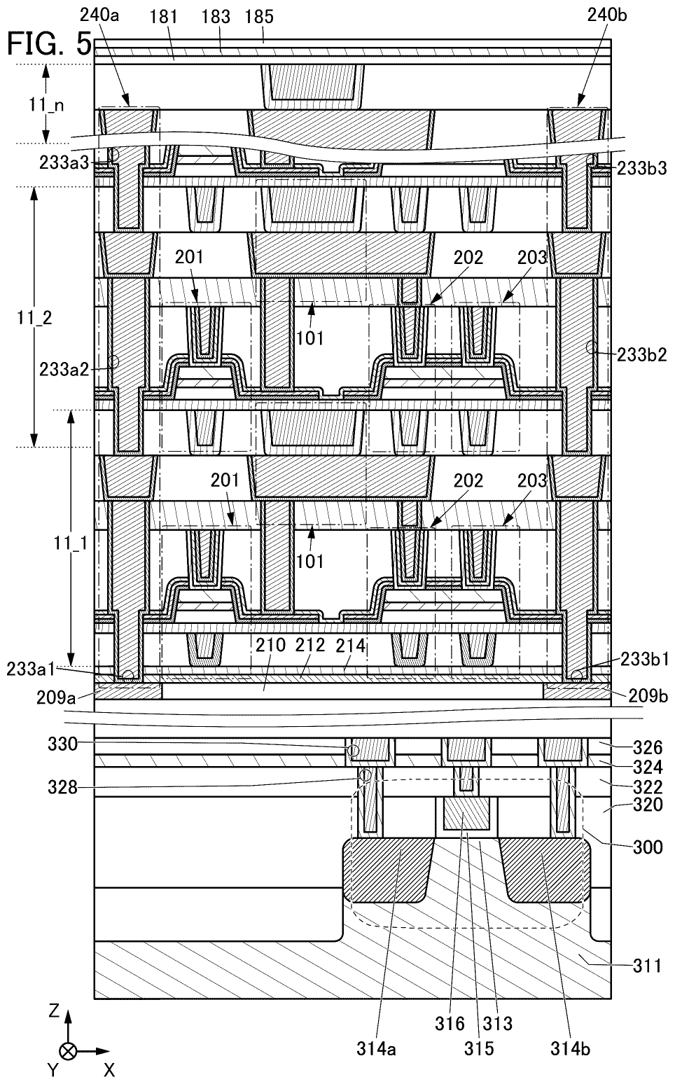

FIG. 5 is a cross-sectional view illustrating a structure example of the semiconductor device of one embodiment of the present invention. The semiconductor device illustrated in FIG. 5 is an example in which a layer including a transistor 300 is provided under the structure illustrated in FIG. 1, for example. The transistor 300 can be provided in a driver circuit of a memory cell formed above the insulator 210, for example. Note that the structure above the insulator 210 in FIG. 5 is similar to that in FIG. 1 and thus is not described in detail.

FIG. 5 illustrates an example of the transistor 300. The transistor 300 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 300 may be either a p-channel transistor or an n-channel transistor. As the substrate 311, a single crystal silicon substrate can be used, for example.

Here, in the transistor 300 illustrated in FIG. 5, the semiconductor region 313 (part of the substrate 311) in which a channel is formed has a protruding shape. The conductor 316 is provided to cover the side surface and the top surface of the semiconductor region 313 with the insulator 315 therebetween. Note that a material for adjusting the work function may be used as the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 300 illustrated in FIG. 5 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are sequentially stacked over the transistor 300 as interlayer films. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using, for example, a chemical mechanical polishing (CMP) method to have improved planarity.

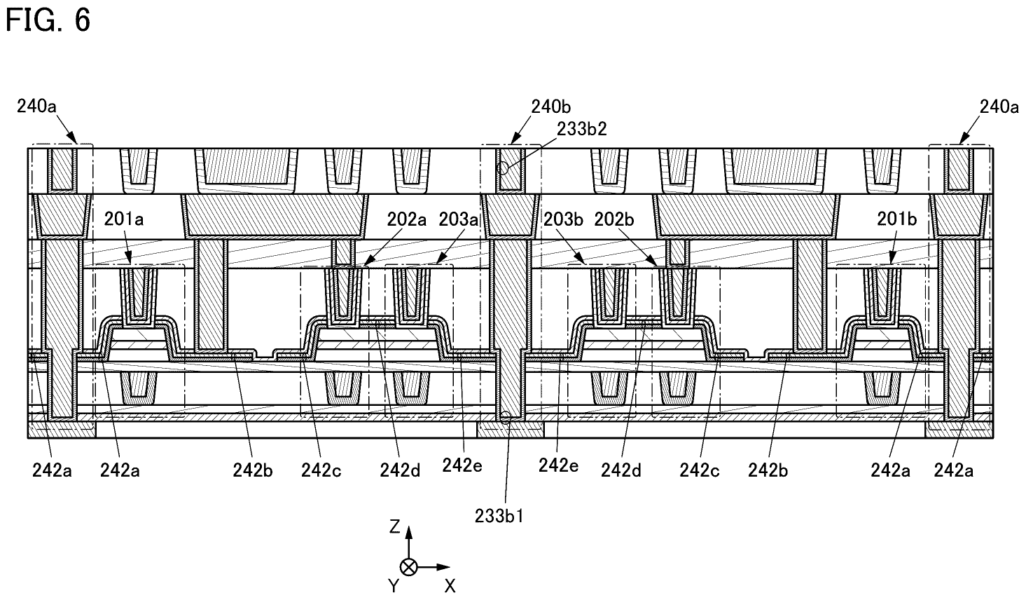

FIG. 6 is a cross-sectional view illustrating an example in which two memory cells are arranged in the X direction. FIG. 6 illustrates a memory cell including a transistor 201a, a transistor 202a, and a transistor 203a respectively as the transistor 201, the transistor 202, and the transistor 203, and a memory cell including a transistor 201b, a transistor 202b, and a transistor 203b respectively as the transistor 201, the transistor 202, and the transistor 203.

As illustrated in FIG. 6, the connection electrode 240b can be electrically connected to the conductor 242e included in the transistor 203a and the conductor 242e included in the transistor 203b. Thus, the connection electrode 240b can be shared by two memory cells adjacent to each other in the X direction, for example. The connection electrode 240a can be electrically connected to two conductors 242a adjacent to each other in the X direction, for example. Thus, the connection electrode 240a can also be shared by two memory cells adjacent to each other in the X direction, for example.

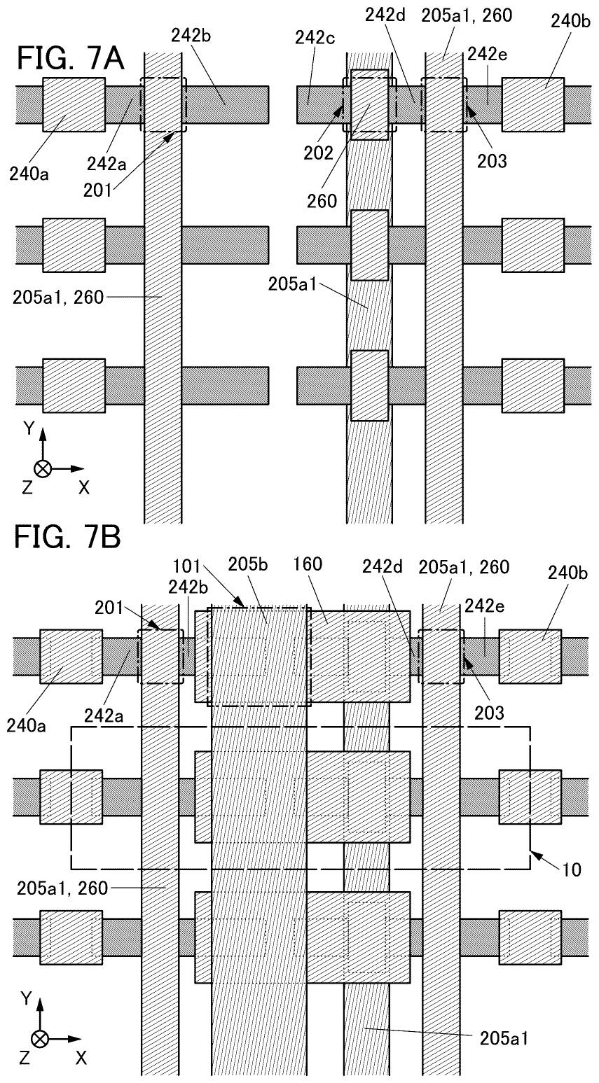

FIG. 7A and FIG. 7B are plan views illustrating examples of the semiconductor device having the structure illustrated in FIG. 2A or the like and illustrate structure examples of the XY plane.

FIG. 7A illustrates the transistor 201, the transistor 202, the transistor 203, the connection electrode 240a, and the connection electrode 240b. FIG. 7B illustrates a structure in which the capacitor 101 is added to FIG. 7A. In FIG. 7B, the transistor 201, the transistor 202, the transistor 203, and the capacitor 101 constitute a memory cell 10. Note that the components other than the conductors are omitted in FIG. 7A and FIG. 7B.

As illustrated in FIG. 7B, the conductor 160 including the region functioning as one electrode of the capacitor 101 and the conductor 205b including the region functioning as the other electrode of the capacitor 101 each have a rectangular shape. For example, in the case where the conductors illustrated in FIG. 7B are formed with a line-and-space pattern, the area of the memory cell 10 is 80 nm×245 nm=0.0196 μm² when the conductors other than the connection electrode 240a are designed such that line/space is 20 nm/20 nm and a margin for a portion where two patterns overlap with each other is 10 nm and the connection electrode 240a is designed with 25 nm×25 nm including a margin for misalignment of 5 nm. The cell density of each of the memory layer 11_1 to the memory layer 11_n illustrated in FIG. 1 is 51.0 cell/μm², for example.

### <Example 1 of Method for Manufacturing Semiconductor Device>

An example of a method for manufacturing the semiconductor device of one embodiment of the present invention will be described below. Here, the case of manufacturing the semiconductor device illustrated in FIG. 1 will be described as an example.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is formed while the flow rate ratio of the source gases is changed, as compared with the case where the film is formed using a plurality of deposition chambers, the time taken for the film formation can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

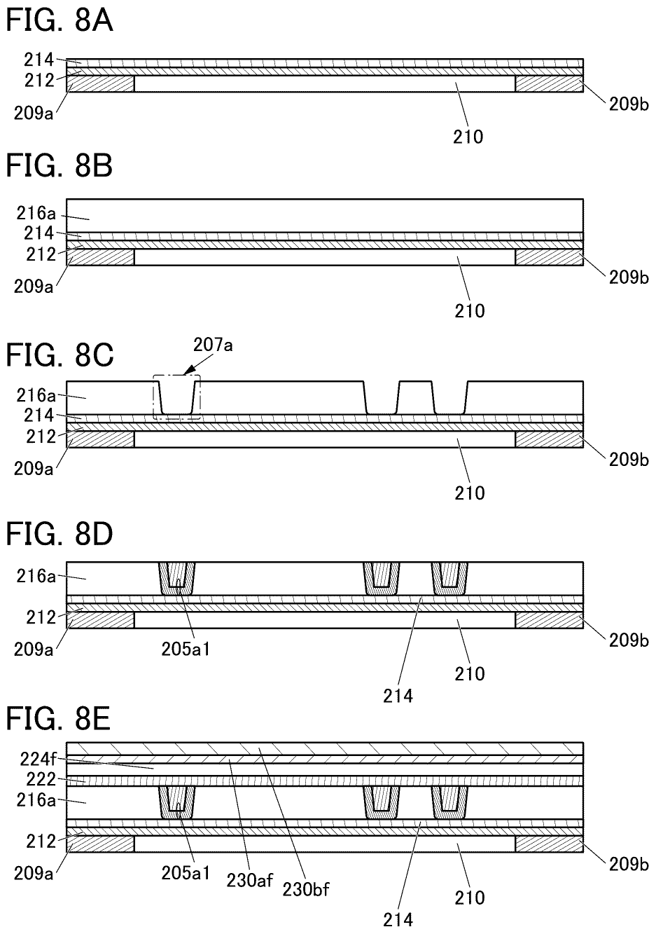

First, a substrate (not illustrated) is prepared, and the conductor 209a, the conductor 209b, and the insulator 210 are formed over the substrate. Next, the insulator 212 is formed over the conductor 209a, the conductor 209b, and the insulator 210, and the insulator 214 is formed over the insulator 212 (FIG. 8A).

The insulator 212 and the insulator 214 are preferably formed by an ALD method. Note that the insulator 212 and the insulator 214 may be formed by a sputtering method, a CVD method, an MBE method, or a PLD method

In this embodiment, for the insulator 212, silicon nitride is deposited by a PEALD method. For the insulator 214, hafnium oxide is deposited by an ALD method.

The use of an insulator through which impurities such as water and hydrogen are unlikely to pass, such as silicon nitride or hafnium oxide, as the insulator 212 and the insulator 214 can inhibit diffusion of impurities such as water and hydrogen contained in a layer below the insulator 212. Even when a metal that is likely to diffuse, such as copper, is used for the conductor 209a, the conductor 209b, and the like, which are conductors in a layer below the insulator 212, the use of an insulator through which copper is unlikely to pass, such as silicon nitride or hafnium oxide, as the insulator 212 and the insulator 214 can inhibit upward diffusion of the metal through the insulator 212.

Next, the insulator 216a is formed over the insulator 214 (FIG. 8B).

In this embodiment, for the insulator 216a, silicon oxide is deposited by a pulsed DC sputtering method using a silicon target in an atmosphere containing an oxygen gas. The use of the pulsed DC sputtering method can achieve more uniform film thickness and improve the sputtering rate and film quality.

Next, an opening 207a reaching the insulator 214 is formed in the insulator 216a (FIG. 8C). Wet etching may be used for forming the opening 207a; however, dry etching is preferably used for fine processing. Note that part of the insulator 214 is sometimes removed by the formation of the opening 207a. This sometimes leads to formation of a depressed portion in a region of the insulator 214 that overlaps with the opening 207a.

In this specification and the like, the term “opening” includes a groove, a slit, and the like. A region where an opening is formed is referred to as an opening portion in some cases.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus can be used, for example.

Next, a conductive film to be the conductor 205a1 is formed. The conductive film preferably has a stacked-layer structure of a conductive film having a function of inhibiting passage of oxygen and a conductive film having lower electrical resistivity than the conductive film. As the conductive film having a function of inhibiting passage of oxygen, one or more of tantalum nitride, tungsten nitride, and titanium nitride are preferably included, for example. Alternatively, the conductive film can have a stacked-layer structure of the conductive film having a function of inhibiting passage of oxygen and tantalum, tungsten, titanium, molybdenum, aluminum, copper, or a molybdenum-tungsten alloy. As the conductive film having low electrical resistivity, one or more of tantalum, tungsten, titanium, molybdenum, aluminum, copper, and a molybdenum-tungsten alloy are preferably included. These conductive films can be formed by, for example, a sputtering method, a plating method, a CVD method, an MBE method, a PLD method, or an ALD method.

In this embodiment, titanium nitride is deposited as the lower layer of the conductive film to be the conductor 205a1 and tungsten is deposited as the upper layer thereof. The use of a metal nitride as the lower layer of the conductor 205a1 can inhibit the insulator 216a from oxidizing the conductor 205al, for example. Furthermore, even when a metal that is likely to diffuse is used as the upper layer of the conductor 205al, the metal can be prevented from diffusing to the outside through the conductor 205a1.

Next, CMP treatment is performed to remove part of the conductive film to be the conductor 205a1, so that the insulator 216a is exposed. As a result, the conductor 205a1 is formed to fill the opening of the insulator 216a (FIG. 8D). Note that the insulator 216a is partly removed by the CMP treatment in some cases. This enables the insulator 216a to be planarized.

Next, the insulator 222 is formed over the insulator 216a and the conductor 205a1 (FIG. 8E).

An insulator containing an oxide of one or both of aluminum and hafnium is preferably formed as the insulator 222. Note that as the insulator containing an oxide of one or both of aluminum and hafnium, for example, aluminum oxide, hafnium oxide, or an oxide containing aluminum and hafnium (hafnium aluminate) is preferably used. Alternatively, hafnium zirconium oxide is preferably used. Alternatively, the insulator 222 can have a stacked-layer structure of an insulating film containing an oxide of one or both of aluminum and hafnium and silicon oxide, silicon oxynitride, silicon nitride, or silicon nitride oxide.

The insulator 222 can be formed by, for example, a sputtering method, a CVD method, an MBE method, a PLD method, or an ALD method. In this embodiment, for the insulator 222, hafnium oxide is deposited by an ALD method. Alternatively, the insulator 222 may have a stacked-layer structure of silicon nitride deposited by a PEALD method and hafnium oxide deposited by an ALD method.

Sequentially, heat treatment is preferably performed. The temperature of the heat treatment is preferably higher than or equal to 250° C. and lower than or equal to 650° C., further preferably higher than or equal to 300° C. and lower than or equal to 500° C., still further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent entry of moisture into the insulator 222 as much as possible, for example.

In this embodiment, as the heat treatment, treatment is performed at 400° C. for one hour with a flow rate ratio of a nitrogen gas to an oxygen gas of 4:1 after the formation of the insulator 222. Through the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after formation of an insulating film 224f, for example.

Next, an insulating film 224f is formed over the insulator 222 (FIG. 8E).

The insulating film 224f can be formed by, for example, a sputtering method, a CVD method, an MBE method, a PLD method, or an ALD method. In this embodiment, for the insulating film 224f, silicon oxide is deposited by an ALD method. By using a sputtering method that does not need to use a molecule containing hydrogen as a deposition gas, the hydrogen concentration in the insulating film 224f can be reduced. The hydrogen concentration in the insulating film 224f is preferably reduced in this manner because the insulating film 224f is in contact with the metal oxide in a later step.

Next, a metal oxide film 230af is formed over the insulating film 224f and a metal oxide film 230bf is formed over the metal oxide film 230af (FIG. 8E). Note that it is preferable to successively form the metal oxide film 230af and the metal oxide film 230bf without exposure to the atmospheric environment. By the film formation without exposure to the atmosphere, impurities or moisture from the atmospheric environment can be prevented from being attached onto the metal oxide film 230af and the metal oxide film 230bf, so that the vicinity of the interface between the metal oxide film 230af and the metal oxide film 230bf can be kept clean.

The metal oxide film 230af and the metal oxide film 230bf can each be formed by a sputtering method, a CVD method, an MBE method, a PLD method, or an ALD method, for example. In this embodiment, the metal oxide film 230af and the metal oxide film 230bf are formed by a sputtering method.

For example, in the case where the metal oxide film 230af and the metal oxide film 230bf are formed by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the metal oxide film 230af and the metal oxide film 230bf are formed by a sputtering method, an In-M-Zn oxide target can be used, for example.

In particular, when the metal oxide film 230af is formed, part of oxygen contained in the sputtering gas is supplied to the insulating film 224f in some cases. Thus, the proportion of oxygen contained in the sputtering gas is preferably higher than or equal to 70%, further preferably higher than or equal to 80%, still further preferably 100%.

In the case where the metal oxide film 230bf is formed by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the metal oxide film 230bf is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the film formation is performed while the substrate is being heated, the crystallinity of the oxide film can be improved.

In this embodiment, the metal oxide film 230af is formed by a sputtering method using an oxide target with In:Ga:Zn=1:3:4 [atomic ratio]. In addition, the metal oxide film 230bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed to have characteristics required for the metal oxide 230a and the metal oxide 230b by selecting the film formation conditions and the atomic ratios as appropriate.

Note that the insulating film 224f, the metal oxide film 230af, and the metal oxide film 230bf are preferably formed by a sputtering method without exposure to the air. For example, a multi-chamber deposition apparatus is preferably used. As a result, entry of hydrogen into the insulating film 224f, the metal oxide film 230af, and the metal oxide film 230bf in intervals between film formation steps can be inhibited.

Note that the metal oxide film 230af and the metal oxide film 230bf may be formed by an ALD method. When the metal oxide film 230af and the metal oxide film 230bf are formed by an ALD method, films with a uniform thickness can be formed even in a groove or an opening portion having a high aspect ratio. The metal oxide film 230af and the metal oxide film 230bf can be formed at a lower temperature by a PEALD method than by a thermal ALD method.

Next, heat treatment is preferably performed. The heat treatment is performed in a temperature range where the metal oxide film 230af and the metal oxide film 230bf do not become polycrystals. The temperature of the heat treatment is preferably higher than or equal to 250° C. and lower than or equal to 650° C., further preferably higher than or equal to 400° C. and lower than or equal to 600° C.

Note that an example of an atmosphere of the heat treatment is an atmosphere similar to the atmosphere applicable to the heat treatment performed after the formation of the insulator 222. As in the heat treatment performed after the deposition of the insulator 222, a gas used in the heat treatment is preferably highly purified. The heat treatment performed using a highly purified gas can prevent entry of moisture or the like into the metal oxide film 230af, the metal oxide film 230bf, and the like as much as possible.

In this embodiment, as the heat treatment, treatment is performed at 400° C. for one hour with a flow rate ratio of a nitrogen gas to an oxygen gas of 4:1. Through such heat treatment using the oxygen gas, impurities such as carbon, water, and hydrogen in the metal oxide film 230af and the metal oxide film 230bf can be reduced. The reduction of impurities in the films in this manner improves the crystallinity of the oxide film 230bf, thereby offering a dense structure with a higher density. Thus, crystalline regions in the metal oxide film 230af and the metal oxide film 230bf are expanded, so that in-plane variations of the crystalline regions in the metal oxide film 230af and the metal oxide film 230bf can be reduced. Accordingly, an in-plane variation of electrical characteristics of transistors can be reduced.

By performing the heat treatment, hydrogen in the insulator 216a, the insulating film 224f, the metal oxide film 230af, and the metal oxide film 230bf moves into the insulator 222 and is absorbed by the insulator 222. In other words, hydrogen in the insulator 216a, the insulating film 224f, the metal oxide film 230af, and the metal oxide film 230bf diffuses into the insulator 222. Accordingly, the hydrogen concentration in the insulator 222 increases, while the hydrogen concentrations in the insulator 216a, the insulating film 224f, the metal oxide film 230af, and the metal oxide film 230bf decrease.

Specifically, the insulating film 224f (to be the insulator 224 later) functions as the gate insulator of each of the transistor 201, the transistor 202, and the transistor 203, and the metal oxide film 230af and the metal oxide film 230bf (to be the metal oxide 230a and the metal oxide 230b later) function as the channel formation region of each of the transistor 201, the transistor 202, and the transistor 203. The transistor 201, the transistor 202, and the transistor 203 formed using the insulating film 224f, the metal oxide film 230af, and the metal oxide film 230bf with reduced hydrogen concentrations are preferable because of their high reliability.

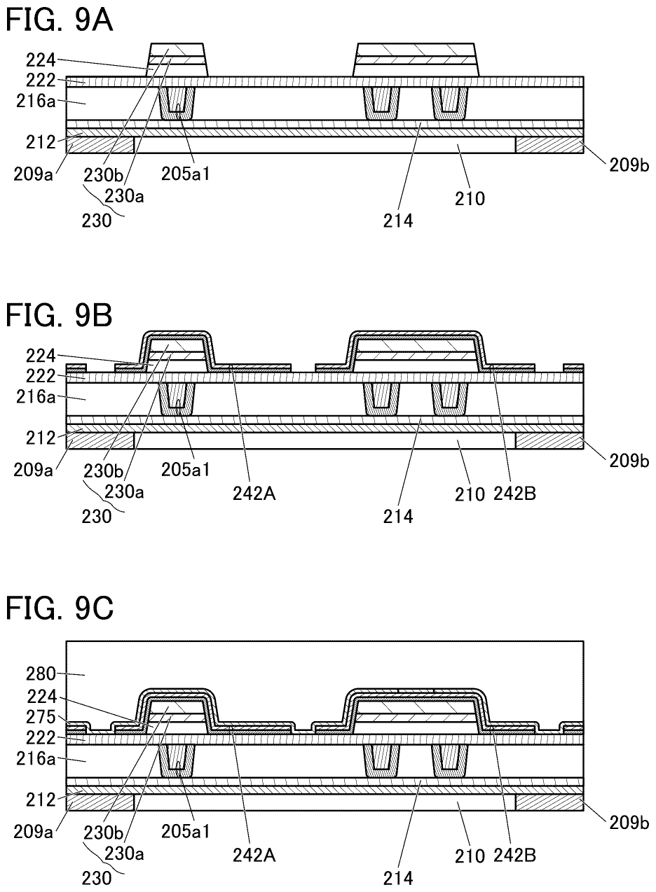

Next, the insulating film 224f, the metal oxide film 230af, and the metal oxide film 230bf are processed into island shapes by, for example, a lithography method and an etching method, so that the insulator 224, the metal oxide 230a, and the metal oxide 230b are formed (FIG. 9A). Here, the insulator 224, the metal oxide 230a, and the metal oxide 230b are formed to at least partly overlap with the conductor 205al. As described above, the metal oxide 230a of the transistor 202 and the metal oxide 230a of the transistor 203 are a common layer, and the metal oxide 230b of the transistor 202 and the metal oxide 230b of the transistor 203 are a common layer.

As illustrated in FIG. 9A, the side surfaces of the insulator 224, the metal oxide 230a, and the metal oxide 230b may have tapered shapes. The side surfaces of the insulator 224, the oxide 230a, and the oxide 230b may have a taper angle greater than or equal to 60° and less than 90°, for example. Such tapered side surfaces can improve the coverage with, for example, the insulator 275 in a later step; as a result, the number of defects such as voids can be reduced.

Not being limited to the above, the insulator 224, the metal oxide 230a, and the metal oxide 230b may have side surfaces that are substantially perpendicular to the top surface of the insulator 222. With such a structure, a plurality of transistors can be provided with high density in a small area.

A dry etching method or a wet etching method can be employed for the processing. Processing by a dry etching method is suitable for microfabrication. The insulating film 224f, the metal oxide film 230af, and the metal oxide film 230bf may be processed under different conditions.

Note that in the lithography method, first, a resist is exposed to light through a mask. Next, a region exposed to light is removed or left using a developing solution, so that a resist mask is formed. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. Note that the resist mask can be removed by dry etching treatment such as ashing, wet etching treatment, wet etching treatment after dry etching treatment, or dry etching treatment after wet etching treatment. After the resist mask is formed by a lithography method, etching treatment is performed through the resist mask, whereby a conductive film, a semiconductor film, an insulating film, or the like can be processed into a desired shape. In this manner, a conductor, a semiconductor, an insulator, or the like can be formed by a lithography method and an etching method. Note that an electron beam or an ion beam may be used instead of the light. A mask is unnecessary in the case of using an electron beam or an ion beam.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the metal oxide film 230bf, a resist mask is formed thereover, and then the hard mask material is etched. For example, the etching of the metal oxide film 230bf may be performed after removal of the resist mask or with the resist mask remaining. In the latter case, the resist mask sometimes disappears during the etching. The hard mask may be removed by etching after the etching of the metal oxide film 230bf, for example. Meanwhile, the hard mask is not necessarily removed when the hard mask material does not affect later steps or can be utilized in later steps.

Next, a conductive film is formed over the metal oxide 230b and the insulator 222. The conductive film can be formed by, for example, a sputtering method, a CVD method, an MBE method, a PLD method, or an ALD method. Note that heat treatment may be performed before the formation of the conductive film. The heat treatment may be performed under reduced pressure, and the conductive film may be successively formed without exposure to the air. Such treatment can remove moisture and hydrogen adsorbed on the surface of the metal oxide 230b and can reduce the moisture concentration and the hydrogen concentration in each of the metal oxide 230a and the metal oxide 230b. The heat treatment is preferably performed at a temperature higher than or equal to 100° C. and lower than or equal to 400° C. In this embodiment, the heat treatment is performed at 200° C.

Next, the conductive film is processed by a lithography method and an etching method, whereby a conductive layer 242A and a conductive layer 242B that cover the top surface and the side surfaces of the metal oxide 230b, the side surfaces of the metal oxide 230a, the side surfaces of the insulator 224, and the top surface of the insulator 222 are formed (FIG. 9B). Here, the conductive layer 242A is formed to cover the top surface and the side surfaces of the metal oxide 230b, the side surfaces of the metal oxide 230a, and the side surfaces of the insulator 224, which are to be the transistor 201. The conductive layer 242B is formed to cover the top surface and the side surfaces of the metal oxide 230b, the side surfaces of the metal oxide 230a, and the side surfaces of the insulator 224, which are to be the transistor 202 and the transistor 203 later.

In this embodiment, the conductive film to be the conductive layer 242A and the conductive layer 242B has a stacked-layer structure of tantalum nitride and tungsten each deposited by a sputtering method. Here, a film containing tungsten and a film containing tantalum nitride may be processed under the same conditions or different conditions.

Next, the insulator 275 is formed over the conductive layer 242A, the conductive layer 242B, and the insulator 222, and the insulator 280 is formed over the insulator 275 (FIG. 9C). As the insulator 280, an insulator having a flat top surface is preferably formed by forming an insulating film to be the insulator 280 and then performing CMP treatment on the insulating film. Note that, for example, silicon nitride may be deposited over the insulator 280 by a sputtering method and CMP treatment may be performed on the silicon nitride film until the insulator 280 is reached.

The insulator 275 and the insulator 280 can each be formed by a sputtering method, a CVD method, an MBE method, a PLD method, or an ALD method, for example.

As the insulator 275, an insulator having a function of inhibiting passage of oxygen is preferably used. For example, silicon nitride is preferably deposited for the insulator 275 by an ALD method, specifically a PEALD method. Alternatively, it is preferable that for the insulator 275, aluminum oxide be deposited by a sputtering method and silicon nitride be deposited thereover by a PEALD method. When the insulator 275 has such a stacked-layer structure, the function of inhibiting diffusion of oxygen and impurities such as water and hydrogen can be improved.

In this manner, the insulator 224, the metal oxide 230a, the metal oxide 230b, the conductive layer 242A, and the conductive layer 242B can be covered with the insulator 275, which has a function of inhibiting diffusion of oxygen. This can inhibit direct diffusion of oxygen from the insulator 280 or the like into the insulator 224, the metal oxide 230a, the metal oxide 230b, the conductive layer 242A, and the conductive layer 242B in a later step.

The insulator 280 is preferably silicon oxide deposited by a sputtering method, for example. When the insulator 280 is deposited by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. The hydrogen concentration in the insulator 280 is preferably lower than 1×10²⁰ atoms/cm³, further preferably lower than 1×10¹⁹ atoms/cm³, still further preferably lower than 1×10¹⁸ atoms/cm³. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 275 and the like, and further can reduce the moisture concentration and the hydrogen concentration in the metal oxide 230a, the metal oxide 230b, and the insulator 224. For the heat treatment, the above heat treatment conditions can be used.

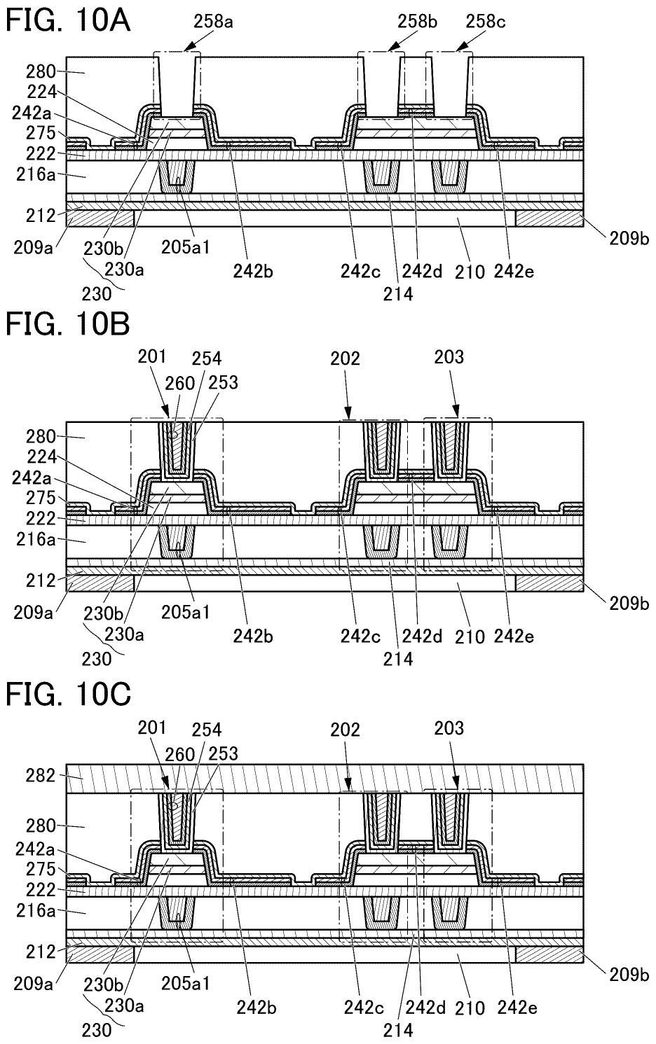

Then, the conductive layer 242A, the insulator 275, and the insulator 280 are processed by a lithography method and an etching method to form an opening 258a that reaches the metal oxide 230b. In addition, the conductive layer 242B, the insulator 275, and the insulator 280 are processed to form an opening 258b and an opening 258c that reach the metal oxide 230b. The conductor 242a and the conductor 242b are formed by the formation of the opening 258a. The conductor 242c, the conductor 242d, and the conductor 242e are formed by the formation of the opening 258b and the opening 258c (FIG. 10A). The opening 258a, the opening 258b, and the opening 258c each include a region overlapping with the conductor 205al. Note that the processing of the conductive layer 242A and the conductive layer 242B, the processing of the insulator 275, and the processing of the insulator 280 may be performed under different conditions. Alternatively, the processing of the insulator 275 and the processing of the insulator 280 may be performed under the same conditions, which may be different from the conditions for the processing of the conductive layer 242A and the conductive layer 242B.

By the above etching treatment, impurities might be attached to the side surface of the metal oxide 230a, the top surface and the side surface of the metal oxide 230b, the side surfaces of the conductor 242a to the conductor 242e, the side surface of the insulator 275, the side surface of the insulator 280, and the like or the impurities might be diffused thereinto. A step of removing such impurities may be performed. Particularly in the case where the opening 258a, the opening 258b, and the opening 258c are formed by a dry etching method, a damaged region may be formed on the surface of the metal oxide 230b. Such a damaged region may be removed. The impurities result from components contained in the insulator 280, the insulator 275, and the conductor 242a to the conductor 242e, components contained in a member of an apparatus used to form the opening 258a to the opening 258c, and components contained in a gas or a liquid used for etching, for example. Examples of the impurities include hafnium, aluminum, silicon, tantalum, fluorine, and chlorine.

In particular, impurities such as aluminum and silicon might reduce the crystallinity of the metal oxide 230b. Thus, it is preferable that impurities such as aluminum and silicon be removed from the surface of the metal oxide 230b and the vicinity thereof. The concentration of the impurities is preferably reduced. For example, the concentration of aluminum atoms at the surface of the metal oxide 230b and the vicinity thereof is preferably lower than or equal to 5.0 atomic %, further preferably lower than or equal to 2.0 atomic %, still further preferably lower than or equal to 1.5 atomic %, yet further preferably lower than or equal to 1.0 atomic %, yet still further preferably lower than 0.3 atomic %.

Note that since the density of a crystal structure is reduced in a low-crystallinity region of the metal oxide 230b because of impurities such as aluminum and silicon, a large amount of VoH is formed; thus, the transistor is likely to be normally on. Hence, the low-crystallinity region of the metal oxide 230b is preferably reduced or removed.

By contrast, the metal oxide 230b preferably has a layered CAAC structure. In particular, the CAAC structure preferably reaches a lower edge portion of a drain in the metal oxide 230b. Here, in the transistor 201 to the transistor 203, at least parts of the conductor 242a to the conductor 242e and their vicinities function as drains. Thus, the metal oxides 230b in the vicinities of the lower edge portions of the conductor 242a to the conductor 242e preferably have a CAAC structure. In this manner, the low-crystallinity region of the metal oxide 230b is removed and the CAAC structure is formed also in the end portion of the drain, which significantly affects the drain withstand voltage, so that a variation in electrical characteristics of the transistor 201 to the transistor 203 can be further suppressed. In addition, the reliability of the transistor 201 to the transistor 203 can be improved.

In order to remove impurities attached to the surface of the metal oxide 230b in the above etching step, for example, cleaning treatment is performed. Examples of the cleaning method include wet cleaning using a cleaning solution (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. For example, damage to the metal oxide 230b can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the metal oxide 230a, the metal oxide 230b, and the like or diffused into the metal oxide 230a, the metal oxide 230b, and the like. Furthermore, the crystallinity of the metal oxide 230b can be increased.

After the etching or the cleaning, heat treatment may be performed. The temperature of the heat treatment is preferably higher than or equal to 100° C. and lower than or equal to 450° C., further preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the metal oxide 230a and the metal oxide 230b to reduce oxygen vacancies. In addition, the crystallinity of the metal oxide 230b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

Next, an insulating film to be the insulator 253 is formed to fill the opening 258a, the opening 258b, and the opening 258c. The insulating film can be formed by an ALD method, a sputtering method, a CVD method, an MBE method, or a PLD method, for example, and is preferably formed by an ALD method. It is preferable that the thickness of the insulator 253 be small and hardly vary. An ALD method is a film formation method in which a precursor and a reactant (e.g., an oxidizer) are alternately introduced, and the thickness can be adjusted with the number of repetition times of the cycle; thus, accurate control of the thickness is possible. As illustrated in FIG. 10B, the insulator 253 is preferably formed with good coverage on the bottom surfaces and the side surfaces of the opening 258a, the opening 258b, and the opening 258c. With the use of an ALD method, an atomic layer can be deposited one by one on the bottom surfaces and the side surfaces of the opening 258a, the opening 258b, and the opening 258c. Thus, the insulator 253 can be formed with good coverage in the opening 258a, the opening 258b, and the opening 258c.

When the insulating film to be the insulator 253 is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the metal oxide 230b can be reduced.

In this embodiment, hafnium oxide is deposited for the insulating film to be the insulator 253 by a thermal ALD method. Alternatively, aluminum oxide and hafnium oxide can be deposited in this order as the insulating film to be the insulator 253.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the metal oxide 230b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment can be followed successively by heat treatment without exposure to air. The temperature of the heat treatment is preferably set to higher than or equal to 100° C. and lower than or equal to 750° C., further preferably higher than or equal to 300° C. and lower than or equal to 500° C., for example.

Furthermore, the microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the metal oxide 230b can be reduced by thus performing the microwave treatment in an atmosphere containing oxygen. In addition, the carrier concentrations in the metal oxide 230b can be prevented from being excessively reduced by preventing an excess amount of oxygen from being introduced into the chamber in the microwave treatment.

The microwave treatment in an atmosphere containing oxygen can convert an oxygen gas into plasma using a high-frequency wave such as a microwave or RF, and apply the oxygen plasma to a region of the metal oxide 230b that is between the conductor 242a and the conductor 242b, a region of the metal oxide 230b that is between the conductor 242c and the conductor 242d, and a region of the metal oxide 230b that is between the conductor 242d and the conductor 242e. By the effect of the plasma, the microwave, or the like, VoH in the region can be divided and hydrogen can be removed from the region. That is, VoH contained in the channel formation region can be reduced. Accordingly, oxygen vacancies and VoH in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

Meanwhile, the metal oxide 230b includes a region overlapping with any of the conductor 242a to the conductor 242e. The region can function as a source region or a drain region. Here, the conductor 242a to the conductor 242e preferably function as blocking films preventing the effect caused by the high-frequency wave such as a microwave or RF, the oxygen plasma, or the like in the microwave treatment in an atmosphere containing oxygen. Therefore, the conductor 242a to the conductor 242e preferably have a function of blocking an electromagnetic wave of greater than or equal to 300 MHz and less than or equal to 300 GHz, for example, greater than or equal to 2.4 GHz and less than or equal to 2.5 GHz.

The conductor 242a to the conductor 242e block the effects of the high-frequency wave such as a microwave or RF, the oxygen plasma, and the like. Thus, the effects do not reach the region of the metal oxide 230b that overlaps with any of the conductor 242a to the conductor 242e. Hence, a reduction in VoH and supply of an excess amount of oxygen do not occur in the source region and the drain region in the microwave treatment, preventing a decrease in carrier concentration.

Furthermore, the insulator 253 having a barrier property against oxygen is provided in contact with the side surfaces of the conductor 242a to the conductor 242e. This can inhibit formation of oxide films on the side surfaces of the conductors 242a and 242e by the microwave treatment.

Furthermore, the film quality of the insulator 253 can be improved, leading to higher reliability of the transistor.

In the above manner, oxygen vacancies and VoH can be selectively removed from the channel formation region in the metal oxide, whereby the channel formation region can be an i-type or substantially i-type region. Furthermore, supply of an excess amount of oxygen to the regions functioning as the source region and the drain region can be inhibited, and the conductivity can be maintained. As a result, a change in the electrical characteristics of the transistor can be inhibited, and thus a variation in the electrical characteristics of transistors in the substrate plane can be inhibited.

In the microwave treatment, thermal energy is directly supplied to the metal oxide 230b in some cases owing to an electromagnetic interaction between the microwave and a molecule in the metal oxide 230b. The metal oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the metal oxide 230b, it is probable that the thermal energy is transmitted to the hydrogen in the metal oxide 230b and the hydrogen activated by the energy is released from the metal oxide 230b.

Note that the microwave treatment may be performed not after the formation of the insulating film to be the insulator 253 but before the formation of the insulating film.

After the microwave treatment after the deposition of the insulating film to be the insulator 253, heat treatment may be performed with the reduced pressure being maintained. Such treatment enables hydrogen in the insulating film, the metal oxide 230b, and the metal oxide 230a to be removed efficiently. Part of hydrogen is gettered by the conductor 242 (the conductor 242a to the conductor 242e) in some cases. Alternatively, the step of performing microwave treatment and then performing heat treatment with the reduced pressure being maintained may be repeated a plurality of cycles. The repetition of the heat treatment enables hydrogen in the insulating film, the metal oxide 230b, and the metal oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the metal oxide 230b is adequately heated by the microwave annealing, for example.

Furthermore, the microwave treatment improves the film quality of the insulating film to be the insulator 253, thereby inhibiting diffusion of hydrogen, water, impurities, or the like. Accordingly, hydrogen, water, impurities, or the like can be inhibited from diffusing into the metal oxide 230b, the metal oxide 230a, and the like through the insulator 253 in a later step such as formation of a conductive film to be the conductor 260 or later treatment such as heat treatment.

Next, an insulating film to be the insulator 254 is formed over the insulating film to be the insulator 253. The insulating film can be formed by a sputtering method, a CVD method, an MBE method, a PLD method, or an ALD method, for example. The insulating film is preferably deposited by an ALD method, like the insulating film to be the insulator 253. By an ALD method, the insulating film to be the insulator 254 can be formed to have a small thickness and good coverage. In this embodiment, for the insulating film, silicon nitride is deposited by a PEALD method.

Next, a conductive film to be the conductor 260 is formed over the insulating film to be the insulator 254. The conductive film may be a single layer or have a stacked-layer structure of two or more layers. The conductive film to be the conductor 260 can be formed by, for example, a sputtering method, a CVD method, an MBE method, a PLD method, or an ALD method. In this embodiment, the conductive film to be the conductor 260 has a stacked-layer structure of titanium nitride deposited by an ALD method and tungsten deposited by a CVD method.

Then, the insulating film to be the insulator 253, the insulating film to be the insulator 254, and the conductive film to be the conductor 260 are polished by CMP treatment until the insulator 280 is exposed. That is, portions of the insulating film to be the insulator 253, the insulating film to be the insulator 254, and the conductive film to be the conductor 260 that are exposed from the opening 258a, the opening 258b, and the opening 258c are removed. Accordingly, the insulator 253, the insulator 254, and the conductor 260 are formed in the opening 258a, the opening 258b, and the opening 258c (FIG. 10B).

Thus, the insulator 253 is provided in contact with the bottom surfaces and the side surfaces of the opening 258a, the opening 258b, and the opening 258c. The conductor 260 is formed to fill the opening 258a, the opening 258b, and the opening 258c with the insulator 253 and the insulator 254 therebetween. Consequently, the transistor 201, the transistor 202, and the transistor 203 are formed. In this manner, the transistor 201, the transistor 202, and the transistor 203 can be formed in parallel through the same process.

Then, heat treatment may be performed under conditions similar to those for the above heat treatment. In this embodiment, treatment is performed at 400° C. in a nitrogen atmosphere for one hour. The heat treatment can reduce the moisture concentration and the hydrogen concentration in the insulator 280. After the heat treatment, the insulator 282 may be successively formed without exposure to the air.

Next, the insulator 282 is formed over the insulator 253, the insulator 254, the conductor 260, and the insulator 280 (FIG. 10C). The insulator 282 can be formed by, for example, a sputtering method, a CVD method, an MBE method, a PLD method, or an ALD method. The insulator 282 is preferably deposited by a sputtering method. By using a sputtering method that does not need to use a molecule containing hydrogen as a deposition gas, the hydrogen concentration in the insulator 282 can be reduced.

In this embodiment, for the insulator 282, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. The RF power applied to the substrate is lower than or equal to 1.86 W/cm². The RF power is preferably higher than or equal to 0 W/cm² and lower than or equal to 0.62 W/cm². With low RF power, the amount of oxygen implanted into the insulator 280 can be reduced. Alternatively, the insulator 282 may have a stacked-layer structure of two layers. In that case, for example, the lower layer of the insulator 282 is formed with an RF power of 0 W/cm² applied to the substrate, and the upper layer of the insulator 282 is formed with an RF power of 0.62 W/cm² applied to the substrate.

When the insulator 282 is deposited by a sputtering method in an atmosphere containing oxygen, oxygen can be added to the insulator 280 during the deposition. Thus, excess oxygen can be contained in the insulator 280. At this time, the insulator 282 is preferably formed while the substrate is being heated.

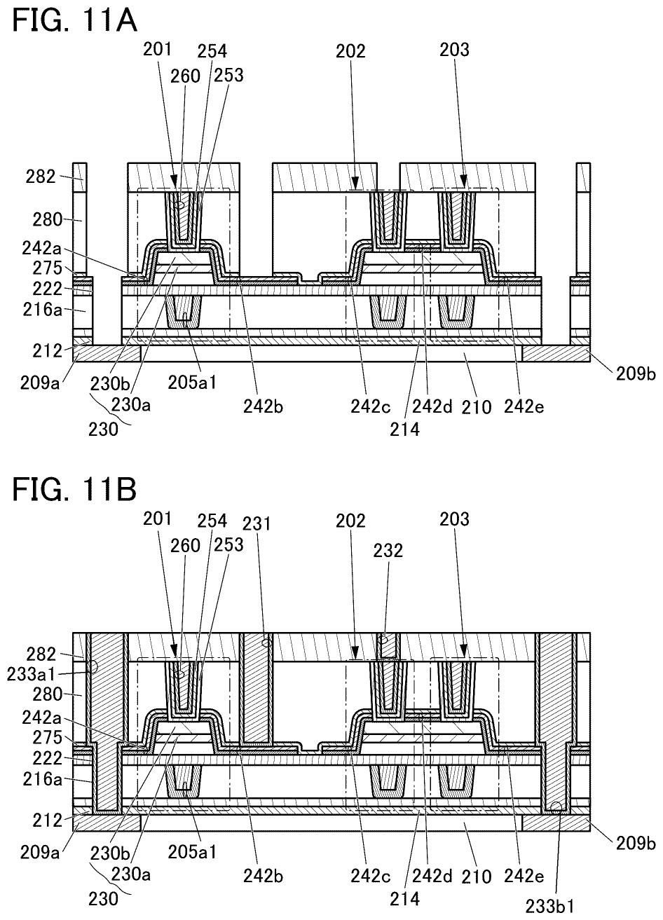

Next, an opening reaching the conductor 242b is formed in the insulator 282, the insulator 280, and the insulator 275. In addition, an opening reaching the conductor 260 included in the transistor 202 is formed in the insulator 282. An opening reaching the conductor 209a is formed in the insulator 282, the insulator 280, the insulator 275, the insulator 222, the insulator 216a, the insulator 214, and the insulator 212. An opening reaching the conductor 209b is formed in the insulator 282, the insulator 280, the insulator 275, the insulator 222, the insulator 216a, the insulator 214, and the insulator 212 (FIG. 11A). Wet etching may be used for forming the openings; however, dry etching is preferably used for microfabrication.

Next, a conductive film to be the conductor 231, the conductor 232, the conductor 233a1, and the conductor 233b1 is formed. The conductive film preferably has a stacked-layer structure of a conductive film having a function of inhibiting passage of oxygen and a conductive film having lower electrical resistivity than the conductive film. A material similar to any of the materials that can be used for the conductor 205a1 can be used for the conductive film to be the conductor 231, the conductor 232, the conductor 233al, and the conductor 233b1, for example.

Next, CMP treatment is performed to partly remove the conductive film to be the conductor 231, the conductor 232, the conductor 233al, and the conductor 233b1, so that the insulator 282 is exposed. As a result, the conductor 231 is formed to fill the opening reaching the conductor 242b. In addition, the conductor 232 is formed to fill the opening reaching the conductor 260 included in the transistor 202. The conductor 233a1 is formed to fill the opening reaching the conductor 209a. The conductor 233b1 is formed to fill the opening reaching the conductor 209b (FIG. 11B). Note that the insulator 282 is partly removed by the CMP treatment in some cases. This enables the insulator 282 to be planarized. In this manner, the top surface of the conductor 231, the top surface of the conductor 232, the top surface of the conductor 233al, and the top surface of the conductor 233b1 are level or substantially level with each other.

Then, the insulator 287 is formed over the insulator 282. The insulator 287 can be formed by a method similar to that for forming the insulator 216a or the insulator 280. For the insulator 287, a material similar to any of the materials that can be used for the insulator 216a or the insulator 280 can be used.

Then, the insulator 287 is processed by a lithography method and an etching method to form openings reaching the conductor 231, the conductor 232, the conductor 233al, and the conductor 233b1. One of the openings is preferably formed to be larger than the top surfaces of the conductor 231 and the conductor 232. One of the openings is preferably formed to be larger than the top surface of the conductor 233al. One of the openings is preferably formed to be larger than the top surface of the conductor 233b1.

Next, a conductive film to be the conductor 160a, the conductor 160b, and the conductor 160c is formed to fill the openings. The conductive film can be formed by a method similar to that for forming the film to be the conductor 242a to the conductor 242e. For the conductive film, a material similar to any of the materials that can be used for the film to be the conductor 242a to the conductor 242e can be used.

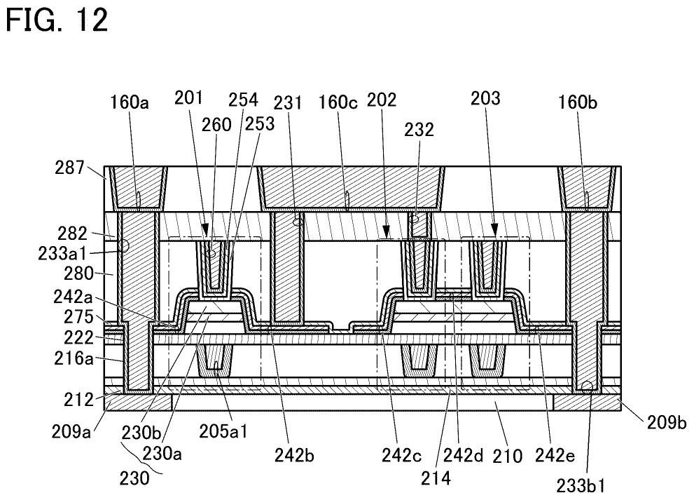

Next, CMP treatment is performed to partly remove the conductive film to be the conductor 160a, the conductor 160b, and the conductor 160c, so that the insulator 287 is exposed. As a result, the conductor 160a, the conductor 160b, and the conductor 160c are formed to fill the openings (FIG. 12). Note that the insulator 287 is partly removed by the CMP treatment in some cases. This enables the insulator 287 to be planarized.

Here, in the case where the etching selectivity of the insulator 287 to the insulator 282 is low, the insulator 282 does not function as an etch-stop film during formation of the opening in the insulator 287, and an opening reaching the insulator 282 is formed in some cases.

The conductor 160c is formed to be electrically connected to the conductor 231 and the conductor 232; for example, the conductor 160c is formed to include regions in contact with the conductor 231 and the conductor 232. In this manner, the conductor 160c is electrically connected to the conductor 242b through the conductor 231 and is electrically connected to the conductor 260 of the transistor 202 through the conductor 232.

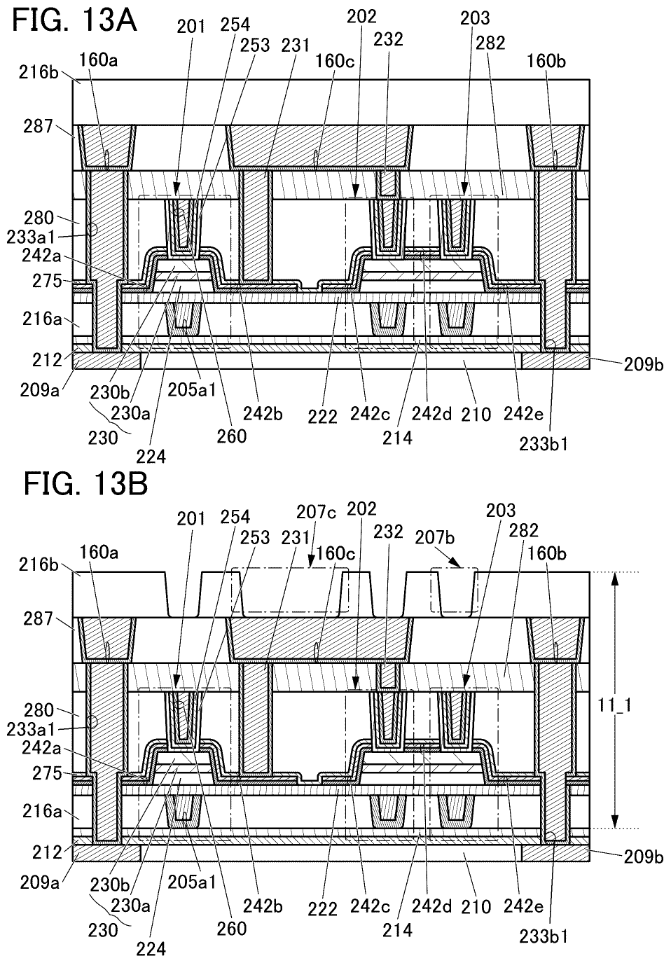

Next, the insulator 216b is formed over the conductor 160a, the conductor 160b, the conductor 160c, and the insulator 287 (FIG. 13A).

In this embodiment, for the insulator 216b, silicon oxide is deposited by a pulsed DC sputtering method using a silicon target in an atmosphere containing an oxygen gas.

Next, an opening 207b reaching the insulator 287 and an opening 207c reaching the conductor 160c are formed in the insulator 216b (FIG. 13B).

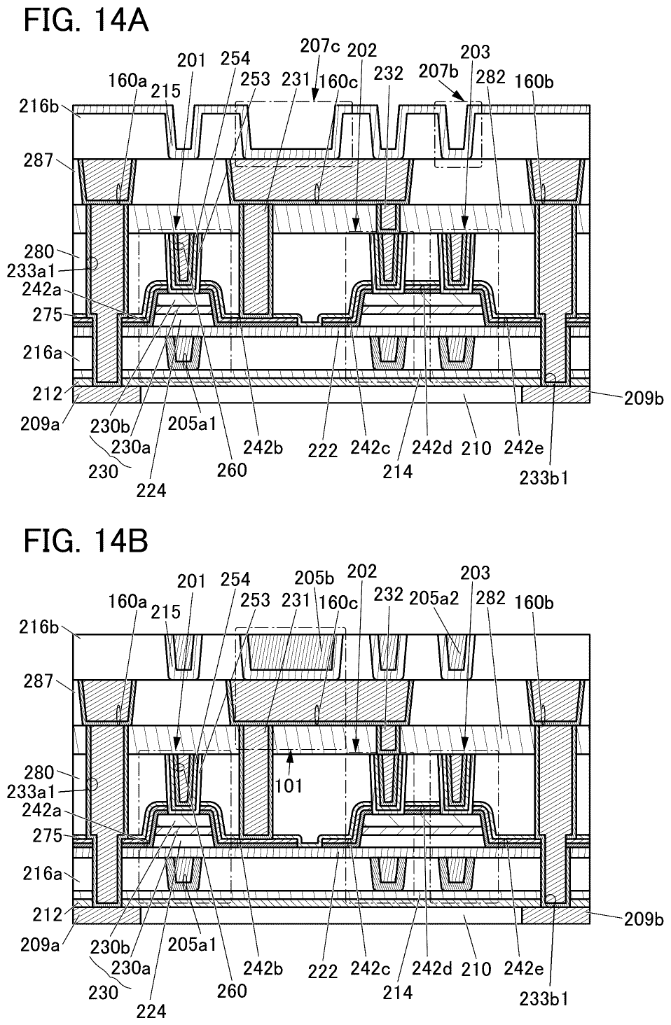

Next, the insulator 215 is formed inside the opening 207b and the opening 207c provided in the insulator 216b (FIG. 14A). As illustrated in the drawing, the insulator 215 is formed to define depressed portions in the opening 207b and the opening 207c. Note that the insulator 215 functions as a dielectric of the capacitor 101.

The insulator 215 is preferably formed by a film formation method that offers excellent coverage. The insulator 215 is preferably formed using a high-k material and further preferably has a stacked-layer structure including a high-k material and a material having higher dielectric strength than the high-k material. In this embodiment, as the insulator 215, zirconium oxide, aluminum oxide, and zirconium oxide are deposited in this order by an ALD method.

Alternatively, as the insulator 215, zirconium oxide, aluminum oxide, zirconium oxide, and aluminum oxide may be deposited in this order by an ALD method.

Next, the conductor 205a2 and the conductor 205b are formed to fill the depressed portions defined by the insulator 215 (FIG. 14B). The conductor 205a2 and the conductor 205b can be formed by a method similar to that for forming the conductor 205al. For the conductor 205a2 and the conductor 205b, a material similar to any of the materials that can be used for the conductor 205a1 can be used. Although the conductor 205a2 and the conductor 205 each have a single-layer structure in the drawing, the conductor 205a2 and the conductor 205 may each have a two-layer structure like the conductor 205al. Here, the conductor 205b is formed to include a region overlapping with the conductor 160c. In this manner, the capacitor 101 including the conductor 160c, the insulator 215, and the conductor 205b is formed.

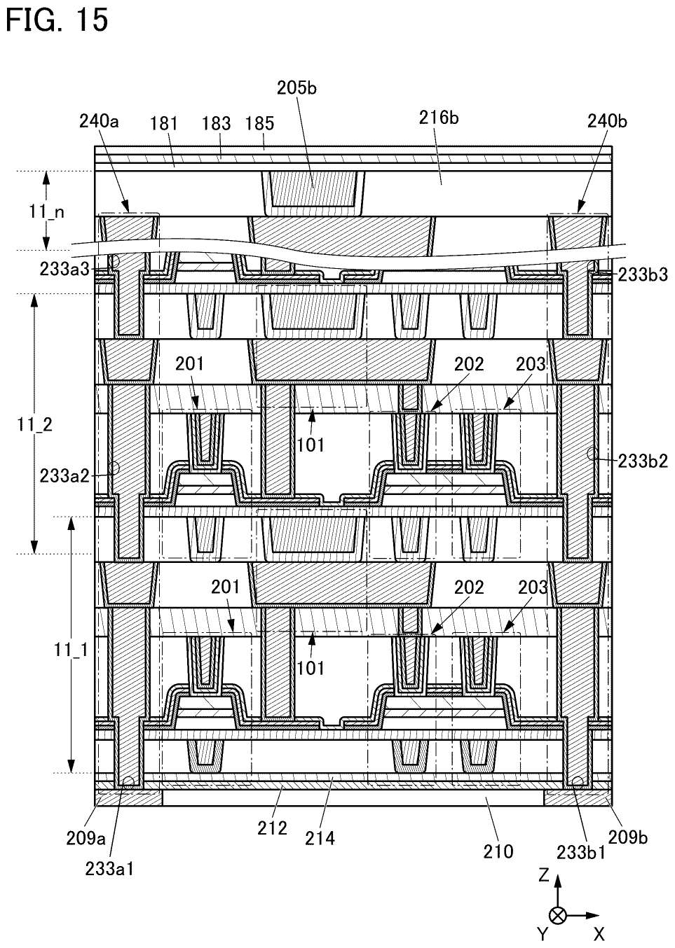

Through the above steps, the memory layer 11_1 can be formed. After that, the formation of the transistor 201, the transistor 202, the transistor 203, and the capacitor 101 is repeated n−1 times, whereby the memory layer 11_2 to the memory layer 11_n are formed (FIG. 15). Since the transistors constituting the memory layer 11 are not formed over the insulator 216b included in the uppermost memory layer 11_n, the conductor 205a is not formed thereover.

As illustrated in FIG. 15, the memory layer 11_1 to the memory layer 11_n include the connection electrode 240a and the connection electrode 240b. The connection electrode 240a includes the conductor 233a1 to a conductor 233an (not illustrated), which are electrically connected to each other. The connection electrode 240b includes the conductor 233b1 to a conductor 233bn (not illustrated), which are electrically connected to each other.

Next, the insulator 181 is formed over the conductor 205b and the insulator 216b in the memory layer 11_n. The insulator 181 can be formed by a method similar to that for forming the insulator 216b, the insulator 287, the insulator 280, the insulator 216a, or the insulator 212. For the insulator 181, a material similar to any of the materials that can be used for the insulator 216b, the insulator 287, the insulator 280, the insulator 216a, or the insulator 212 can be used.

Next, the insulator 183 is formed over the insulator 181, and the insulator 185 is formed over the insulator 183. The insulator 183 and the insulator 185 can be formed by an ALD method, a sputtering method, a CVD method, an MBE method, or a PLD method. Through the above steps, the semiconductor device illustrated in FIG. 1 can be manufactured.

This embodiment can be combined with any of the other embodiments as appropriate. In this specification, in the case where a plurality of structure examples are described in one embodiment, the structure examples can be combined as appropriate.

### Embodiment 2

In this embodiment, a memory device of one embodiment of the present invention will be described with reference to drawings.

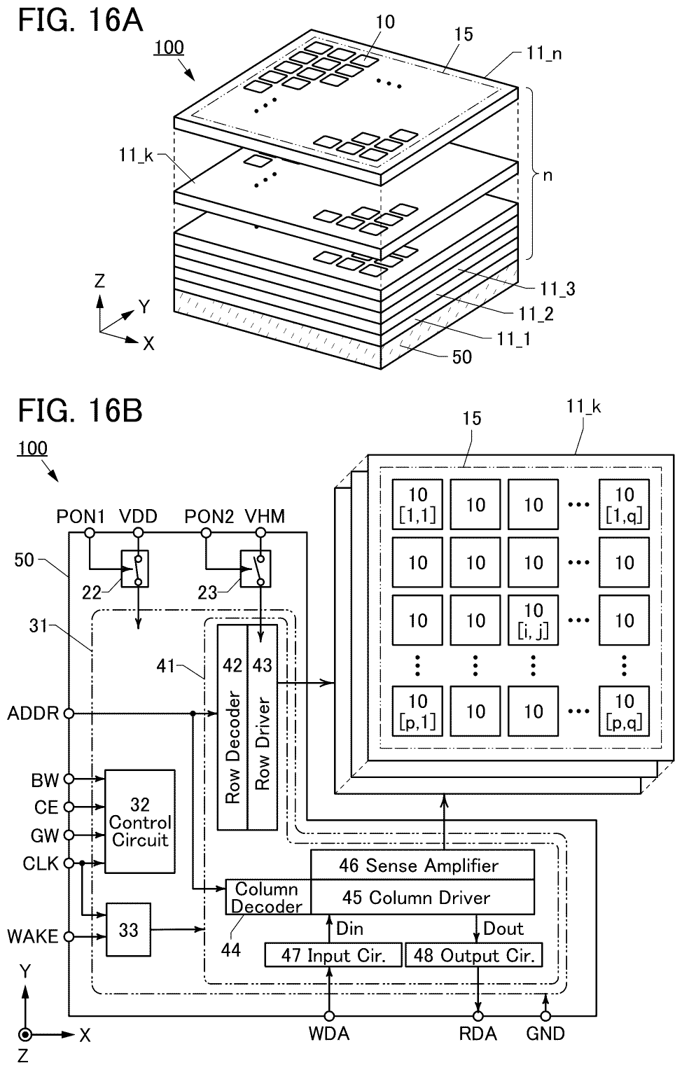

FIG. 16A is a schematic perspective view of a memory device of one embodiment of the present invention. FIG. 16B is a block diagram of the memory device of one embodiment of the present invention.

A memory device 100 illustrated in FIG. 16A and FIG. 16B includes a driver circuit layer 50 and the n memory layers 11. The memory layers 11 each include a memory cell array 15. The memory cell array 15 includes a plurality of the memory cells 10.

The n memory layers 11 are provided over the driver circuit layer 50. Provision of the n memory layers 11 over the driver circuit layer 50 can reduce the area occupied by the memory device 100. Furthermore, memory capacity per unit area can be increased.

In this embodiment, the first memory layer 11 is denoted by the memory layer 11_1, the second memory layer 11 is denoted by the memory layer 11_2, and the third memory layer 11 is denoted by a memory layer 11_3. Furthermore, the k-th (k is an integer greater than or equal to 1 and less than or equal to n) memory layer 11 is denoted by a memory layer 11_k, and the n-th memory layer 11 is denoted by the memory layer 11_n. Note that in this embodiment and the like, the simple term “memory layer 11” is sometimes used to describe matters related to all the n memory layers 11 or matters common to the n memory layers 11.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33 and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 10, a function of reading data from the memory cells 10, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 16B but can be more than one. In that case, a power switch is provided for each power domain.

### <Structure Example of Memory Layer 11>

A structure example of the n memory layers 11 will be described. The n memory layers 11 each include the memory cell array 15. The memory cell array 15 includes the plurality of memory cells 10. FIG. 16A and FIG. 16B illustrate an example in which the memory cell array 15 includes the plurality of memory cells 10 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 16B, the memory cell 10 provided in the first row and the first column is referred to as a memory cell 10[1,1], and the memory cell 10 provided in the p-th row and the q-th column is referred to as a memory cell 10[p,q]. The memory cell 10 provided in the i-th row and the j-th column (i is an integer greater than or equal to 1 and less than or equal to p, and j is an integer greater than or equal to 1 and less than or equal to q) is referred to as a memory cell 10[i,j].

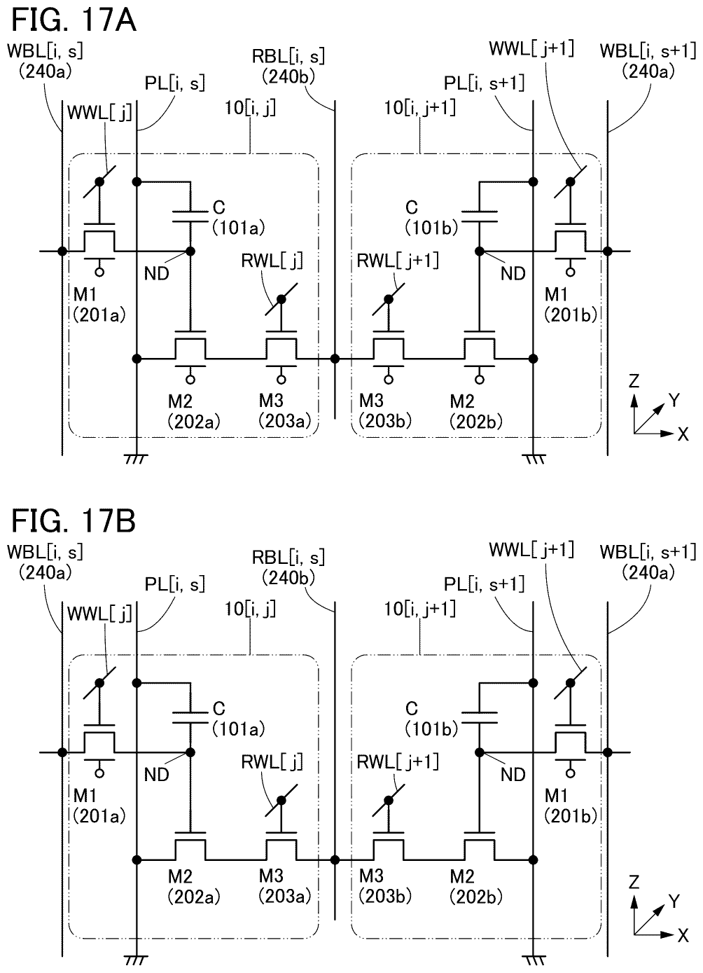

FIG. 17A and FIG. 17B illustrate circuit structure examples of memory cells. Embodiment 1 can be referred to for cross-sectional structure examples of the memory cells 10 corresponding to the circuit structures.

The memory cells 10 each include a transistor M1, a transistor M2, a transistor M3, and a capacitor C. A memory cell composed of three transistors and one capacitor is also referred to as a 3Tr1C memory cell. Thus, the memory cell 10 described in this embodiment is a 3Tr1C memory cell.

The transistor M1 corresponds to the transistor 201 or the transistor 201b described in Embodiment 1. The transistor M2 corresponds to the transistor 202 or the transistor 202b described in Embodiment 1. The transistor M3 corresponds to the transistor 203 or the transistor 203b described in Embodiment 1. The capacitor C corresponds to the capacitor 101 described in Embodiment 1. The wiring WBL corresponds to the connection electrode 240a described in Embodiment 1. The wiring RBL corresponds to the connection electrode 240b described in Embodiment 1.

In the memory cell 10[i,j], a gate of the transistor M1 is electrically connected to a wiring WWL[j], and one of a source and a drain of the transistor M1 is electrically connected to a wiring WBL[i,s]. FIG. 17A illustrates a structure example in which part of the wiring WWL[j] serves as the gate of the transistor M1. One electrode of the capacitor C is electrically connected to a wiring PL[i,s], and the other electrode is electrically connected to the other of the source and the drain of the transistor M1. Note that FIG. 17A illustrates a structure example in which part of the wiring PL[i,s] functions as the one electrode of the capacitor C, for example. A gate of the transistor M2 is electrically connected to the other electrode of the capacitor C, one of a source and a drain of the transistor M2 is electrically connected to one of a source and a drain of the transistor M3, and the other of the source and the drain of the transistor M2 is electrically connected to the wiring PL[i,s]. A gate of the transistor M3 is electrically connected to a wiring RWL[j], and the other of the source and the drain of the transistor M3 is electrically connected to a wiring RBL[i,s]. In the memory cell 10[i,j], a region where the other electrode of the capacitor C, the other of the source and the drain of the transistor M1, and the gate of the transistor M2 are electrically connected to one another and always have the same potential is referred to as a “node ND”.

In a memory cell 10[i,j+1], the gate of the transistor M1 is electrically connected to a wiring WWL[j+1], and one of the source and the drain of the transistor M1 is electrically connected to a wiring WBL[i,s+1]. FIG. 17A illustrates a structure example in which part of the wiring WWL[j+1] serves as the gate of the transistor M1. One electrode of the capacitor C is electrically connected to a wiring PL[i,s+1], and the other electrode is electrically connected to the other of the source and the drain of the transistor M1. Note that FIG. 17A illustrates a structure example in which part of the wiring PL[i,s+1] functions as the one electrode of the capacitor C, for example. The gate of the transistor M2 is electrically connected to the other electrode of the capacitor C, one of the source and the drain of the transistor M2 is electrically connected to one of the source and the drain of the transistor M3, and the other of the source and the drain of the transistor M2 is electrically connected to the wiring PL[i,s+1]. The gate of the transistor M3 is electrically connected to a wiring RWL[j+1], and the other of the source and the drain of the transistor M3 is electrically connected to the wiring RBL[i,s].

Thus, the wiring RBL[i,s] is electrically connected to the other of the source and the drain of the transistor M3 included in the memory cell 10[i,j] and the other of the source and the drain of the transistor M3 included in the memory cell 10[i,j+1]. Accordingly, the wiring RBL[i,s] is shared by the memory cell 10[i,j] and the memory cell 10[i,j+1]. Although not illustrated, the wiring WBL[i,s] is shared by a memory cell 10[i,j−1] and the memory cell 10[i,j], and the wiring WBL[i,s+1] is shared by the memory cell 10[i,j+1] and a memory cell 10[i,j+2].

In the memory cell 10[i,j+1], a region where the other electrode of the capacitor C, the other of the source and the drain of the transistor M1, and the gate of the transistor M2 are electrically connected to one another and always have the same potential is referred to as the node ND.

As illustrated in FIG. 17A, each of the transistor M1, the transistor M2, and the transistor M3 may be a transistor with a back gate. The gate and the back gate are placed such that a channel formation region of a semiconductor is sandwiched between the gate and the back gate. The gate and the back gate are formed using conductors. The back gate can function like the gate. By changing the potential of the back gate, the threshold voltage of the transistor can be changed. The potential of the back gate may be the same as the potential of the gate or may be a ground potential or a given potential.

Note that each of the transistor M1, the transistor M2, and the transistor M3 does not necessarily include a back gate. For example, as illustrated in FIG. 17B, a transistor with a back gate may be used as the transistor M1 and a transistor without a back gate may be used as each of the transistor M2 and the transistor M3.

In addition, the gate and the back gate are formed using conductors and thus also have a function of preventing an electric field generated outside the transistor from affecting the semiconductor in which a channel is formed (particularly, a function of blocking static electricity). That is, a variation in the electrical characteristics of the transistor due to the influence of an external electric field such as static electricity can be inhibited. Moreover, providing the back gate can reduce the amount of change in threshold voltage of the transistor before and after a BT test.

For example, the use of a transistor with a back gate as the transistor M1 can reduce the influence of an external electric field, allowing the off state to be maintained stably. Thus, data written to the node ND can be retained stably. Providing the back gate can stabilize the operation of the memory cells 10 and can improve the reliability of the memory device including the memory cells 10.

Likewise, the use of a transistor with a back gate as the transistor M3 can reduce the influence of an external electric field, allowing the off state to be maintained stably. Thus, leakage current between the wiring RBL and the wiring PL can be reduced, resulting in a reduction in the power consumption of the memory device including the memory cells 10.

As a semiconductor layer in which the channel of each of the transistor M1, the transistor M2, and the transistor M3 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, an oxide semiconductor, or a nitride semiconductor may be used.

Note that each of the transistor M1, the transistor M2, and the transistor M3 is preferably a transistor using an oxide semiconductor, which is a kind of metal oxide, in a semiconductor layer in which a channel is formed (also referred to as an “OS transistor”). An oxide semiconductor has a band gap of 2 eV or more and thus has an extremely low off-state current. Thus, the power consumption of the memory cells 10 can be reduced. Accordingly, the power consumption of the memory device 100 including the memory cells 10 can be reduced.

A memory cell including an OS transistor can be referred to as an “OS memory”. The memory device 100 including the memory cells can also be referred to as an “OS memory”.

The OS transistor operates stably even in a high-temperature environment and has a small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the OS memory can operate stably and have high reliability even in the high-temperature environment.

### <Operation Example of Memory Cell 10>

Data writing and reading operation examples of the memory cell 10 will be described. In this embodiment, normally-off n-channel transistors are used as the transistor M1, the transistor M2, and the transistor M3.

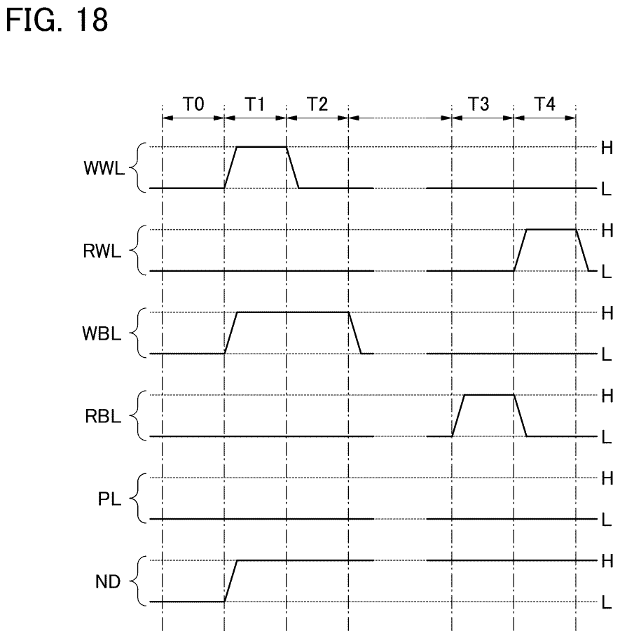

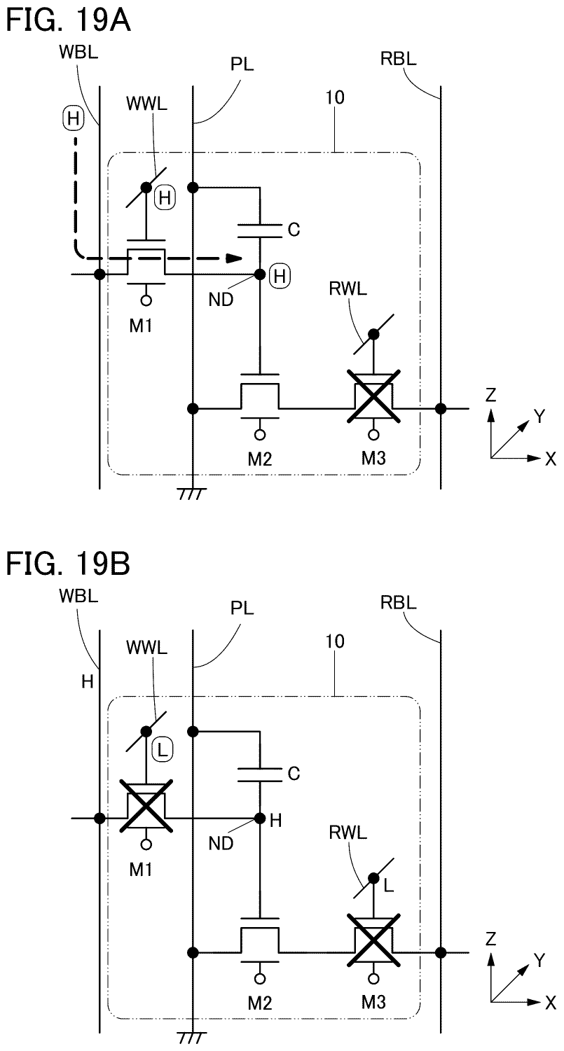

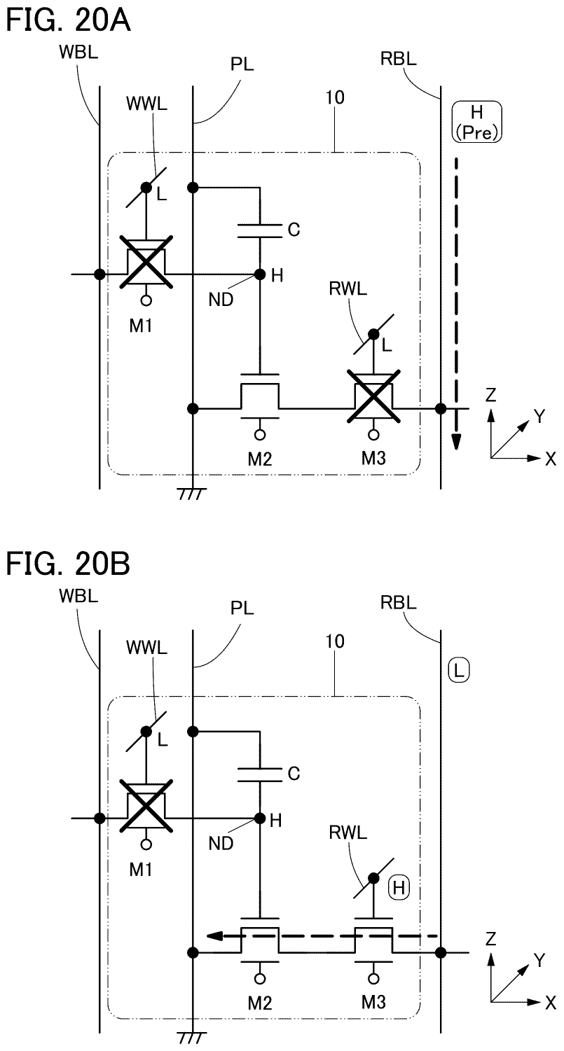

FIG. 18 is a timing chart for describing an operation example of the memory cell 10. FIG. 19A, FIG. 19B, FIG. 20A, and FIG. 20B are circuit diagrams for describing the operation example of the memory cell 10.

In the drawings and the like, for showing the potentials of a wiring and an electrode, “H” representing a potential H or “L” representing a potential L is sometimes written near the wiring and the electrode. In addition, enclosed “H” or “L” is sometimes written near a wiring or an electrode whose potential changes. Moreover, in the case where a transistor is in an off state, a symbol “x” is sometimes written on the transistor.

When the potential H is supplied to a gate of an n-channel transistor, the transistor is turned on. When the potential L is supplied to a gate of an n-channel transistor, the transistor is turned off. Thus, the potential H is higher than the potential L. The potential H may be equal to a high power supply potential VDD. The potential L is lower than the potential H. The potential L may be equal to a ground potential GND. In this embodiment, the potential L is equal to the ground potential GND.

First, in Period TO, the potentials of the wiring WWL, the wiring RWL, the wiring WBL, the wiring RBL, the wiring PL, and the node ND are the potential L (FIG. 18). In addition, the ground potential GND is supplied to the back gates of the transistor M1, the transistor M2, and the transistor M3.

### [Data Writing Operation]

In Period T1, the potential His supplied to the wiring WWL and the wiring WBL (FIG. 18 and FIG. 19A). Accordingly, the transistor M1 is turned on and the potential H is written to the node ND as data indicating “1”.

When the potential of the node ND becomes the potential H, the transistor M2 is turned on. Since the potential of the wiring RWL is the potential L, the transistor M3 is in the off state. The transistor M3 in the off state can prevent a short circuit between the wiring RBL and the wiring PL.

### [Retention Operation]

In Period T2, the potential L is supplied to the wiring WWL. Accordingly, the transistor M1 is turned off and the node ND is brought into a floating state. Thus, data (potential H) written to the node ND is retained (FIG. 18 and FIG. 19B). Note that after Period T2, the potential of the wiring WBL becomes the potential L.

As described above, the OS transistor is a transistor having an extremely low off-state current. The use of the OS transistor as the transistor M1 enables data written to the node ND to be retained for a long period. Therefore, it becomes unnecessary to frequently refresh the node ND and the power consumption of the memory cell 10 can be reduced. Thus, the power consumption of the memory device 100 can be reduced.

When the OS transistor is used as one or both of the transistor M2 and the transistor M3, leakage current flowing between the wiring RBL and the wiring PL in the writing operation and the retention operation can be extremely low.

Moreover, the OS transistor has a higher source-drain withstand voltage than a transistor containing silicon in a semiconductor layer where a channel is formed (also referred to as a Si transistor). When the OS transistor is used as the transistor M1, a higher potential can be supplied to the node ND. This increases the range of a potential retained at the node ND. An increase in the range of the potential retained at the node ND makes it easy to retain multilevel data or to retain analog data.

### [Reading Operation]

In Period T3, the potential H is precharged to the wiring RBL. That is, the potential of the wiring RBL is set to the potential H and then the wiring RBL is brought into a floating state (FIG. 18 and FIG. 20A).

Next, in Period T4, the potential H is supplied to the wiring RWL, so that the transistor M3 is turned on (FIG. 18 and FIG. 20B). In the case where the potential of the node ND is the potential H at this time, the transistor M2 is in an on state; thus, electrical continuity is established between the wiring RBL and the wiring PL through the transistor M2 and the transistor M3. When electrical continuity is established between the wiring RBL and the wiring PL, the potential of the wiring RBL, which is in a floating state, changes from the potential H to the potential L.

Note that the transistor M2 is in an off state in the case where the potential L is written to the node ND as data indicating “0”. Thus, electrical continuity is not established between the wiring RBL and the wiring PL even when the transistor M3 is turned on, and the potential of the wiring RBL remains the potential H.

By detecting a change in the potential of the wiring RBL at the time of supplying the potential H to the wiring RWL in this manner, data written to the memory cell 10 can be read.

The memory cell 10 using the OS transistor employs a method in which charge is written to the node ND through the OS transistor; hence, a high voltage, which is required for a conventional flash memory, is unnecessary and a high-speed writing operation is possible. Unlike in a flash memory, charge injection and extraction into/from a floating gate or a charge trap layer are not performed in the memory cell 10 including the OS transistor, allowing a substantially unlimited number of data writing and reading operations. Unlike in a flash memory, unstableness due to an increase of electron trap centers is not observed in the memory cell 10 using the OS transistor even when a rewriting operation is repeated. The memory cell 10 using the OS transistor is less likely to degrade than a conventional flash memory and can have high reliability.

Unlike a magnetic memory, a resistive random access memory, or the like, the memory cell 10 using the OS transistor has no change in the structure at the atomic level. Thus, the memory cell 10 using the OS transistor has higher rewrite endurance than a magnetic memory and a resistive random access memory.

### <Structure Example of Sense Amplifier 46>

Next, a structure example of the sense amplifier 46 will be described. Specifically, a structure example of a write read circuit that includes the sense amplifier 46 and performs writing or reading of a data signal will be described.

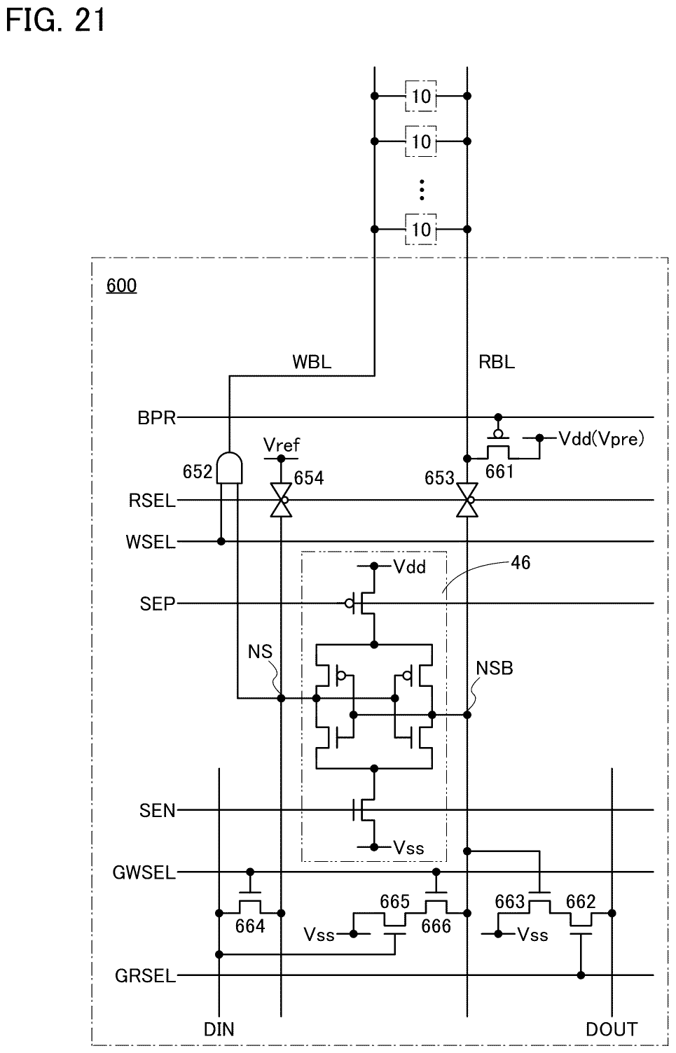

FIG. 21 is a circuit diagram illustrating a structure example of a circuit 600 that includes the sense amplifier 46 and performs writing or reading of a data signal. The circuit 600 is provided for every wiring WBL and every wiring RBL.

The circuit 600 includes a transistor 661 to a transistor 666, the sense amplifier 46, an AND circuit 652, an analog switch 653, and an analog switch 654.

The circuit 600 operates in accordance with a signal SEN, a signal SEP, a signal BPR, a signal RSEL, a signal WSEL, a signal GRSEL, and a signal GWSEL.

Data DIN input to the circuit 600 is written to the memory cell 10 through the wiring WBL electrically connected to a node NS. Data DOUT written to the memory cell 10 is transmitted to the wiring RBL electrically connected to a node NSB and output from the circuit 600 as the data DOUT.

Note that the data DIN and the data DOUT are internal signals and correspond to the signal WDA and the signal RDA, respectively.

The transistor 661 constitutes a precharge circuit. The wiring RBL is precharged to a precharge potential Vpre by the transistor 661. Note that in this embodiment, the case where a potential Vdd (high level) is used as the precharge potential Vpre will be described (denoted by Vdd (Vpre) in FIG. 21). The signal BPR is a pre-charge signal, and the conduction state of the transistor 661 is controlled by the signal BPR.

In a reading operation, the sense amplifier 46 determines whether data input to the wiring RBL is at a high level or a low level. In a writing operation, the sense amplifier 46 functions as a latch circuit that temporarily retains the data DIN input to the circuit 600.

The sense amplifier 46 illustrated in FIG. 21 is a latch sense amplifier. The sense amplifier 46 includes two inverter circuits, and an input node of one of the inverter circuits is connected to an output node of the other of the inverter circuits. When the input node of the one of the inverter circuits is the node NS and the output node is the node NSB, complementary data is retained at the node NS and the node NSB.

The signal SEN and the signal SEP are each a sense amplifier enable signal for activating the sense amplifier 46, and a reference potential Vref is a read judge potential. The sense amplifier 46 determines whether the potential of the node NSB at the time of the activation is at a high level or a low level on the basis of the reference potential Vref.

The AND circuit 652 controls electrical continuity between the node NS and the wiring WBL. The analog switch 653 controls the conduction state between the node NSB and the wiring RBL, and the analog switch 654 controls the conduction state between the node NS and a wiring for supplying the reference potential Vref.

In data reading, the potential of the wiring RBL is transmitted to the node NSB by the analog switch 653. When the potential of the wiring RBL is lower than the reference potential Vref, the sense amplifier 46 determines that the wiring RBL is at a low level. The sense amplifier 46 determines that the wiring RBL is at a high level when the potential of the wiring RBL does not become lower than the reference potential Vref.

The signal WSEL is a write selection signal and controls the AND circuit 652. The signal RSEL is a read selection signal and controls the analog switch 653 and the analog switch 654.

The transistor 662 and the transistor 663 constitute an output multiplexer (MUX) circuit. The signal GRSEL is a global read selection signal and controls the output MUX circuit. The output MUX circuit has a function of selecting the wiring RBL from which data is to be read. The output MUX circuit has a function of outputting the data DOUT read from the sense amplifier 46.

The transistor 664 to the transistor 666 constitute a write driver circuit. The signal GWSEL is a global write selection signal and controls the write driver circuit. The write driver circuit has a function of writing the data DIN to the sense amplifier 46.

The write driver circuit has a function of selecting a column to which the data DIN is to be written. The write driver circuit writes data in byte units, half-word units, or word units in response to the signal GWSEL.

In a gain-cell memory cell, at least two transistors are required for one memory cell, which makes it difficult to increase the number of memory cells that can be arranged per unit area. However, when an OS transistor is used as a transistor included in the memory cell 10, a plurality of the memory cell arrays 15 can be provided to be stacked. That is, the amount of data that can be stored per unit area can be increased. The gain-cell memory cell can operate as a memory by amplifying accumulated charge by the closest transistor even when the capacitance of accumulated charge is small. When an OS transistor with an extremely low off-state current is used as a transistor constituting the memory cell 10, the capacitance of the capacitor can be made small. Furthermore, one or both of the gate capacitance of a transistor and the parasitic capacitance of a wiring can be used as the capacitor, so that the capacitor can be omitted. That is, the area of the memory cell 10 can be made small.

This embodiment can be combined with any of the other embodiments as appropriate.

### Embodiment 3

In this embodiment, an example of a chip on which the memory device of one embodiment of the present invention is mounted will be described with reference to drawings.

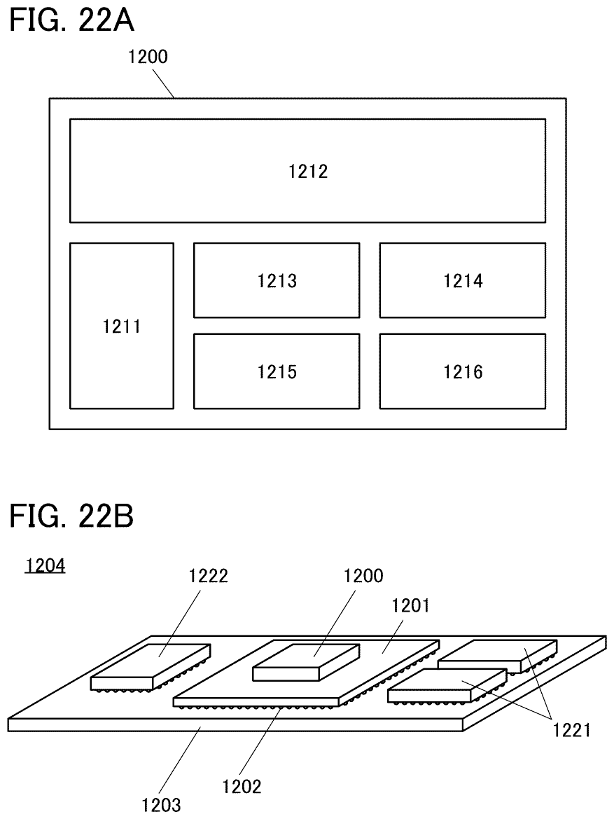

A plurality of circuits (systems) are mounted on a chip 1200 illustrated in FIG. 22A and FIG. 22B. A technique for integrating a plurality of circuits (systems) into one chip is referred to as system on chip (SoC) in some cases.

As illustrated in FIG. 22A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 22B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the NOSRAM described in the above embodiment can be used as the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The NOSRAM described above can be used as the memory. The GPU 1212 is suitable for parallel computation of a large amount of data and thus can be used for image processing or a product-sum operation. When an image processing circuit or a product-sum operation circuit using an OS transistor is provided in the GPU 1212, image processing or a product-sum operation can be performed with low power consumption.

In addition, since the CPU 1211 and the GPU 1212 are provided on the same chip, a wiring between the CPU 1211 and the GPU 1212 can be shortened, and data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at a high speed

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with any of the other embodiments as appropriate.

### Embodiment 4

In this embodiment, examples of an electronic component incorporating the memory device of one embodiment of the present invention will be described.

### [Electronic Component]

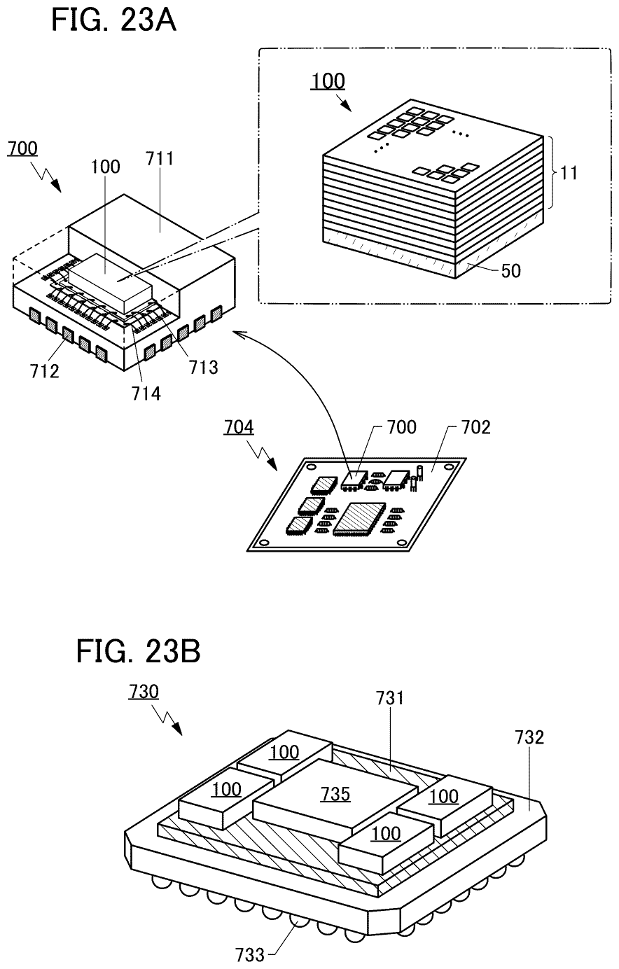

FIG. 23A is a perspective view of an electronic component 700 and a substrate (circuit board 704) on which the electronic component 700 is mounted. The electronic component 700 illustrated in FIG. 23A includes the memory device 100 that is the memory device of one embodiment of the present invention in a mold 711. FIG. 23A omits part of the electronic component to illustrate the inside of the electronic component 700. The electronic component 700 includes a land 712 outside the mold 711. The land 712 is electrically connected to an electrode pad 713, and the electrode pad 713 is electrically connected to the memory device 100 through a wire 714. The electronic component 700 is mounted on a printed circuit board 702, for example. A plurality of such electronic components are combined and electrically connected to each other on the printed circuit board 702, so that the circuit board 704 is completed.

As described in the above embodiment, the memory device 100 includes the driver circuit layer 50 and the memory layers 11 (each including the memory cell array 15).

FIG. 23B is a perspective view of an electronic component 730. The electronic component 730 is an example of a SiP (System in package) or an MCM (Multi Chip Module). In the electronic component 730, an interposer 731 is provided on a package substrate 732 (printed circuit board), and a semiconductor device 735 and a plurality of the memory devices 100 are provided on the interposer 731.

The electronic component 730 using the memory devices 100 as high bandwidth memory (HBM) is illustrated as an example. An integrated circuit (a semiconductor device) such as a CPU, a GPU, or an FPGA can be used as the semiconductor device 735.

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of a silicon interposer can be formed through a semiconductor process, formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

A heat sink (radiator plate) may be provided to overlap with the electronic component 730. In the case of providing a heat sink, the heights of integrated circuits provided on the interposer 731 are preferably equal to each other. In the electronic component 730 of this embodiment, the heights of the memory device 100 and the semiconductor device 735 are preferably equal to each other, for example.

An electrode 733 may be provided on the bottom portion of the package substrate 732 to mount the electronic component 730 on another substrate. FIG. 23B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with any of the other embodiments as appropriate.

### Embodiment 5

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device can also be used for image sensors, IoT (Internet of Things), healthcare-related devices, and the like. Note that here, the computers refer not only to tablet computers, laptop computers, and desktop computers, but also to large computers such as server systems.

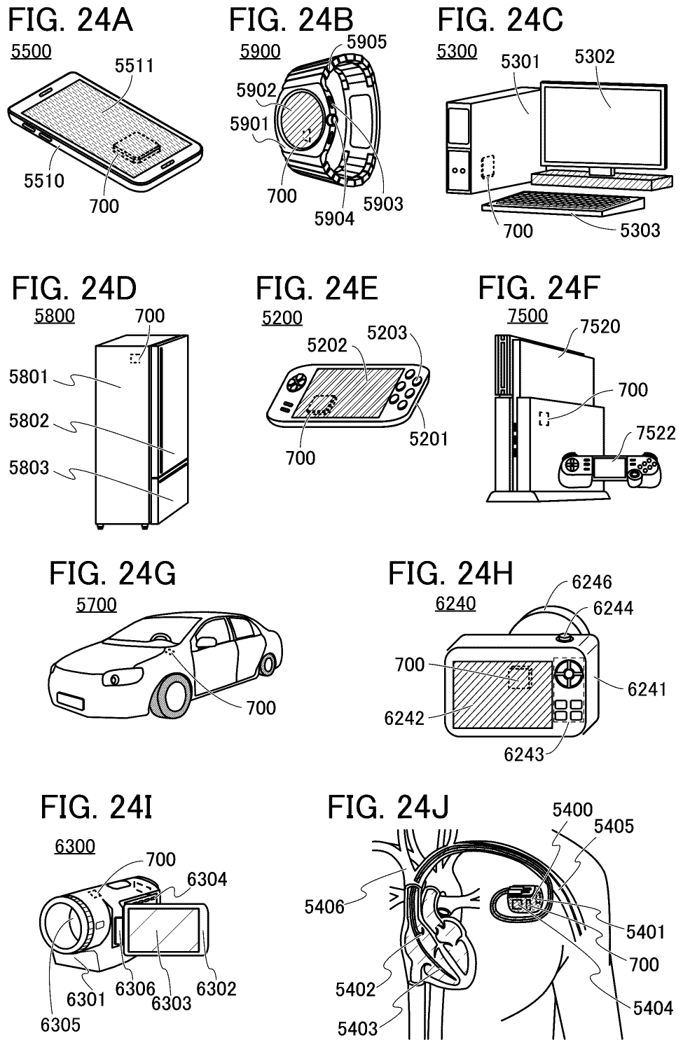

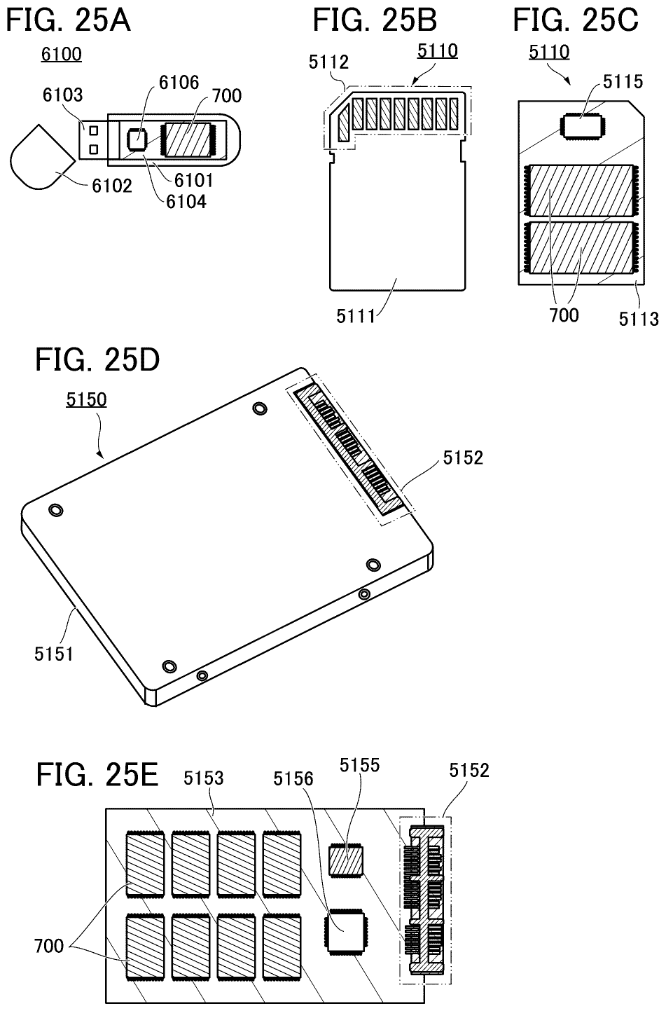

Examples of an electronic device including the memory device of one embodiment of the present invention will be described. Note that FIG. 24A to FIG. 24J and FIG. 25A to FIG. 25E each illustrate a state where the electronic component 700 or the electronic component 730, which is described in the above embodiment and includes the memory device, is included in an electronic device.

### [Mobile Phone]

An information terminal 5500 illustrated in FIG. 24A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache).

### [Wearable Terminal]

FIG. 24B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device of one embodiment of the present invention.

### [Information Terminal]

FIG. 24C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device of one embodiment of the present invention.

FIG. 24A to FIG. 24C illustrate the smartphone, the wearable terminal, and the desktop information terminal as electronic devices; other examples of information terminals include a PDA (Personal Digital Assistant), a laptop information terminal, and a workstation.

### [Household Appliance]

FIG. 24D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be used in the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the memory device of one embodiment of the present invention can retain a temporary file generated at the time of transmitting the information.

FIG. 24D illustrates the electric refrigerator-freezer as a household appliance, and examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 24E illustrates a portable game machine 5200 that is an example of a game machine. The portable game machine 5200 includes a housing 5201, a display portion 5202, a button 5203, and the like.

FIG. 24F illustrates a stationary game machine 7500 that is an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 24F, the controller 7522 can include a display portion that displays a game image, and an input interface besides the button, such as a touch panel, a stick, a rotating knob, and a sliding knob. The shape of the controller 7522 is not limited to that illustrated in FIG. 24F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

Videos displayed on the game machine can be output with a display device such as a television device, a personal computer display, a game display, or a head-mounted display.

By using the memory device of one embodiment of the present invention, the portable game machine 5200 or the stationary game machine 7500 can achieve low power consumption. Moreover, heat generation from a circuit can be reduced owing to low power consumption; thus, the influence of heat generation on the circuit itself, a peripheral circuit, and a module can be reduced.

Moreover, by using the memory device of one embodiment of the present invention, the portable game machine 5200 or the stationary game machine 7500 can retain a temporary file or the like necessary for an arithmetic operation that occurs during game play.

FIG. 24E and FIG. 24F illustrate the portable game machine and the home-use stationary game machine as examples of game machines; other examples of game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and the periphery of a driver's seat in the automobile.

FIG. 24G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a memory device showing the above information may be provided around the driver's seat.

In particular, the display device can compensate for the view obstructed by a pillar, blind areas for the driver's seat, and the like by displaying a video from an imaging device (not illustrated) provided for the automobile 5700, which can improve safety. That is, displaying an image taken by the imaging device provided on the exterior of the automobile 5700 can compensate for blind areas and improve safety.

The memory device of one embodiment of the present invention can temporarily retain information; thus, the memory device can be used to retain temporary information necessary in a system conducting automatic driving, navigation, risk prediction, or the like for the automobile 5700, for example. Moreover, the memory device of one embodiment of the present invention may be configured to retain a video of a driving recorder provided in the automobile 5700.

Although the automobile is described above as an example of a moving vehicle, the moving vehicle is not limited to the automobile. Examples of moving vehicles include a train, a monorail train, a ship, and a flying object (a helicopter, an unmanned aircraft (drone), an airplane, or a rocket).

### [Camera]

The memory device of one embodiment of the present invention can be used in a camera.

FIG. 24H illustrates a digital camera 6240 that is an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. Moreover, the digital camera 6240 may be configured to be additionally equipped with a stroboscope, a viewfinder, or the like.

By using the memory device of one embodiment of the present invention, the digital camera 6240 can achieve low power consumption. Moreover, heat generation from a circuit can be reduced owing to the low power consumption; thus, the influence of heat generation on the circuit itself, a peripheral circuit, and a module can be reduced.

### [Video Camera]

The memory device of one embodiment of the present invention can be used in a video camera.

FIG. 24I illustrates a video camera 6300 that is an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Videos displayed on the display portion 6303 may be switched in accordance with the angle at the joint 6306 between the first housing 6301 and the second housing 6302.

When videos taken by the video camera 6300 are recorded, the videos need to be encoded in accordance with a data recording format. By using the memory device of one embodiment of the present invention, the video camera 6300 can retain a temporary file generated at the time of encoding.

### [ICD]

The memory device of one embodiment of the present invention can be used in an implantable cardioverter-defibrillator (ICD).

FIG. 24J is a schematic cross-sectional view showing an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium. The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, the safety can be improved. Specifically, even when some of the batteries in the ICD main unit 5400 are dead, the other batteries can work properly; hence, the batteries also function as an auxiliary power source.

In addition to the antenna 5404 that can receive electric power, an antenna that can transmit a physiological signal may be included to construct, for example, a system that monitors cardiac activity by checking physiological signals such as a pulse, a respiratory rate, a heart rate, and body temperature with an external monitoring device.

### [Expansion Device for PC]

The memory device of one embodiment of the present invention can be used in a computer such as a PC (Personal Computer) and an expansion device for an information terminal.

FIG. 25A illustrates, as an example of the expansion device, a portable expansion device 6100 that includes a chip capable of storing information and is externally provided on a PC. The expansion device 6100 can store information using the chip when connected to a PC with a USB (Universal Serial Bus), for example. Note that FIG. 25A illustrates the portable expansion device 6100; however, the expansion device of one embodiment of the present invention is not limited thereto and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. For example, the substrate 6104 is provided with the electronic component 700 and a controller chip 6106. The USB connector 6103 functions as an interface for connection to an external device.

### [SD Card]

The memory device of one embodiment of the present invention can be used in an SD card that can be attached to an electronic device such as an information terminal or a digital camera.

FIG. 25B is a schematic external view of an SD card, and FIG. 25C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the electronic components 700 and a controller chip 5115 are attached to the substrate 5113. Note that the circuit structures of the electronic components 700 and the controller chip 5115 are not limited to those described above and can be changed as appropriate according to circumstances. For example, a write circuit, a row driver, a read circuit, or the like provided in an electronic component may be incorporated into the controller chip 5115 instead of the electronic component 700.

When the electronic components 700 are provided also on a rear surface side of the substrate 5113, the capacity of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The memory device of one embodiment of the present invention can be used in an SSD (Solid State Drive) that can be attached to an electronic device such as an information terminal.

FIG. 25D is a schematic external view of an SSD, and FIG. 25E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the electronic components 700, a memory chip 5155, and a controller chip 5156 are attached to the substrate 5153. When the electronic components 700 are provided also on a rear surface side of the substrate 5153, the capacity of the SSD 5150 can be increased. A work memory is incorporated in the memory chip 5155. For example, a DRAM chip is used as the memory chip 5155. A processor, an ECC (Error-Correcting Code) circuit, and the like are incorporated into the controller chip 5156. Note that the circuit structures of the electronic component 700, the memory chip 5155, and the controller chip 5115 are not limited to those described above and may be changed as appropriate depending on circumstances. For example, a memory functioning as a work memory may also be provided in the controller chip 5156.

### [Computer]

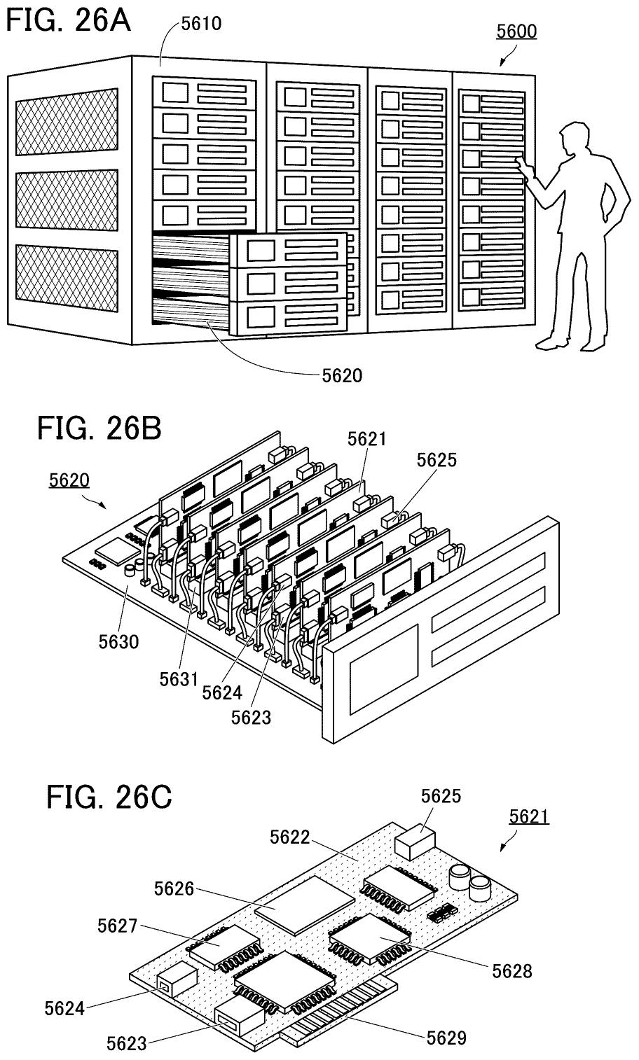

A computer 5600 illustrated in FIG. 26A is an example of a large computer. In the computer 5600, a plurality of rack mount computers 5620 are stored in a rack 5610.

The computer 5620 can have a structure in a perspective view illustrated in FIG. 26B, for example. In FIG. 26B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 26C also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve, for example, as an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices and the like described above, whereby a reduction in size and a reduction in power consumption of the electronic devices can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high-temperature environment. Thus, the reliability of the electronic device can be improved.

This embodiment can be combined with any of the other embodiments as appropriate.

### Embodiment 6

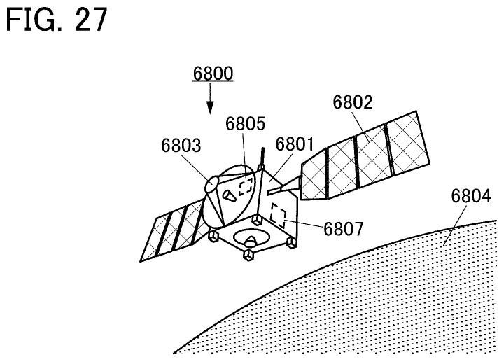

In this embodiment, a specific example of a case where the semiconductor device of one embodiment of the present invention is applied to a device for space is described with reference to FIG. 27.

The semiconductor device of one embodiment of the present invention includes an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

FIG. 27 illustrates an artificial satellite 6800 as an example of a device for space. The artificial satellite 6800 includes a body 6801, a solar panel 6802, an antenna 6803, a secondary battery 6805, and a control device 6807. Note that in FIG. 27, a planet 6804 in outer space is illustrated as an example. Note that outer space refers to, for example, space at an altitude greater than or equal to 100 km, and outer space described in this specification may include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to exposure to radiation is smaller in the OS transistor than in a Si transistor. Accordingly, the OS transistor has high reliability and thus can be suitably used even in an environment where radiation can enter.

The artificial satellite 6800 can be configured to include a sensor. For example, with a structure including a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### Example 1

In this example, to evaluate a metal that can be used for the conductor 242 and the like, a single-layer film of tantalum nitride and a stacked-layer film of tantalum nitride and tungsten were comparatively evaluated. Specifically, etching rate measurement and sheet resistance measurement were performed. In addition, carrier concentration measurement was performed to examine the influence of the metal provided over a metal oxide on the metal oxide.

### <Etching Rate Measurement>

The etching rates of a tantalum nitride film and a tungsten film in a dry etching method were evaluated.

Sample 1A and Sample 1B were fabricated as samples for the etching rate measurement. Two types of dry etching conditions were employed: Etching Condition A and Etching Condition B.

Sample 1A was fabricated in the following manner. A substrate was prepared and tantalum nitride was deposited over the substrate by a DC sputtering method. In the deposition of the tantalum nitride, a tantalum target was used, a mixed gas of argon at a flow rate of 50 sccm and nitrogen at a flow rate of 19 sccm was used as a deposition gas, the deposition pressure was 0.5 Pa, the TS (target-substrate) distance was 286 mm, the deposition power was 1000 W, and the substrate temperature was room temperature.

Sample 1B was fabricated in the following manner. A substrate was prepared and tungsten was deposited over the substrate by a DC sputtering method. In the deposition of the tungsten, a tungsten target was used, argon at a flow rate of 50 sccm was used as a deposition gas, the deposition pressure was 0.4 Pa, the TS distance was 60 mm, the deposition power was 1000 W, and the substrate temperature was 130° C.

Next, a resist pattern was formed. As the resist pattern, quadrangular island-shaped patterns were provided at multiple positions on the substrate surface. Then, dry etching treatment was performed.

In the dry etching treatment, a dry etching apparatus in which two types of high-frequency power sources were connected to a lower electrode of parallel plate electrodes and a DC (direct current) power source was connected to an upper electrode was used. The two types of high-frequency power sources were a 40-MHz HF (high frequency) power source and a 13-MHz LF (low frequency) power source.

Etching Condition A was as follows. As Etching Condition A, a mixed gas of a C₄F₈ gas at a flow rate of 12 sccm, a hydrogen gas at a flow rate of 24 sccm, a carbon dioxide gas at a flow rate of 20 sccm, and an Ar gas at a flow rate of 475 sccm was used, the substrate temperature was 20° C., the pressure was 3.0 Pa, the output of the HF power source was 1000 W, the output of the LF power source was 1200 W, and the DC power source was-300 V. Note that the output of the HF power source was pulse driving in which 60% of the period with a frequency of 0.5 kHz was an application period.

As Etching Condition B, a mixed gas of a C₄F₈ gas at a flow rate of 12 sccm, a CF₄ gas at a flow rate of 20 sccm, a nitrogen gas at a flow rate of 50 sccm, and an Ar gas at a flow rate of 500 sccm was used, the substrate temperature was 20° C., the pressure was 3.0 Pa, the output of the HF power source was 1000 W, the output of the LF power source was 1200 W, and the DC power source was-300 V. Note that the output of the HF power source was pulse driving in which 60% of the period with a frequency of 5 kHz was an application period.

Each of Sample 1A and Sample 1B was subjected to treatment under Etching Condition A and Etching Condition B, and the etching rates under the four conditions were measured. Note that the resist pattern was removed after the etching treatment.

For the etching rate measurement, the shapes of the quadrangular island-shaped patterns provided at the multiple positions on the substrate surface were measured. Specifically, step shapes of the patterns were measured. For the measurement, a fully automatic micro figure measurement instrument ET4100A produced by Kosaka Laboratory Ltd. was used.

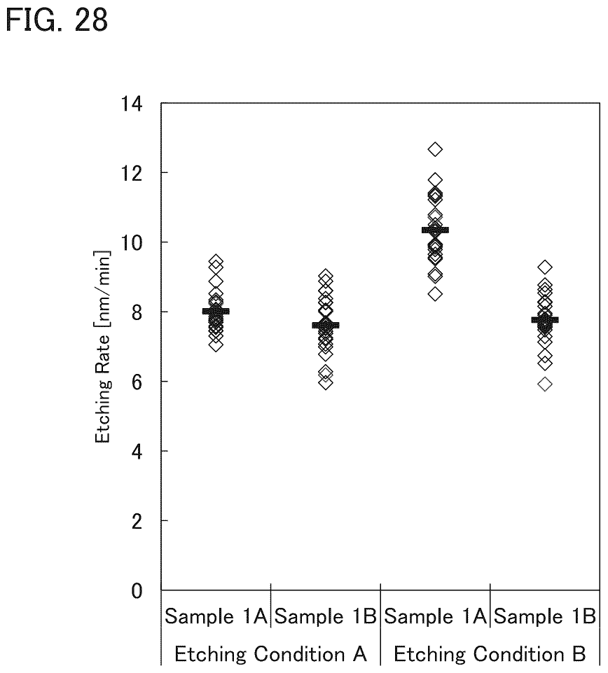

FIG. 28 shows measurement results of the etching rates at 25 points on the substrate surface and the average value of the 25 points. Note that in FIG. 28, a rhombus represents each measured value and a horizontal bar represents the average value.

The etching rate of Sample 1A was 8.01 nm/min and that of Sample 1B was 7.61 nm/min under Etching Condition A. Meanwhile, under Etching Condition B, the etching rate of Sample 1A was 10.35 nm/min and that of Sample 1B was 7.77 nm/min. As shown above, it was found that the etching rate of Sample 1B was lower than that of Sample 1A under either Etching Condition A or Etching Condition B.

Here, assuming that either Etching Condition A or Etching Condition B is used in the step of forming the opening reaching the conductor 242b in the insulator 282, the insulator 280, and the insulator 275, which is illustrated in FIG. 11A, the top surface of the conductor 242b is preferably less likely to be etched. Therefore, it can be said that the top surface of the conductor 242b is preferably tungsten.

Furthermore, as described in Embodiment 1, the bottom surface of the conductor 242b includes a region in contact with a metal oxide and thus is preferably tantalum nitride. Considering the above together, it can be said that a stacked-layer film of tantalum nitride (bottom surface) and tungsten (top surface) is preferably used as the conductor 242b.

### <Sheet Resistance Measurement>

Next, sheet resistance measurement was performed to examine the conductivity of the single-layer film of the tantalum nitride and the stacked-layer film of the tantalum nitride and the tungsten.

Sample 2A, Sample 2B, and Sample 2C were fabricated as samples for the sheet resistance measurement.

A fabrication process of Sample 2A is described. A silicon substrate was prepared, and the surface of the silicon substrate was subjected to thermal oxidation treatment so that first silicon oxide was formed to a thickness of 100 nm. Then, over the first silicon oxide, second silicon oxide, first metal oxide, second metal oxide, and tantalum nitride were deposited in this order by a sputtering method to a thickness of 20 nm, a thickness of 10 nm, a thickness of 15 nm, and a thickness of 20 nm, respectively. In the above manner, Sample 2A was fabricated.

A fabrication process of Sample 2B is described. The fabrication process of Sample 2B was the same as that of Sample 2A except that tantalum nitride and tungsten were deposited in this order by a sputtering method each to a thickness of 10 nm, instead of depositing the tantalum nitride to the thickness of 20 nm.

A fabrication process of Sample 2C is described. The fabrication process of Sample 2C was the same as that of Sample 2A except that tantalum nitride and tungsten were deposited in this order by a sputtering method to a thickness of 5 nm and a thickness of 15 nm, respectively, instead of depositing tantalum nitride to a thickness of 20 nm.

Sample 2A to Sample 2C were fabricated as described above. Here, the tantalum nitride is exposed at the surface of Sample 2A and the tungsten is exposed at the surfaces of the Sample 2B and Sample 2C.

Note that the deposition conditions of the tantalum nitride and the tungsten are the same as those of the tantalum nitride and the tungsten in <Etching rate measurement>.

For the sheet resistance measurement, a sheet resistance measuring instrument Σ-10 produced by NPS, Inc. was used.

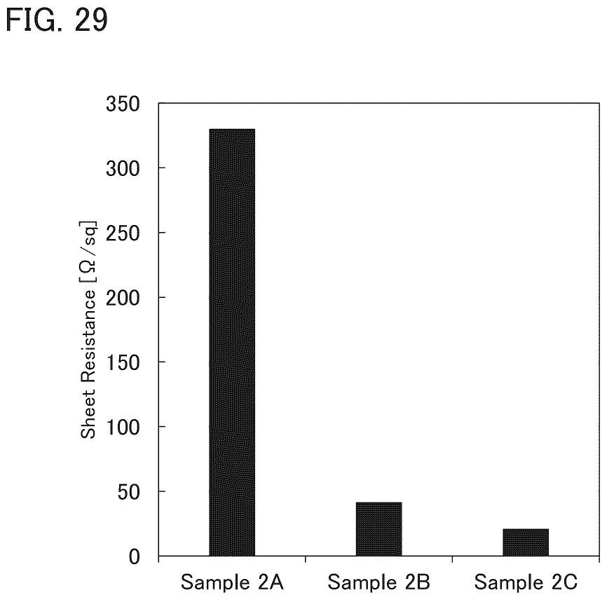

FIG. 29 shows average values of measurement results of 25 points on the substrate surface in each of Sample 2A to Sample 2C

The measurement results of the sheet resistances of Sample 2A, Sample 2B, and Sample 2C were 329 [Ω/sq], 41 [Ω/sq], and 21 [Ω/sq], respectively. These results demonstrate that the use of the stacked-layer film of the tantalum nitride and the tungsten can significantly reduce sheet resistance as compared with the use of the single-layer of the tantalum nitride. Note that the sheet resistance refers to the amount of electric resistance of a thin film with a uniform thickness and is also referred to as surface resistivity. The unit of sheet resistance is Ω but is denoted by [Ω/sq] to avoid confusion with electric resistance.

Since the thickness of the tungsten in the stacked-layer film is larger in Sample 2C than in Sample 2B, the sheet resistance of Sample 2C is lower than that of Sample 2B. In Sample 2C, the thickness of the tantalum nitride is 5 nm and the thickness of the tungsten over the tantalum nitride is 15 nm.

### <Carrier Concentration Measurement>

Next, the carrier concentration in a metal oxide was measured to examine the influence, on a metal oxide film, of formation of the single-layer film of the tantalum nitride over the metal oxide film or formation of the stacked-layer film of the tantalum nitride and the tungsten over the metal oxide film. Specifically, Hall effect measurement was performed, and the result was used to calculate the carrier concentration in the metal oxide.

Here, the Hall effect measurement is a method in which electrical characteristics such as carrier concentration, mobility, and resistivity are measured with the use of the Hall effect, which is a phenomenon where, when a magnetic field is applied to an object through which a current flows in a direction perpendicular to the direction of the current, an electromotive force is produced in directions perpendicular to both the current and the magnetic field. Here, the Hall effect measurement using the Van der Pauw method was performed.

Sample 3A, Sample 3B, Sample 3C, and Sample 3R were fabricated as samples for the Hall effect measurement.

A fabrication process of Sample 3A is described. A quartz substrate was prepared, and over the quartz substrate, first hafnium oxide was deposited to a thickness of 20 nm by an ALD method, silicon oxide was deposited to a thickness of 20 nm by a sputtering method, first metal oxide was deposited to a thickness of 10 nm by a sputtering method, second metal oxide was deposited to a thickness of 15 nm by a sputtering method, tantalum nitride was deposited to a thickness of 20 nm by a sputtering method, first silicon nitride was deposited to a thickness of 2 nm by a PEALD method, aluminum oxide was deposited to a thickness of 1 nm by an ALD method, second hafnium oxide was deposited to a thickness of 4 nm by an ALD method, second silicon nitride was deposited to a thickness of 1 nm by a PEALD method, titanium nitride was deposited to a thickness of 5 nm by a CVD method, and tungsten was deposited to a thickness of 150 nm by a CVD method in this order.

Next, the titanium nitride and the tungsten were removed by wet etching and the tantalum nitride, the first silicon nitride, the aluminum oxide, the second hafnium oxide, and the second silicon nitride were removed by dry etching to expose the top surface of the second metal oxide. In the above manner, Sample 3A was fabricated.

A fabrication process of Sample 3B is described. The fabrication process of Sample 3B was the same as that of Sample 3A except that tantalum nitride and tungsten were deposited in this order by a sputtering method each to a thickness of 10 nm, instead of depositing tantalum nitride to a thickness of 20 nm.

A fabrication process of Sample 3C is described. The fabrication process of Sample 3C was the same as that of Sample 3A except that tantalum nitride and tungsten were deposited in this order by a sputtering method to a thickness of 5 nm and a thickness of 15 nm, respectively, instead of depositing tantalum nitride to a thickness of 20 nm.

Sample 3A, Sample 3B, and Sample 3C were fabricated as described above. Here, the second metal oxide is exposed at the surfaces of Sample 3A to Sample 3C.

Note that the deposition conditions of the tantalum nitride and the deposition conditions of the tungsten are the same as those of the tantalum nitride and the tungsten in <Etching rate measurement>.

Sample 3R was fabricated as a comparative sample in the carrier concentration measurement.

A fabrication process of Sample 3R is described. A quartz substrate was prepared, and over the quartz substrate, first hafnium oxide was deposited to a thickness of 20 nm by an ALD method, first silicon oxide was deposited to a thickness of 20 nm by a sputtering method, first metal oxide was deposited to a thickness of 10 nm by a sputtering method, and second metal oxide was deposited to a thickness of 15 nm by a sputtering method in this order.

Here, the deposition conditions of the first metal oxide and the deposition conditions of the second metal oxide are described.

As the first metal oxide, an IGZO film was formed. The IGZO film was formed as follows: a target with In:Ga:Zn=1:3:2 [atomic ratio] was used as a sputtering target, an argon gas and an oxygen gas were supplied respectively at a flow rate of 6 sccm and a flow rate of 90 sccm to a treatment chamber of a sputtering apparatus, the pressure in the treatment chamber was controlled to 0.5 Pa, and an AC power of 2 kW was supplied. Note that the TS distance was 154 mm and the substrate temperature was 250° C.

As the second metal oxide, an IGZO film was formed. The IGZO film was formed as follows: a target with In:Ga:Zn=1:1:1.2 [atomic ratio] was used as a sputtering target, an argon gas and an oxygen gas were supplied respectively at a flow rate of 6 sccm and a flow rate of 90 sccm to a treatment chamber of a sputtering apparatus, the pressure in the treatment chamber was controlled to 0.5 Pa, and an AC power of 2 kW was supplied. Note that the TS distance was 154 mm and the substrate temperature was 250° C.

Note that a 200-nm-thick titanium-aluminum alloy film was formed over each sample by a sputtering method in order to perform the Hall effect measurement. Note that a metal mask was used to form the titanium-aluminum alloy film at each of the four corners of the sample. For the Hall effect measurement, “ResiTest 8400” produced by TOYO Corporation was used.

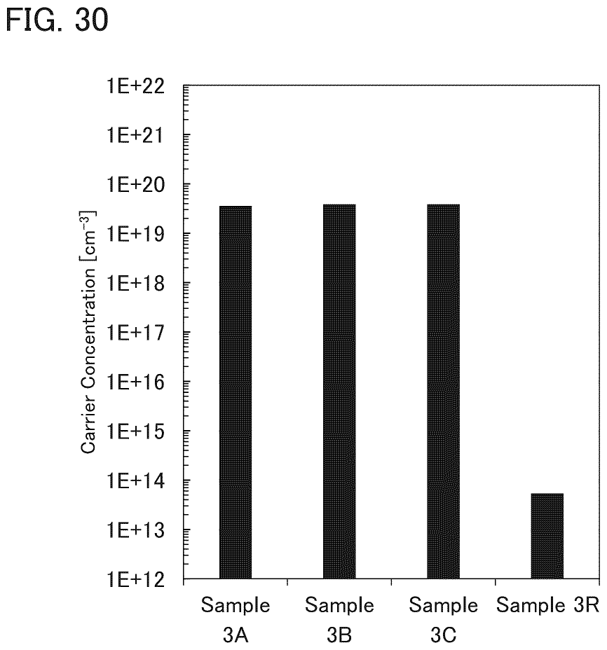

FIG. 30 shows carrier concentrations in the metal oxides included in the samples. In FIG. 30, the vertical axis represents the carrier concentration (cm⁻³) in the metal oxide.

The carrier concentration in Sample 3A was 3.6×10¹⁹ [cm⁻³], the carrier concentration in Sample 3B was 3.9×10¹⁹ [cm⁻³], the carrier concentration in Sample 3C was 3.9×10¹⁹ [cm⁻³], and the carrier concentration in Sample 3R was 5.4×10¹³ [cm⁻³]. As described above, Sample 3A, Sample 3B, and Sample 3C each had a high carrier concentration.

Accordingly, it can be said that the carrier concentration in the metal oxide is sufficiently high in either the case where the single-layer film of the tantalum nitride was formed over the metal oxide film or the case where the stacked-layer film of the tantalum nitride and the tungsten was formed over the metal oxide film. Therefore, it can be said that even in the case where either the single-layer film or the stacked-layer film is used as the conductor 242, a region in the metal oxide 230 illustrated in FIG. 2 and the like that is in contact with the conductor 242 can be an n-type region, i.e., a lower-resistance region. Note that a region in the metal oxide film that has reduced resistance can also be referred to as an n+ region.

### Example 2

In this example, to study the electrical connection between the conductor 242b and the conductor 231 in FIG. 2 and the like, a TEG (Test Element Group) for electric resistance measurement was fabricated and comparison was made between the case where a single-layer film of tantalum nitride was formed and the case where a stacked-layer film of tantalum nitride and tungsten was formed.

Two types of TEGs were fabricated. In the first TEG, a first metal layer and a second metal layer were stacked on top of each other in a cross shape to perform Kelvin measurement. Since the first TEG is measured with four terminals, contact resistance at the contact interface between the first metal layer and the second metal layer can be measured.

The second TEG is referred to as a contact chain in which the first metal layer and the second metal layer are arranged alternately to be connected in series; three resistance elements of the first metal layer, the second metal layer, and the contact interface between the first metal layer and the second metal layer are connected in series. The second TEG was fabricated to have 3000 contact interfaces between the first metal layer and the second metal layer and is referred to as a contact chain with 3000 contacts in some cases.

A method for fabricating samples including the first TEG and the second TEG is described. Sample 4A and Sample 4B each include the first TEG and the second TEG. The contents common to the fabrication of Sample 4A and Sample 4B are described first.

In each of the first TEG and the second TEG, an insulating layer is provided between the first metal layer and the second metal layer and the first metal layer and the second metal layer are in contact with each other in an opening portion in the insulator.

The insulating film was formed in the following manner: first silicon nitride was deposited to a thickness of 5 nm by a sputtering method, first silicon oxide was deposited to a thickness of 85 nm by a sputtering method, second silicon nitride was deposited to a thickness of 110 nm by a sputtering method, first aluminum oxide was deposited to a thickness of 10 nm by a sputtering method, third silicon nitride was deposited to a thickness of 20 nm by a sputtering method, second silicon oxide was deposited to a thickness of 50 nm by a sputtering method, second aluminum oxide was deposited to a thickness of 3 nm by an ALD method, and fourth silicon nitride was deposited to a thickness of 3 nm by a PEALD method in this order.

The opening portion in the insulator was formed by a dry etching method. Here, conditions of the dry etching to expose the first metal layer were the same as Etching Condition B described in <Etching rate measurement>.

As the second metal layer in contact with the first metal layer in the opening portion in the insulator, titanium nitride and tungsten were deposited in this order to form a stacked-layer film.

The titanium nitride in the second metal layer was deposited to a thickness of 5 nm by a CVD method. The deposition conditions were as follows: a mixed gas of a TiCl₄ gas at a flow rate of 50 sccm and an NH₃ gas at a flow rate of 2700 sccm was used, the pressure was 667 Pa, the distance between the surface of a substrate and an upper electrode was 3 mm, and the substrate temperature was 400° C.

The tungsten in the second metal layer was deposited to a thickness of 150 nm by a CVD method. The deposition conditions were different between a first step, a second step, and a third step. The conditions of the first step were as follows: a mixed gas of a WF₆ gas at a flow rate of 160 sccm, a SiH₄ gas at a flow rate of 400 sccm, an argon gas at a flow rate of 6000 sccm, and a nitrogen gas at a flow rate of 2000 sccm was used, the pressure was 1000 Pa, and the substrate temperature was 400° C. The conditions of the second step was as follows: a mixed gas of a WF₆ gas at a flow rate of 250 sccm, a hydrogen gas at a flow rate of 4000 sccm, an argon gas at a flow rate of 2000 sccm, and a nitrogen gas at a flow rate of 2000 sccm was used, the pressure was 10666 Pa, and the substrate temperature was 400° C. The conditions of the third step was as follows: a mixed gas of a WF₆ gas at a flow rate of 250 sccm, a hydrogen gas at a flow rate of 2200 sccm, an argon gas at a flow rate of 2000 sccm, and a nitrogen gas at a flow rate of 200 sccm was used, the pressure was 10666 Pa, and the substrate temperature was 400° C.

The fabrication conditions common to Sample 4A and Sample 4B are as described above.

In Sample 4A, the first metal layer is a single-layer film of tantalum nitride. The tantalum nitride was deposited to a thickness of 20 nm by a sputtering method.

In Sample 4B, the first metal layer is a stacked-layer film of tantalum nitride and tungsten. The tantalum nitride was deposited to a thickness of 5 nm by a sputtering method, and the tungsten was deposited to a thickness of 15 nm over the tantalum nitride by a sputtering method.

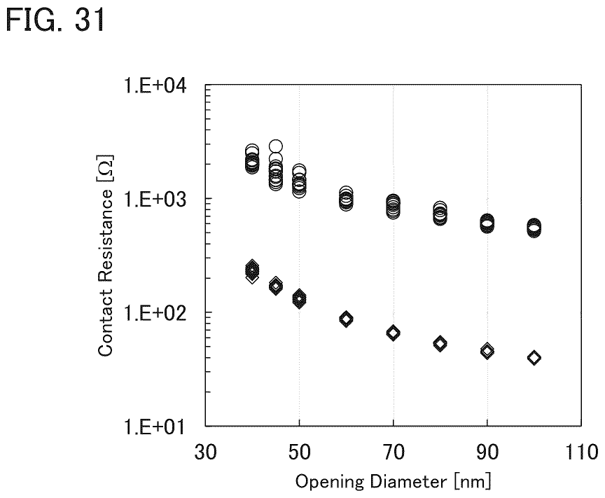

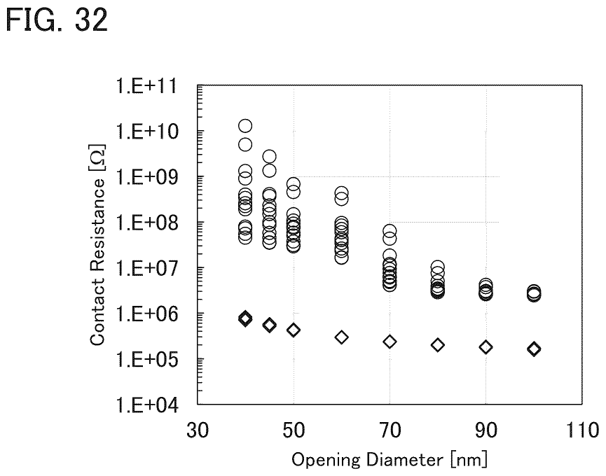

The first TEG and the second TEG included in each of Sample 4A and Sample 4B fabricated as described above were subjected to measurement. FIG. 31 shows measurement results of the first TEG and FIG. 32 shows measurement results of the second TEG.

In FIG. 31 and FIG. 32, measured values of Sample 4A are indicated by circles and measured values of Sample 4B are indicated by rhombuses.

Note that the first TEG and the second TEG each include eight types of TEGs with different diameters of the opening in the insulating film. The horizontal axis in each of FIG. 31 and FIG. 32 represents the designed opening diameter of the TEG. The diameters of the opening in the insulating film are 40 nm, 45 nm, 50 nm, 60 nm, 70 nm, 80 nm, 90 nm, and 100 nm.

In both the first TEG and the second TEG, the resistance values of Sample 4B are lower than those of Sample 4A by one or more orders of magnitude.

Moreover, in both the first TEG and the second TEG, the resistance value variation of Sample 4B is smaller than that of Sample 4A. That is, it can be said that the structure is more stable when the stacked-layer film of the tantalum nitride and the tungsten is used. It can also be said that the process is more stable.

### REFERENCE NUMERALS

10: memory cell, 11: memory layer, 15: memory cell array, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 100: memory device, 101: capacitor, 160: conductor, 181: insulator, 183: insulator, 185: insulator, 201a: transistor, 201b: transistor, 201: transistor, 202a: transistor, 202b: transistor, 202: transistor, 203a: transistor, 203b: transistor, 203: transistor, 205a: conductor, 205b: conductor, 205: conductor, 207a: opening, 207b: opening, 207c: opening, 209a: conductor, 209b: conductor, 209: conductor, 210: insulator, 212: insulator, 214: insulator, 215: insulator, 216a: insulator, 216b: insulator, 222: insulator, 224f: insulating film, 224: insulator, 230a: metal oxide, 230af: metal oxide film, 230b: metal oxide, 230bf: metal oxide film, 230: metal oxide, 231: conductor, 232: conductor, 233: conductor, 233a: conductor, 233b: conductor, 240a: connection electrode, 240b: connection electrode, 242a: conductor, 242A: conductive layer, 242b: conductor, 242B: conductive layer, 242c: conductor, 242d: conductor, 242e: conductor, 242: conductor, 253: insulator, 254: insulator, 258a: opening, 258b: opening, 258c: opening, 258: opening, 260: conductor, 275: insulator, 280: insulator, 282: insulator, 287: insulator, 291: opening, 292: opening, 293: opening, 294: opening, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 600: circuit, 652: AND circuit, 653: analog switch, 654: analog switch, 661: transistor, 662: transistor, 663: transistor, 664: transistor, 666: transistor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: connection portion, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first conductor;
a second conductor;
a first insulator;
a first transistor over the first insulator; and
a second insulator over the first transistor,
wherein the first transistor comprises a first metal oxide, a third conductor electrically connected to the first metal oxide, a fourth conductor electrically connected to the first metal oxide, a third insulator over the first metal oxide, and a fifth conductor over the third insulator,
wherein the fourth conductor comprises a first layer and a second layer over the first layer,
wherein the top surface of the fifth conductor is in contact with the second insulator,
wherein the first conductor comprises a portion inside a first opening of the first insulator, a region in contact with a side surface of the third conductor, and a portion inside a second opening of the second insulator,
wherein the second conductor comprises a region in contact with the second layer and a portion inside a third opening of the second insulator, and
wherein the top surface of the first conductor and the top surface of the second conductor are level or substantially level with each other.

2. A semiconductor device comprising:
a first conductor;
a second conductor;
a first insulator;
a first transistor, a second transistor, and a third transistor over the first insulator; and
a second insulator over the first transistor, the second transistor, and the third transistor,
wherein the first transistor comprises a first metal oxide, a third conductor electrically connected to the first metal oxide, a fourth conductor electrically connected to the first metal oxide, a third insulator over the first metal oxide, and a fifth conductor over the third insulator,
wherein the fourth conductor comprises a first layer and a second layer over the first layer,
wherein the second transistor comprises a second metal oxide, a sixth conductor electrically connected to the second metal oxide, a seventh conductor electrically connected to the second metal oxide, a fourth insulator over the second metal oxide, and an eighth conductor over the fourth insulator,
wherein the third transistor comprises the second metal oxide, the seventh conductor electrically connected to the second metal oxide, a ninth conductor electrically connected to the second metal oxide, a fifth insulator over the second metal oxide, and a tenth conductor over the fifth insulator,
wherein the top surface of the fifth conductor and the top surface of the tenth conductor are in contact with the second insulator,
wherein the first conductor comprises a portion inside a first opening of the first insulator, a region in contact with a side surface of the third conductor, and a portion inside a second opening of the second insulator,
wherein the second conductor comprises a region in contact with the second layer and a portion inside a third opening of the second insulator,
wherein the second conductor and the eighth conductor are electrically connected to each other, and
wherein the top surface of the first conductor and the top surface of the second conductor are level or substantially level with each other.

3. A semiconductor device comprising:
a first conductor;
a second conductor;
a first insulator;
a first transistor, a second transistor, and a third transistor over the first insulator;
a second insulator over the first transistor, the second transistor, and the third transistor; and
a capacitor,
wherein the first transistor comprises a first metal oxide, a third conductor electrically connected to the first metal oxide, a fourth conductor electrically connected to the first metal oxide, a third insulator over the first metal oxide, and a fifth conductor over the third insulator,
wherein the fourth conductor comprises a first layer and a second layer over the first layer,
wherein the second transistor comprises a second metal oxide, a sixth conductor electrically connected to the second metal oxide, a seventh conductor electrically connected to the second metal oxide, a fourth insulator over the second metal oxide, and an eighth conductor over the fourth insulator,
wherein the third transistor comprises the second metal oxide, the seventh conductor electrically connected to the second metal oxide, a ninth conductor electrically connected to the second metal oxide, a fifth insulator over the second metal oxide, and a tenth conductor over the fifth insulator,
wherein the capacitor comprises an eleventh conductor, a sixth insulator over the eleventh conductor, and a twelfth conductor over the sixth insulator,
wherein the top surface of the fifth conductor and the top surface of the tenth conductor are in contact with the second insulator,
wherein the first conductor comprises a portion inside a first opening of the first insulator, a region in contact with a side surface of the third conductor, and a portion inside a second opening of the second insulator,
wherein the second conductor comprises a region in contact with the second layer and a portion inside a third opening of the second insulator,
wherein the second conductor and the eighth conductor are electrically connected to each other through the eleventh conductor, and
wherein the top surface of the first conductor and the top surface of the second conductor are level or substantially level with each other.

4. The semiconductor device according to claim 3,
wherein the sixth insulator comprises a first zirconium oxide, an aluminum oxide over the first zirconium oxide, and a second zirconium oxide over the aluminum oxide.

5. The semiconductor device according to claim 1,
wherein the first layer comprises tantalum nitride, and
wherein the second layer comprises tungsten.

6. The semiconductor device according to claim 1,
wherein a thickness of the fourth conductor is greater than or equal to 10 nm and less than or equal to 50 nm, and
wherein a thickness of the first layer is greater than or equal to 2 nm and less than or equal to 10 nm.

7. The semiconductor device according to claim 1,
wherein a width of the region of the first conductor that is in contact with the side surface of the third conductor is smaller than a width of the portion of the first conductor that is inside the second opening of the second insulator in a cross-sectional view in a channel length direction.

8. The semiconductor device according to claim 1,
wherein the first metal oxide comprises one or more selected from indium, zinc, gallium, aluminum, and tin.

9. The semiconductor device according to claim 2,
wherein the first metal oxide and the second metal oxide comprise one or more selected from indium, zinc, gallium, aluminum, and tin.

10. The semiconductor device according to claim 2,
wherein the first layer comprises tantalum nitride, and
wherein the second layer comprises tungsten.

11. The semiconductor device according to claim 2,
wherein a thickness of the fourth conductor is greater than or equal to 10 nm and less than or equal to 50 nm, and
wherein a thickness of the first layer is greater than or equal to 2 nm and less than or equal to 10 nm.

12. The semiconductor device according to claim 2,
wherein a width of the region of the first conductor that is in contact with the side surface of the third conductor is smaller than a width of the portion of the first conductor that is inside the second opening of the second insulator in a cross-sectional view in a channel length direction.

13. The semiconductor device according to claim 3,
wherein the first layer comprises tantalum nitride, and
wherein the second layer comprises tungsten.

14. The semiconductor device according to claim 3,
wherein a thickness of the fourth conductor is greater than or equal to 10 nm and less than or equal to 50 nm, and
wherein a thickness of the first layer is greater than or equal to 2 nm and less than or equal to 10 nm.

15. The semiconductor device according to claim 3,
wherein a width of the region of the first conductor that is in contact with the side surface of the third conductor is smaller than a width of the portion of the first conductor that is inside the second opening of the second insulator in a cross-sectional view in a channel length direction.

16. The semiconductor device according to claim 3,
wherein the first metal oxide and the second metal oxide comprise one or more selected from indium, zinc, gallium, aluminum, and tin.
